(19) United States
(12) Patent Application Publication
(10) Pub. No.: US 2026/0040821 A1
(43) Pub. Date: Feb. 5, 2026

(54) LAMINATE, AND QUANTUM DOT ELECTROLUMINESCENT DEVICE COMPRISING THE LAMINATE

(71) Applicant: SAMSUNG ELECTRONICS CO., LTD., Suwon-si, Gyeonggi-do (KR)

(72) Inventors: Naotoshi SUGANUMA, Yokohama-shi, Kanagawa (JP); Norihito ISHII, Yokohama-shi, Kanagawa (JP); Fumiaki KATO, Yokohama-shi, Kanagawa (JP); Yusaku KONISHI, Yokohama-shi, Kanagawa (JP); Kiyohiko TSUTSUMI, Yokohama-shi, Kanagawa (JP); Masashi TSUJI, Yokohama-shi, Kanagawa (JP); Takahiro FUJIYAMA, Yokohama-shi, Kanagawa (JP); Tomoyuki KIKUCHI, Yokohama-shi, Kanagawa (JP)

(21) Appl. No.: 18/668,414

(22) Filed: May 20, 2024

(30) Foreign Application Priority Data
May 19, 2023 (JP) 2023-083152

(51) Int. Cl. H10K 85/00; H10K 50/115; H10K 50/15; H10K 85/10; H10K 85/60

(52) U.S. Cl. CPC H10K 85/731; H10K 50/15; H10K 85/115; H10K 85/151; H10K 85/60; H10K 85/6576; H10K 50/115

(57) ABSTRACT

An electroluminescent device having improved solvent resistance and high performance (high luminous efficiency and long luminous lifetime), for example, a quantum dot electroluminescent device, is provided, wherein the electroluminescent device includes a laminate comprising a hole transport layer and an emitting layer, wherein the hole transport layer comprises a first organic compound and a second organic compound having hole transport properties, the first organic compound being an amine-based polymer, the second organic compound being a liquid crystalline compound, and the hole transport layer comprising a domain of the liquid crystalline compound.

### CROSS REFERENCE TO RELATED APPLICATIONS

This application claims priority to Japanese Patent Application No. 2023-83152 filed in the Japanese Intellectual Property Office on May 19, 2023, and all the benefits arising therefrom under 35 U.S.C. § 119, the contents of which are herein incorporated by reference in their entirety.

### BACKGROUND

### 1. Field

A laminate, and quantum dot electroluminescent device comprising the laminate are disclosed.

### 2. Description of the Related Art

Electroluminescent devices (hereinafter, also referred to as (EL devices′) is a promising candidate for use as solid-state, at low-cost, in a large-area, of a full-color display or for recording light source arrays. EL device has a thin film having a thickness of several nanometers to hundreds of nanometers disposed between an anode and a cathode. Additionally, an EL element can have a hole transport layer, a light emitting layer, an electron transport layer, etc.

Among these, the light-emitting layer can include fluorescent materials and/or phosphorescent materials as light-emitting materials. Compared to the fluorescent materials, phosphorescent materials are expected to have approximately four times of the luminous efficiency. Meanwhile, the RGB (red, green, blue) light sources are required to have an emission spectrum with a narrow full width at half maximum (FWHM) for covering a wide color region. In particular, a deep blue is desirable, but a device that can achieve a combination of long lifespan and color purity has yet to be developed.

Conventional light-emitting devices include “quantum dots,” (QDs) as an inorganic light-emitting material, (Japanese Patent Publication No. 2010-199067). Quantum dots are semiconductor materials having crystalline structures of several nanometers in size, and comprised of hundreds to thousands of atoms. As the quantum dots are very small in size, they have a large surface area per unit volume. Because of this, most atoms exist on the surface of the nanocrystal, and the quantum confinement effect is exhibited. Due to the quantum confinement effect, the emission wavelength may be controlled simply by adjusting size of the QD, and excellent color purity and high PL (photoluminescence) emission efficiency may be achieved. A quantum dot electroluminescent device (QD LED) has a basic three-layer structure that includes a hole transport layer (HTL) and an electron transport layer (ETL) at both the anode and the cathode and a quantum dot light-emitting layer between the two ends.

When fabricating a quantum dot electroluminescent device, cost reduction can be expected by forming each layer, for example, the light emitting layer, by coating, for example, using an inkjet coating. For example, in order to form an upper layer of the hole transport layer, for example, the light emitting layer, by coating, the hole transport layer is preferably resistant to solvents.

However, the electroluminescent device using a hole transport material described in Japanese Patent Publication No. 2010-199067, in particular a quantum dot electroluminescent device, has insufficient solvent resistance.

### SUMMARY

The inventors of the present application have found that solvent resistance can be achieved with a laminate that includes a hole transport layer and a light emitting layer, wherein the hole transport layer includes a first organic compound and a second organic compound both of which have hole transport properties, wherein the first organic compound includes an amine-based polymer, and the second organic compound is a liquid crystalline compound, and the hole transport layer includes a domain of the liquid crystalline compound.

Accordingly, the present invention includes the following aspects.

[1] A laminate includes a hole transport layer and a light-emitting layer, wherein the hole transport layer includes a first organic compound and a second organic compound both of which have hole transport properties, the first organic compound includes an amine-based polymer, the second organic compound is a liquid crystalline compound, and the hole transport layer includes a domain of the liquid crystalline compound.

[2] The laminate according to [1] above, wherein the solvent resistance value of the hole transport layer may be greater than or equal to 95%, wherein the solvent resistance value may be a ratio of the intensity of the absorption spectrum at a reference wavelength after immersing the hole transport layer in a solvent to the intensity of the absorption spectrum at a reference wavelength before immersing the hole transport layer in a solvent multiplied by 100%.

[3] The laminate according to [1] or [2] above, wherein the hole transport layer may include the liquid crystalline compound in an amount of greater than or equal to 5% by weight (wt %) and 50 wt % or less based on a total weight of all organic compounds constituting the hole transport layer.

[4] The laminate according to any one of [1] to [3] above, wherein the second organic compound may include at least one of the compounds represented by formulas (L1) to (L4).

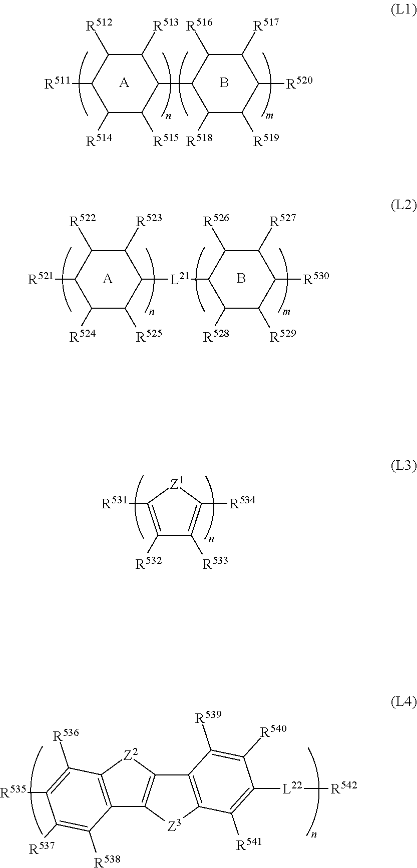

where in formulas (L1) to (L4),
ring A and ring B are each independently a benzene ring or a cyclohexane ring,
R⁵¹¹ to R⁵⁴² are each independently hydrogen, deuterium (D), a cyano group, a nitro group, a halogen group, a carboxyl group, an alkyl group having 1 to 20 carbon atoms, an alkoxy group having 1 to 20 carbon atoms, —R⁵⁴³—COOH (R⁵⁴³ is an alkylene group having 1 to 20 carbon atoms or an alkenylene group having 2 to 20 carbon atoms), deuterated —R⁵⁴³—COOH (R⁵⁴³ is an alkylene group having 1 to 20 carbon atoms or an alkenylene group having 2 to 20 carbon atoms), a silyl group (—Si(R⁵⁴⁴)₃) (R⁵⁴⁴ is independently hydrogen or an alkyl group having 1 to 20 carbon atoms), a siloxanyl group (—O—Si(R⁵⁴⁵)₃) (R⁵⁴⁵ is, each independently, hydrogen or an alkyl group having 1 to 20 carbon atoms), an amino group (—N(R⁵⁴⁶)₂) (R⁵⁴⁶ is independently hydrogen or an alkyl group having 1 to 20 carbon atoms), or —R⁵⁴⁷—C(═O)—R⁵⁴⁸ (R⁵⁴⁷ is a single bond, an alkylene group having 1 to 20 carbon atoms or an alkenylene group having 2 to 20 carbon atoms, and R⁵⁴⁸ is an alkyl group having 1 to 20 carbon atoms or an alkenyl group having 2 to 20 carbon atoms),
L²¹ is one of the following structures:

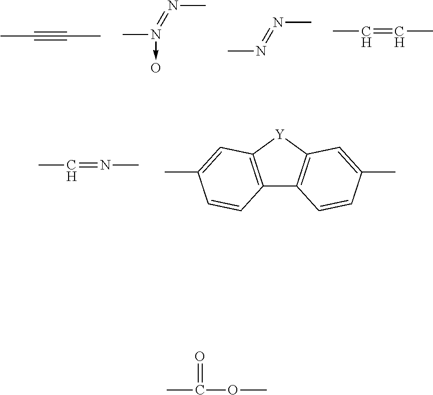

wherein in the above structures,
Y is —Si(R⁵⁴⁹)(R⁵⁰)—, —C(R⁵⁵¹)(R⁵⁵²)—, S, O, Se, or Te, wherein R⁵⁴⁹ to R⁵⁵² are each independently hydrogen, deuterium (D), an alkyl group having 1 to 20 carbon atoms, an alkoxy group having 1 to 20 carbon atoms, —R⁵⁴³—COOH (R⁵⁴³ is an alkylene group having 1 to 20 carbon atoms or an alkenylene group having 2 to 20 carbon atoms), a silyl group (—Si(R⁵⁴⁴)₃) (R⁵⁴⁴ is each independently hydrogen or an alkyl group having 1 to 20 carbon atoms), or a siloxanyl group (—O—Si(R⁵⁴⁵)₃) (R⁵⁴⁵ is each independently hydrogen or an alkyl group having 1 to 20 carbon atoms),
Z¹, Z² and Z³ are each independently S, O, Se, or Te,
L²² is a single bond or a phenylene group, and
n and m are each independently an integer of from 1 to 10,
wherein, when ring A and ring B are both benzene rings, then, at least one of R⁵¹¹ to R⁵²⁰, and at least one of R⁵²¹ to R⁵³⁰ each independently includes a cyano group, a nitro group, a halogen group (e.g. a fluoro group), a carboxyl group (—COOH), —R⁵⁴³—COOH (R⁵⁴³ is an alkylene group having 1 to 20 carbon atoms or an alkenylene group having 2 to 20 carbon atoms), or —R⁵⁴⁷—C(═O)—R⁵⁴⁸ (R⁵⁴⁷ is a single bond, an alkylene group having 1 to 20 carbon atoms or an alkenylene group having 2 to 20 carbon atoms, and R⁵⁴⁸ is an alkyl group having 1 to 20 carbon atoms or an alkenyl group having 2 to 20 carbon atoms, and
wherein, when ring A and ring B are both cyclohexane rings, then, at least one of R⁵¹¹ to R⁵²⁰, and at least one of R⁵²¹ to R⁵³⁰ each independently includes hydrogen, deuterium (D), a cyano group, a nitro group, a halogen group, an alkyl group having 1 to 20 carbon atoms, an alkoxy group having 1 to 20 carbon atoms, —R⁵⁴³—COOH (R⁵⁴³ is an alkylene group having 1 to 20 carbon atoms or an alkenylene group having 2 to 20 carbon atoms), a silyl group (—Si(R⁵⁴⁴)₃) (R⁵⁴⁴ is each independently hydrogen or an alkyl group having 1 to 20 carbon atoms), a siloxanyl group (—O—Si(R⁵⁴⁵)₃) (R⁵⁴⁵ is independently hydrogen or an alkyl group having 1 to 20 carbon atoms), an amino group (—N(R⁵⁴⁶)₂) (R⁵⁴⁶ is independently hydrogen, or an alkyl group having 1 to 20 carbon atoms), or a deuterated —R⁵⁴³—COOH (R⁵⁴³ is an alkylene group having 1 to 20 carbon atoms or an alkenylene group having 2 to 20 carbon atoms).

[5] The laminate according to any one of [1] to [4] above, wherein the amine-based polymer may include at least one structural unit represented by Chemical Formula (1), (2), or (3):

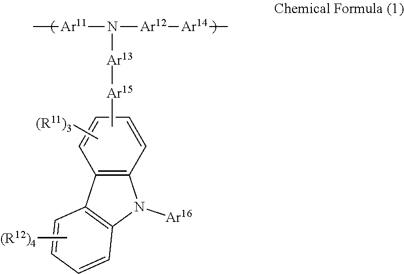

wherein in Chemical Formula (1),
Ar¹¹ and Ar¹² are each independently a substituted or unsubstituted aromatic hydrocarbon group having 6 to 60 carbon atoms,
Ar¹³ is a substituted or unsubstituted aromatic hydrocarbon group having 6 to 120 carbon atoms,
Ar¹⁴ is a substituted or unsubstituted aromatic hydrocarbon group having 6 to 60 carbon atoms, or a substituted or unsubstituted heterocyclic ring having 3 to 60 ring-forming atoms,
Ar¹⁵ is a single bond, or a substituted or unsubstituted heterocyclic ring having 3 to 60 ring-forming atoms,
Ar¹⁶ is a substituted or unsubstituted aromatic hydrocarbon group having 6 to 60 carbon atoms, or a substituted or unsubstituted heterocyclic ring having 3 to 60 ring-forming atoms,
R¹¹ is independently hydrogen atom, an alkyl group, a hydroxyalkyl group, an alkoxy group, an alkoxyalkyl group, an alkenyl group, an alkynyl group, an alkylthio group, an alkoxy carbonyl group, a hydroxyl group (—OH), a carboxyl group (—COOH), a thiol group (—SH), or a cyano group (—CN), and
R¹² is independently hydrogen atom, an alkyl group, a hydroxyalkyl group, an alkoxy group, an alkoxyalkyl group, an alkenyl group, an alkynyl group, an alkylthio group, an alkoxy carbonyl group, an hydroxyl group (—OH), a carboxyl group (—COOH), a thiol group (—SH), or a cyano group (—CN);

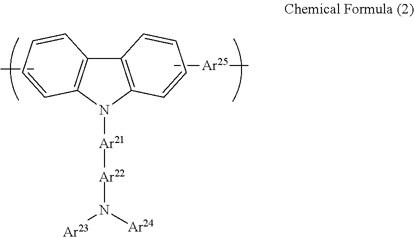

wherein in Chemical Formula (2),
Ar²¹ is a substituted or unsubstituted aromatic hydrocarbon group having 6 to 120 carbon atoms,
Ar²² is a single bond, or a substituted or unsubstituted heterocyclic ring having 3 to 60 ring-forming atoms,
Ar²³ and Ar²⁴ are each independently a substituted or unsubstituted aromatic hydrocarbon group having 6 to 25 carbon atoms, or a substituted or unsubstituted heterocyclic ring having 3 to 60 ring-forming atoms, and
Ar²⁵ is a substituted or unsubstituted aromatic hydrocarbon group having 6 to 60 carbon atoms, or a substituted or unsubstituted heterocyclic ring having 3 to 60 ring-forming atoms,

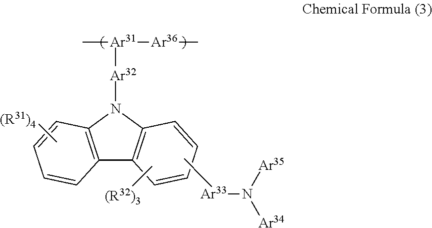

wherein in Chemical Formula (3),
Ar³¹ is a substituted or unsubstituted aromatic hydrocarbon group having 6 to 60 carbon atoms,
Ar³² and Ar³³ are each independently a substituted or unsubstituted aromatic hydrocarbon group having 6 to 120 carbon atoms,
Ar³⁴ and Ar³⁵ are each independently a substituted or unsubstituted aromatic hydrocarbon group having 6 to 60 carbon atoms, or a substituted or unsubstituted heterocyclic ring having 3 to 60 ring-forming atoms,
Ar³⁶ is a substituted or unsubstituted aromatic hydrocarbon group having 6 to 60 carbon atoms, or a substituted or unsubstituted heterocyclic ring having 3 to 60 ring-forming atoms,
R³¹ is independently hydrogen atom, an alkyl group, a hydroxyalkyl group, an alkoxy group, an alkoxyalkyl group, an alkenyl group, an alkynyl group, an alkylthio group, an alkoxy carbonyl group, a hydroxyl group (—OH), a carboxyl group (—COOH), a thiol group (—SH), or a cyano group (—CN), and
R³² is independently hydrogen atom, an alkyl group, a hydroxyalkyl group, an alkoxy group, an alkoxyalkyl group, an alkenyl group, an alkynyl group, an alkylthio group, an alkoxy carbonyl group, a hydroxyl group (—OH), a carboxyl group (—COOH), a thiol group (—SH), or a cyano group (—CN).

[6] The laminate according to [5] above, wherein in Chemical Formula (1), Ar¹³ may be selected from Group I below, Ar¹¹, Ar¹², and Ar¹⁴ may each independently be selected from Group II below, and Ar¹⁶ may be selected from Group III below:

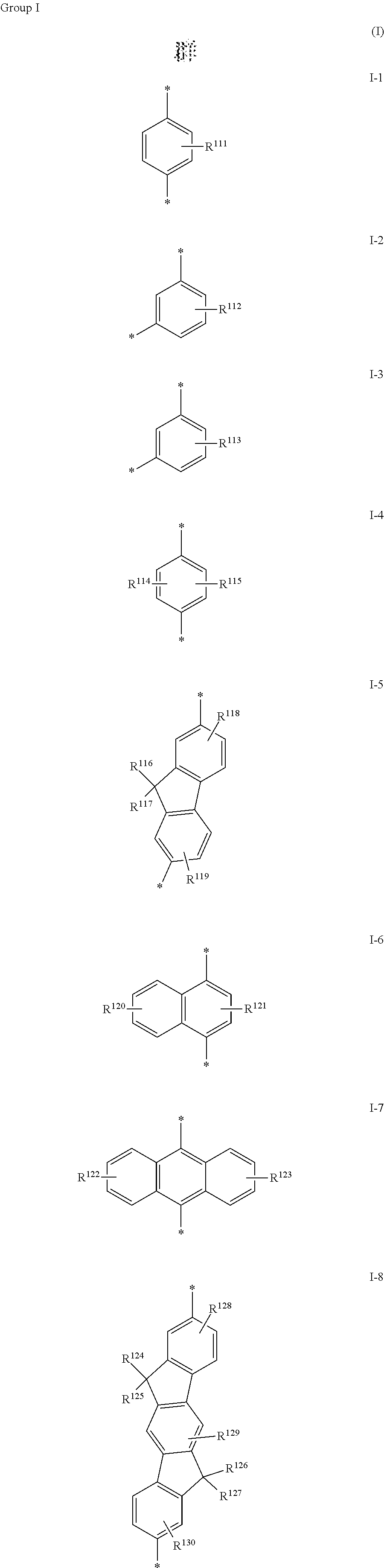

wherein in Group I,
R¹¹¹ to R¹³⁰ are each independently hydrogen atom, or a linear or branched hydrocarbon group having 1 to 18 carbon atoms, and
* is the bonding position with an adjacent atom;

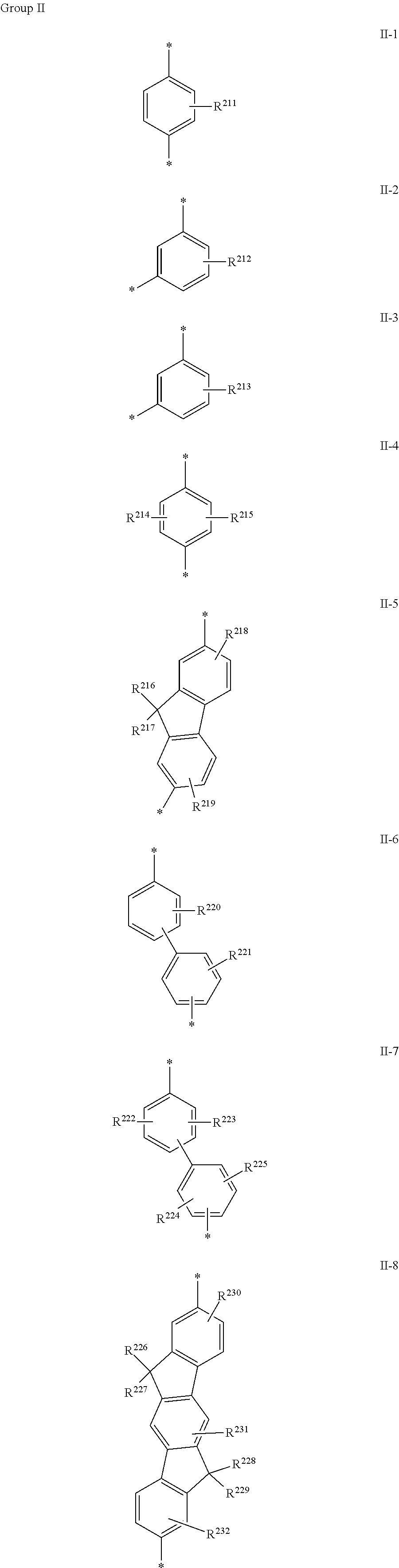

wherein in Group II,
R²¹¹ to R²³² are each independently hydrogen atom, or a linear or branched hydrocarbon group having 1 to 18 carbon atoms, and
* is the bonding position with an adjacent atom;

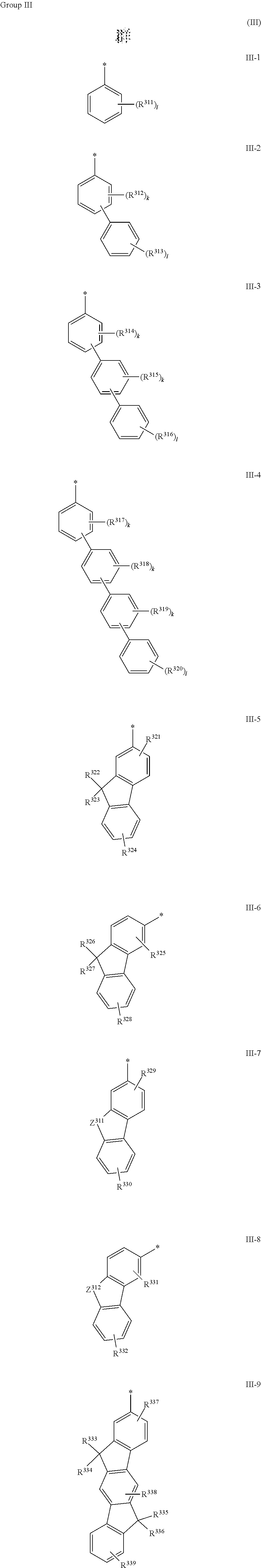

wherein in Group III,
R³¹¹ to R³³⁹ are each independently hydrogen atom, or a linear or branched hydrocarbon group having 1 to 18 carbon atoms,
Z³¹¹ and Z³¹² are each independently oxygen or sulfur atom,
k is an integer of from 0 to 4,
l is an integer of from 0 to 5, and
* indicates the bonding position with adjacent atoms.

[7] The laminate according to [5] above, wherein in Chemical Formula (2), Ar²³ and Ar²⁴ may each independently be selected from Group IV below, and Ar²⁵ is selected from Group II below:

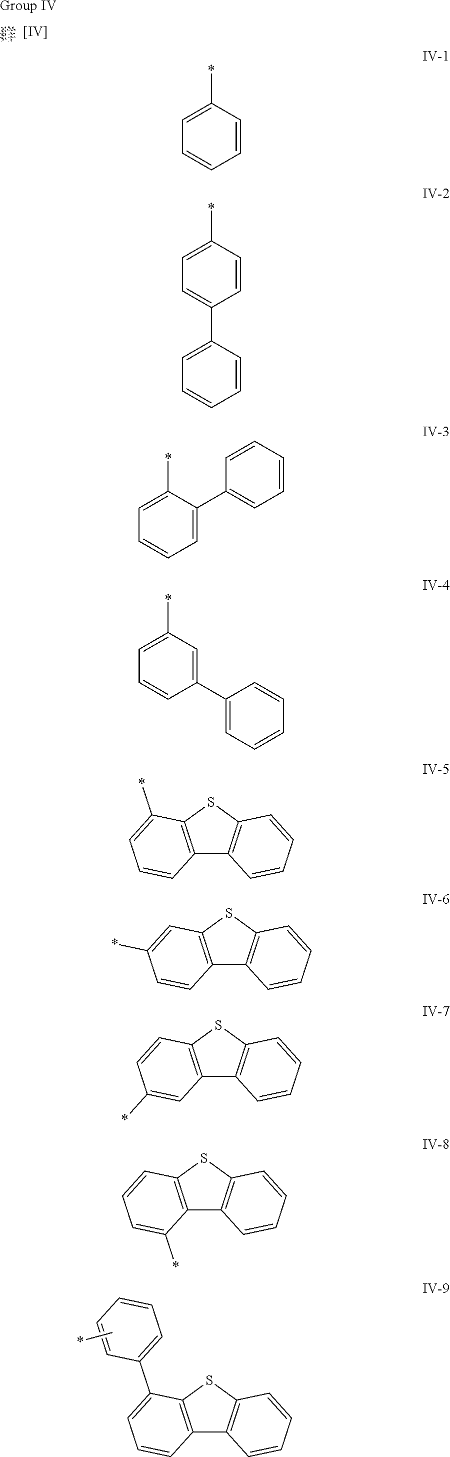

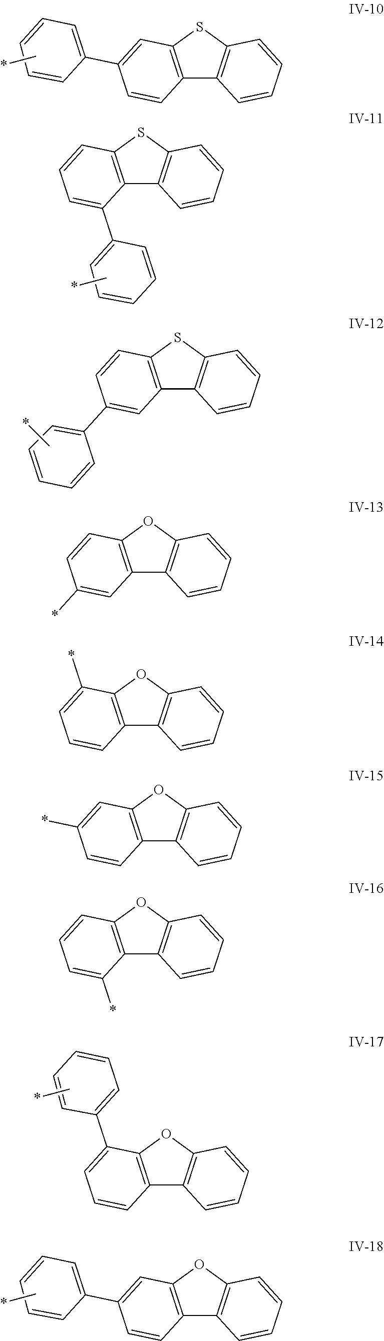

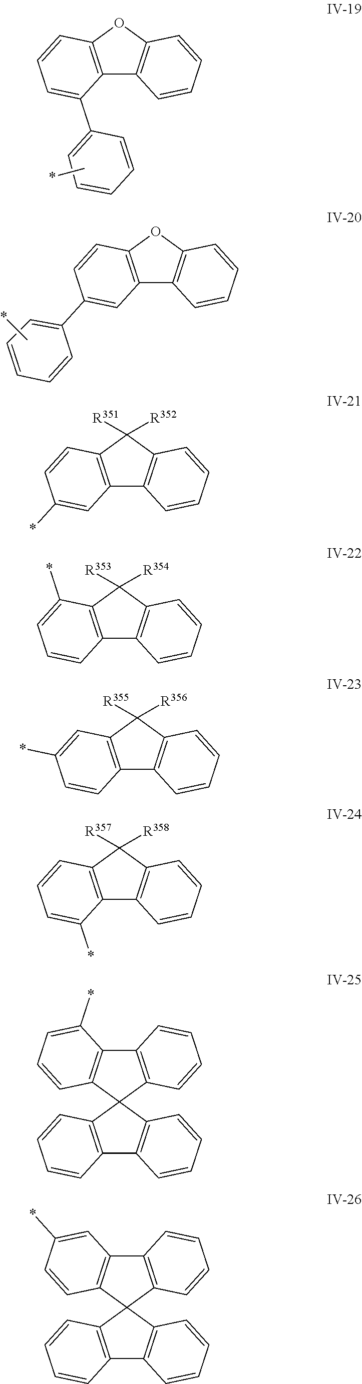

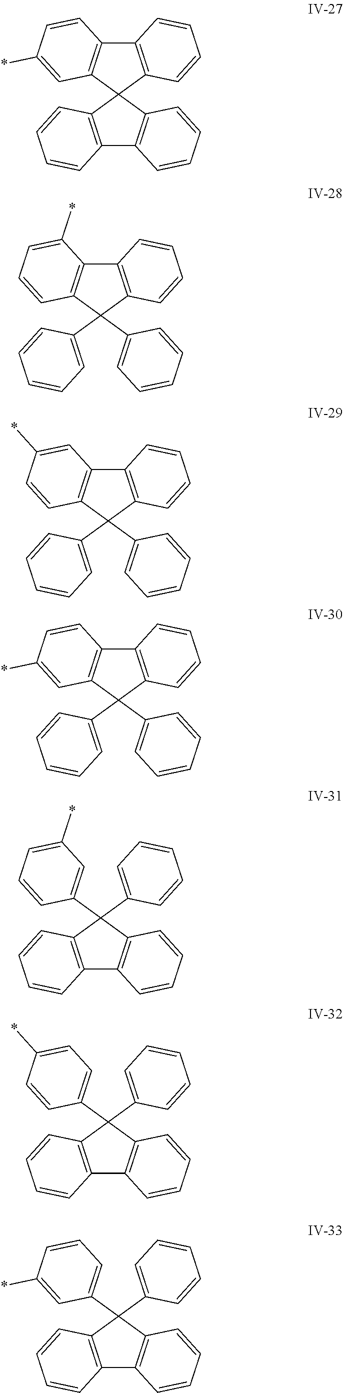

wherein in Group IV,
R³⁵¹ to R³⁵⁸ are each independently an alkyl group having 1 to 20 carbon atoms, and
* indicates the bonding position with an adjacent atom;

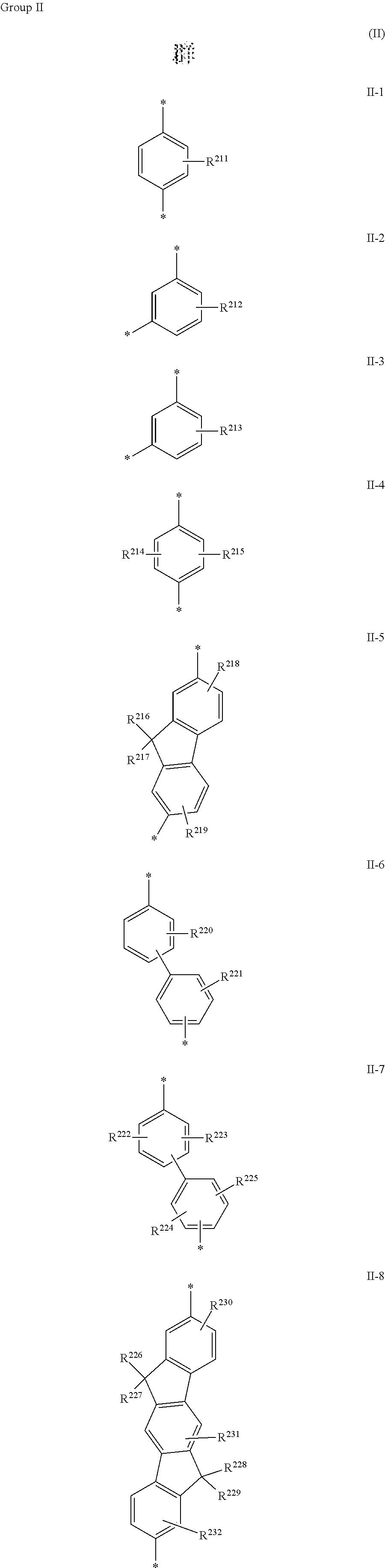

wherein in Group II,
R²¹¹ to R²³² are each independently hydrogen atom, or a linear or branched hydrocarbon group having 1 to 18 carbon atoms, and
* is the bonding position with an adjacent atom.

[8] The laminate according to [5] above, wherein the structural unit of Chemical Formula (3) may include one or more of the structural units described in Group V below.

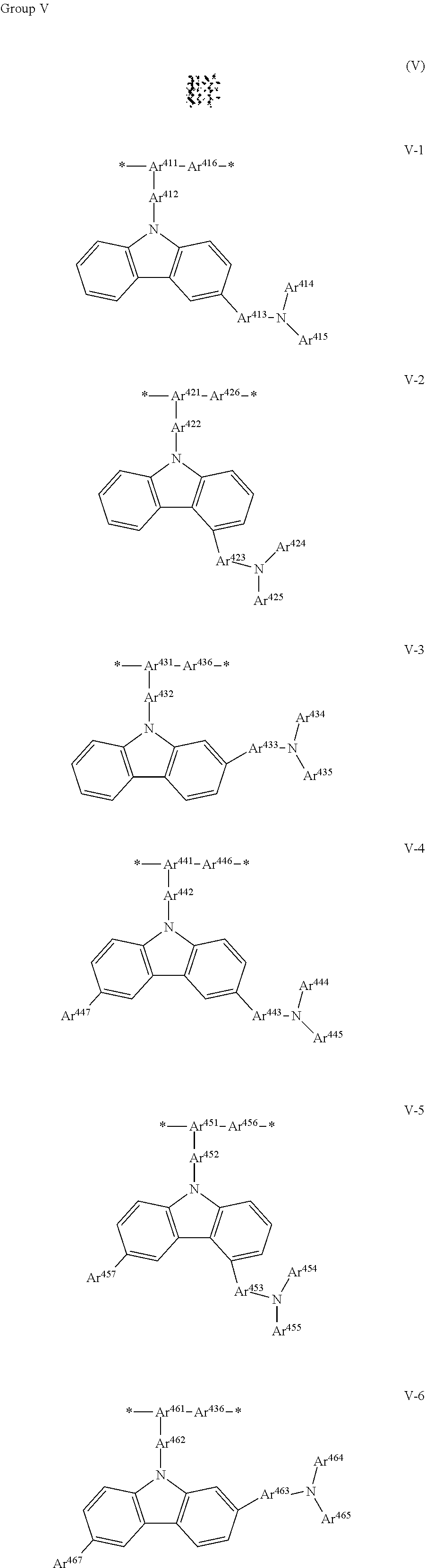

wherein in group V,
Ar⁴¹¹, Ar⁴²¹, Ar⁴³¹, Ar⁴⁴¹, Ar⁴⁵¹, and Ar⁴⁶¹ are each independently a substituted or unsubstituted aromatic hydrocarbon group having 6 to 60 carbon atoms,
Ar⁴¹², Ar⁴²², Ar⁴³², Ar⁴⁴², Ar⁴⁵², Ar⁴⁶², Ar⁴¹³, Ar⁴²³, Ar⁴³³, Ar⁴⁴³, Ar⁴⁵³, and Ar⁴⁶³ are each independently a substituted or unsubstituted aromatic hydrocarbon group having 6 to 120 carbon atoms,
Ar⁴¹⁴, Ar⁴²⁴, Ar⁴³⁴, Ar⁴, Ar⁴⁵⁴, Ar⁴⁶⁴, Ar⁴¹⁵, Ar⁴²⁵, Ar⁴³⁵, Ar⁴⁴⁵, Ar⁴⁵⁵, and Ar⁴⁶⁵ are each independently a group selected from Group IV above,
Ar⁴¹⁶, Ar⁴²⁶, Ar⁴³⁶, Ar⁴⁶, Ar⁴⁵⁶, and Ar⁴⁶ are each independently selected from Group II below,
Ar⁴⁴⁷, Ar⁴⁵⁷, and Ar⁴⁶⁷ are each independently hydrogen atom, or a linear or branched hydrocarbon group having 1 to 18 carbon atoms, and
* indicates the bonding position with an adjacent atom:

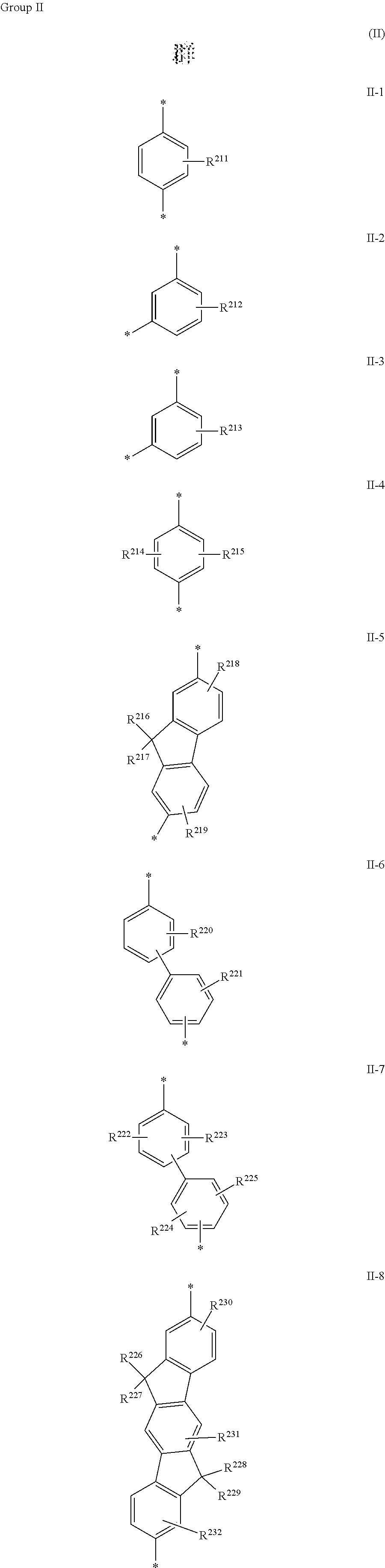

wherein in Group II,
R²¹¹ to R²³² are each independently hydrogen atom, or a linear or branched hydrocarbon group having 1 to 18 carbon atoms, and
* indicates the bonding position with an adjacent atom.

[9] The laminate according to [6] above, wherein in Chemical Formula (1), Ar¹³ may be selected from Group I above, Ar¹¹ and Ar¹² may each independently be selected from Group II above, and Ar¹⁴ may be represented by Chemical Formula (5):

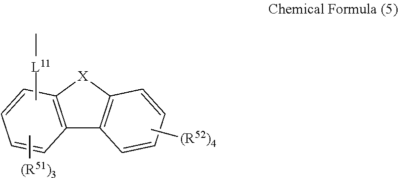

wherein in Chemical Formula (5),
L¹¹ is a single bond, a substituted or unsubstituted aromatic hydrocarbon group having 6 to 30 carbon atoms, or a substituted or unsubstituted heterocyclic ring having 3 to 30 ring-forming atoms,
R⁵¹ and R⁵² are each independently hydrogen atom, a substituted or unsubstituted alkyl group having 1 to 20 carbon atoms, a substituted or unsubstituted alkoxy group having 1 to 20 carbon atoms, a substituted or unsubstituted aromatic hydrocarbon group having 6 to 30 carbon atoms, or a substituted or unsubstituted ring heterocyclic ring having 3 to 30 ring-forming atoms, wherein R⁵¹ and R⁵² may be the same as or different from each other,
X is a group selected from —C(R⁵³)(R⁵⁴)—, O, or S, wherein R⁵³ and R⁵⁴ are each independently a substituted or unsubstituted aryl group having 6 to 30 carbon atoms, or a substituted or unsubstituted alkyl group having 1 to 20 carbon atoms, or optionally bonded to each other to form a ring structure including the carbon atom to which they are bonded.

[10] The laminate according to any one of [1] to [9] above, wherein the light emitting layer may include quantum dots having a core-shell structure.

[11] A quantum dot electroluminescent device comprising the laminate according to [10] above.

The electroluminescent device, for example, quantum dot electroluminescent device, having excellent solvent resistance and performance, such as, for example, high luminous efficiency and long luminous lifetime, can be provided.

### BRIEF DESCRIPTION OF THE DRAWINGS

FIG. 1 is a schematic diagram showing a laminate according to an exemplary embodiment.

FIG. 2 is a schematic diagram showing an electroluminescent device according to an exemplary embodiment.

### DETAILED DESCRIPTION

Hereinafter, exemplary embodiments will be described in detail so that a person skilled in the art would understand the same. The exemplary embodiments will be described more fully hereinafter with reference to the accompanying drawings, in which various embodiments are shown. This invention may, however, be embodied in many different forms, and should not be construed as limited to the embodiments set forth herein. The terminology used herein is for the purpose of describing particular embodiments only and is not intended to be limiting. As used herein, the singular forms “a,” “an,” and “the” are intended to include the plural forms, including “at least one,” unless the content clearly indicates otherwise. Therefore, reference to “an” element in a claim followed by reference to “the” element is inclusive of one element as well as a plurality of the elements.

Herein, it should be understood that terms such as “comprises,” “includes,” or “have” are intended to designate the presence of an embodied feature, number, step, element, or a combination thereof, but does not preclude the possibility of the presence or addition of one or more other features, number, step, element, or a combination thereof.

In the drawings, the thickness of layers, films, panels, regions, etc., are exaggerated for clarity and like reference numerals designate like elements throughout the specification. It will be understood that when an element such as a layer, film, region, or substrate is referred to as being “on” or “above” another element, it may be directly on the other element or intervening elements may also be present. In contrast, when an element is referred to as being “directly on” another element, there are no intervening elements present.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompass both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

In addition, “layer” herein includes not only a shape formed on the whole surface when viewed from a plan view, but also a shape formed on a partial surface.

The use of the term “the” and similar referential terms may refer to both the singular and the plural. Unless the order of the steps constituting the method is clearly stated or stated to the contrary, these steps may be performed in any appropriate order and are not necessarily limited to the order described.

The connections or connection members of lines between components shown in the drawings exemplify functional connections and/or physical or circuit connections, and in an actual device, they may be represented by a variety of alternative or additional functional, physical, or circuit connections.

As used herein, “at least one of A, B, or C,” “one of A, B, C, or any combination thereof” and “one of A, B, C, and any combination thereof” refer to each constituent element, and any combination thereof (e.g., A; B; C; A and B; A and C; B and C; or A, B, and C).

Herein, “a combination thereof” means a mixture of components, a stack, a composite, an alloy, a blend, and the like.

Hereinafter, unless otherwise defined, “substantially” or “approximately” or “about” means not only the stated value, but also the mean within an acceptable range of deviations, considering the errors associated with the corresponding measurement and the measurement of the measured value. For example, “substantially” or “approximately” can mean within ±10%, ±5%, ±3%, or ±1% or within standard deviation of the stated value,

Additionally, unless otherwise defined, operations and measurements of physical properties are performed at room temperature (greater than or equal to 20° C. and less than or equal to 25° C.) and relative humidity (RH) of greater than or equal to 40% and less than or equal to 50%.

In the present specification, “X and Y are, each independently” means that X and Y may be the same as or different from each other.

In the present specification, “a group derived from a ring” indicates a group derived from hydrolysis of hydrogen directly bonded to an atom that constitutes a ring.

In the present specification, “a ring assembly” refers to a set of two or more rings joined through a single bond. Also, “a group derived from a ring assembly” refers to a group derived from hydrolysis of hydrogen directly bonded to an atom that constitutes a ring in the ring assembly.

The laminate according to one embodiment includes a hole transport layer including a first organic compound that includes an amine-based polymer, and a second organic compound that is a liquid crystalline compound. In the hole transport layer, a domain of the second organic compound, that is, a domain of the liquid crystalline compound, is formed within a matrix of the amine-based polymer. Without wishing to be bound by theory, as the domain of the liquid crystalline compound is formed, the packing of the amine-based polymer, which is the matrix, becomes dense, and as a result, it becomes difficult for a solvent that can be used in the subsequent process to enter a gap between the organic compounds, for example, the first organic compounds, that form the hole transport layer. As a result, the penetration of the solvent on the surface of the hole transport layer may be suppressed, solubility of the hole transport layer may be decreased, and a solvent resistance of the hole transport layer may be improved. In addition, as the packing of the amine-based polymer in the hole transport layer becomes more dense, electron density in the hole transport layer increases, and thus, the hole transport may also be improved. Accordingly, an electroluminescent device including the laminate according to an embodiment may have improved luminous efficiency and a longer luminous lifetime, and thus, may exhibit excellent performance.

Meanwhile, the above mechanism is hypothetical, and its rightness or wrongness does not affect the technical scope of the present invention. Also, as for other hypotheses in the present specification, their rightness or wrongness does not affect the technical scope of the present invention.

As described above, the hole transport layer according to an embodiment of the present invention has a high solvent resistance. In the context of the present specification, a solvent resistance value (%) is defined by a ratio of the intensity of the absorption spectrum at a reference wavelength after immersing the hole transport layer in a solvent to the intensity of the absorption spectrum at a reference wavelength before immersing the hole transport layer in a solvent, i.e., {(“Intensity of the absorption spectrum at a reference wavelength after immersing the hole transport layer in a solvent”/“Intensity of the absorption spectrum at a reference wavelength before immersing the hole transport layer in a solvent”)×100(%)}, and the solvent resistance may be estimated from the value. The absorption spectrum may be measured by a UV-VIS spectroscopy.

Meanwhile, the determination of the reference wavelength and estimation of the solvent resistance value will be described in detail in the Examples.

The solvent resistance value for the hole transport layer according to an example of the present invention is not particularly limited, but may be 90% or more, for example, 93% or more, 95% or more, or 97% or more. Within the above range, a layer mixing between the hole transport layer and another layer formed on the hole transport layer may further be inhibited, even if another layer was formed on the hole transport layer by a solution coating method.

For example, if an electroluminescent device, which will be described later, is fabricated with the hole transport layer satisfying the above range by using a solution method, such as, for example, an inkjet method, the hole transport layer may be prevented from being mixed with another layer disposed thereon.

### <Laminate>

A first embodiment of the present invention is a laminate that includes a hole transport layer and a light emitting layer, wherein the hole transport layer includes a first organic compound and a second organic compound both of which have hole transport properties, the first organic compound includes an amine-based polymer, and the hole transport layer includes a domain of a liquid crystalline compound.

In the laminate according to the embodiment, the hole transport layer and the light emitting layer may be stacked adjacent to each other, or another layer may exist between the hole transport layer and the light emitting layer. For example, the light emitting layer may be formed in contact with the hole transport layer.

The laminate according to the embodiment may further include a layer, in addition to the hole transport layer and the light emitting layer. The additional layer may be, for example, an electron transport layer. In other words, the laminate according to an embodiment may include a hole transport layer, an electron transport layer, and a light emitting layer sandwiched between the hole transport layer and the electron transport layer.

In an exemplary embodiment, the laminate may further include a pair of electrodes. In this case, the laminate that includes a hole transport layer, an electron transport layer, and a light emitting layer interposed between the hole transport layer and the electron transport layer may be disposed between a pair of the electrodes to form an electroluminescent device.

First, the hole transport layer and the light emitting layer of the laminate according to one embodiment will be described.

### [Hole Transport Layer]

The hole transport layer is a layer that has a function of transporting holes.

The hole transport layer according to an embodiment includes a first organic compound and a second organic compound both of which have hole transport properties, the first organic compound includes an amine-based polymer, the second organic compound is a liquid crystalline compound, and the hole transport layer has a domain of the liquid crystalline compound.

“The hole transport layer has a domain of the liquid crystalline compound” means that the domain of the liquid crystalline compound is formed within a matrix of the amine-based polymer contained in the first organic compound. The domain of the liquid crystalline compound may be formed by appropriately selecting and combining heat treatment conditions (temperature, time, etc.) for forming the hole transport layer, type of the second organic compound, amount of the second organic compound, and the like.

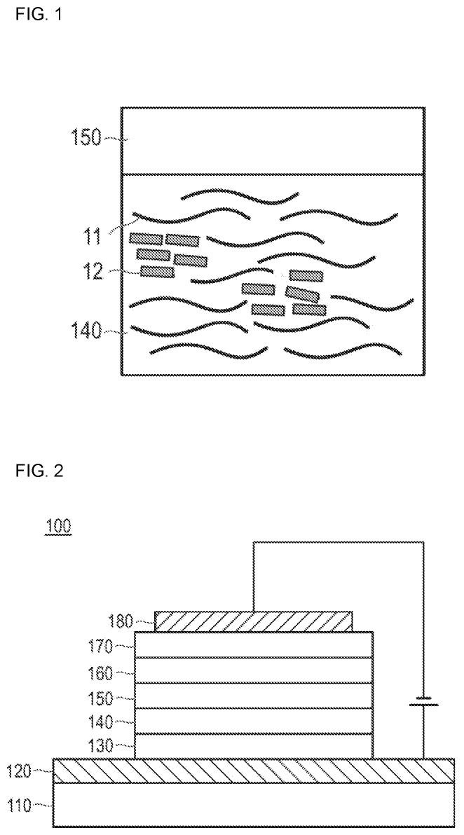

FIG. 1 is a schematic diagram of a laminate according to an exemplary embodiment.

As shown in FIG. 1, a laminate includes a hole transport layer 140 and a light emitting layer 150. In the hole transport layer 140, a domain may be formed by association of the liquid crystalline compound 12 in a matrix of amine-based polymer 11. Here, the packing of the amine-based polymer 11 becomes dense as the liquid crystalline compound 12 forms a domain within the hole transport layer 140. The domain of the liquid crystalline compound 12 may be identified by observing a cross-section of the hole transport layer using a scanning electron microscope (SEM) or transmission electron microscope (TEM). In addition, whether or not a domain is formed can be determined by, for example, the solvent resistance, as shown in the example. An average size of the domain may be greater than or equal to about 2 nanometers (nm), or for example, greater than or equal to about 3 nanometers (nm). For example, when forming the hole transport layer according to an embodiment, if curing (heat treatment) of the liquid crystalline compound is performed in a liquid crystalline temperature range, the obtained cured product, i.e., the hole transport layer, may have a solvent resistance value of 90% or more, for example, 93% or more, 95% or more, or 97% or more, whereby it can be determined that the domain is formed.

The hole transport layer according to an embodiment may be formed by using a solution coating method (also referred to as ‘wet process’). Therefore, the hole transport layer according to an embodiment may be formed by using a solution of the amine-based polymer and the second organic compound. In this case, the solvent resistance of the hole transport layer may further be improved. In addition, durability (luminescence lifespan) of an electroluminescent device including the hole transport layer may be extended. Also, it may be possible to improve the luminous efficiency of an electroluminescent device including the hole transport layer. Again, as the hole transport layer may be formed by the coating method, a large-area layer may efficiently be made.

### <First Organic Compound>

The first organic compound included in the hole transport layer according to one embodiment may be an amine-based polymer.

The amine-based polymer may be any polymer obtained by polymerizing a monomer having an amino group, and may, for example, be a polymer including a structural unit represented by any one of Chemical Formula (1), (2), or (3):

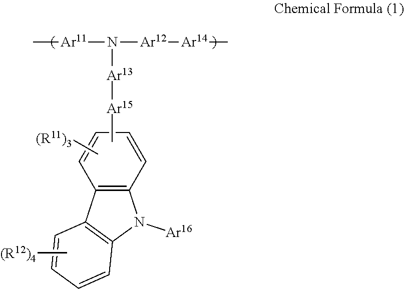

wherein in Chemical Formula (1),
Ar¹¹ and Ar¹² may each independently be a substituted or unsubstituted aromatic hydrocarbon group having 6 to 60 carbon atoms,
Ar¹³ may be a substituted or unsubstituted aromatic hydrocarbon group having 6 to 120 carbon atoms,
Ar¹⁴ may be a substituted or unsubstituted aromatic hydrocarbon group having 6 to 60 carbon atoms, or a substituted or unsubstituted heterocyclic ring having 3 to 60 ring-forming atoms,
Ar¹⁵ may be a single bond, or a substituted or unsubstituted heterocyclic ring having 3 to 60 ring-forming atoms,
Ar¹⁶ may be a substituted or unsubstituted aromatic hydrocarbon group having 6 to 60 carbon atoms, or a substituted or unsubstituted heterocyclic ring having 3 to 60 ring-forming atoms,
R¹¹ is independently a hydrogen atom, an alkyl group, a hydroxyalkyl group, an alkoxy group, an alkoxyalkyl group, an alkenyl group, an alkynyl group, an alkylthio group, an alkoxy carbonyl group, a hydroxyl group (—OH), a carboxyl group (—COOH), a thiol group (—SH), or a cyano group (—CN), and
R¹² is independently a hydrogen atom, an alkyl group, a hydroxyalkyl group, an alkoxy group, an alkoxyalkyl group, an alkenyl group, an alkynyl group, an alkylthio group, an alkoxy carbonyl group, a hydroxyl group (—OH), a carboxyl group (—COOH), a thiol group (—SH), or a cyano group (—CN);

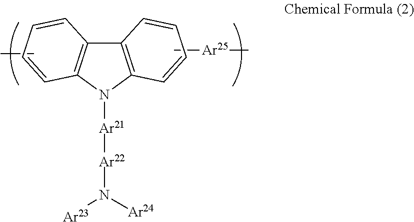

wherein in Chemical Formula (2),
Ar²¹ may be a substituted or unsubstituted aromatic hydrocarbon group having 6 to 120 carbon atoms,
Ar²² may be a single bond, or a substituted or unsubstituted heterocyclic ring having 3 to 60 ring-forming atoms,
Ar²³ and Ar²⁴ may each independently be a substituted or unsubstituted aromatic hydrocarbon group having 6 to 25 carbon atoms, or a substituted or unsubstituted heterocyclic ring having 3 to 60 ring-forming atoms, and
Ar²⁵ may be a substituted or unsubstituted aromatic hydrocarbon group having 6 to 60 carbon atoms, or a substituted or unsubstituted heterocyclic ring having 3 to 60 ring-forming atoms,

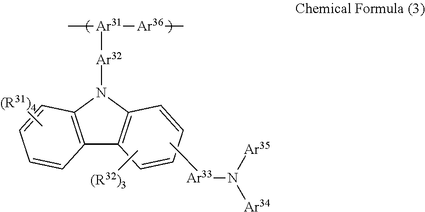

wherein in Chemical Formula (3),
Ar³¹ may be a substituted or unsubstituted aromatic hydrocarbon group having 6 to 60 carbon atoms,
Ar³² and Ar³³ may each independently be a substituted or unsubstituted aromatic hydrocarbon group having 6 to 120 carbon atoms,
Ar³⁴ and Ar³⁵ may each independently be a substituted or unsubstituted aromatic hydrocarbon group having 6 to 60 carbon atoms, or a substituted or unsubstituted heterocyclic ring having 3 to 60 ring-forming atoms,
Ar³⁶ may be a substituted or unsubstituted aromatic hydrocarbon group having 6 to 60 carbon atoms, or a substituted or unsubstituted heterocyclic ring having 3 to 60 ring-forming atoms,
R³¹ may each independently be a hydrogen atom, an alkyl group, a hydroxyalkyl group, an alkoxy group, an alkoxyalkyl group, an alkenyl group, an alkynyl group, an alkylthio group, an alkoxy carbonyl group, a hydroxyl group (—OH), a carboxyl group (—COOH), a thiol group (—SH), or a cyano group (—CN), and
R³² may each independently be a hydrogen atom, an alkyl group, a hydroxyalkyl group, an alkoxy group, an alkoxyalkyl group, an alkenyl group, an alkynyl group, an alkylthio group, an alkoxy carbonyl group, a hydroxyl group (—OH), a carboxyl group (—COOH), a thiol group (—SH), or a cyano group (—CN).

In Chemical Formulae (1) to (3), the aromatic hydrocarbon group having 6 to 60 carbon atoms that may constitute Ar¹¹, Ar¹², Ar¹⁴, Ar¹⁶, Ar²⁵, Ar³¹, Ar³⁴, Ar³⁵ or Ar³⁶ is not particularly limited.

In Chemical Formulae (1) to (3), the aromatic hydrocarbon group having 6 to 120 carbon atoms, or for example, the aromatic hydrocarbon group having 6 to 60 carbon atoms, that may constitute Ar¹³, Ar²¹, Ar³², or Ar³³ is not particularly limited.

In Chemical Formula (2), the aromatic hydrocarbon group having 6 to 25 carbon atoms, or for example, the aromatic hydrocarbon group having 6 to 20 carbon atoms, that may constitute Ar²³ or Ar²⁴ is not particularly limited.

In Chemical Formulae (1) and (3), the aromatic hydrocarbon group having 6 to 60 carbon atoms that may constitute Ar¹⁶, Ar³⁴ or Ar³⁵ is not particularly limited.

Examples of the aromatic hydrocarbon groups that may constitute Ar¹¹ to Ar¹⁴, Ar¹⁶, Ar²¹, Ar²³ to Ar²⁵, and Ar³¹ to Ar³⁶ include, for example, aromatic hydrocarbon ring groups derived from benzene (phenylene group), indene, naphthalene, anthracene, azulene, heptalene, acenaphthene, phenalene, fluorene, phenanthrene, pyrene, and the like, and groups derived from ring assemblies of 2 or more aromatic hydrocarbon rings linked by a sing bond, such as, for example, a biphenyl (biphenylene) group, a terphenyl (terphenylene) group, a quarterphenyl (quarterphenylene) group, a quinquephenyl (quinquephenylene) group, a sexyphenyl (sexyphenylene group) group, and the like.

Each of Ar¹¹ to Ar¹⁴, Ar¹⁶, Ar²¹, Ar²³ to Ar²⁵, and Ar³¹ to Ar³⁶ may be selected from the exemplified groups depending on the number of carbon atoms determined for each group.

Meanwhile, in the present specification, a hydrocarbon ring that contains an aromatic hydrocarbon ring part, such as, for example, fluorene, may also be referred to as an aromatic hydrocarbon ring.

In Chemical Formulae (1) to (3), the aromatic heterocyclic ring group having 3 to 60 ring-forming atoms that may constitute Ar¹⁴, Ar¹⁵, Ar¹⁶, Ar²², Ar²⁵, Ar³⁴, Ar³⁵ or Ar³⁶ is not particularly limited.

In Chemical Formula (2), the aromatic heterocyclic ring group having 3 to 25 ring-forming atoms that may constitute Ar²³ or Ar²⁴ is not particularly limited.

Examples of the aromatic heterocyclic ring groups that may constitute Ar¹⁴ to Ar¹⁶, Ar²² to Ar²⁵, and Ar³⁴ to Ar³⁶ include a group derived from an aromatic heterocyclic ring, such as, for example, acridine, phenazine, benzoquinoline, benzoisoquinoline, phenanthridine, phenanthroline, anthraquinone, fluorenone, dibenzofuran, dibenzothiophene, carbazole, imidazophenanthridine, benzimidazophenanthridine, azadibenzofuran, azacarbazole, azadibenzothiophene, diazadibenzofuran, diazacarbazole, diazadibenzothiophene, xanthone, thioxanthone, pyridine, quinoline, anthraquinoline, and the like, and a group derived from a ring assembly containing 2 or more aromatic heterocyclic rings linked by a single bond, such as, for example, bipyridine, bipyrimidine, bipyrazine, and the like.

Meanwhile, in the present specification, a heterocyclic ring containing an aromatic ring, such as, for example, dibenzofuran, dibenzothiophene, carbazole, and the like, may also be referred to as an aromatic heterocyclic ring.

In addition, in the present specification, the aromatic heterocyclic ring may also include a ring that contains an hetero atom bonded to an atom that directly consists a ring via a double bond.

If Ar¹¹ to Ar¹⁶, Ar²¹ to Ar²⁵, and Ar³¹ to Ar³⁶ are groups substituted with a substituent, number of the substituent introduced to the groups is not particularly limited. The number of substituent introduced to the groups, Ar¹¹ to Ar¹⁶, Ar²¹ to Ar²⁵, and Ar³¹ to Ar³⁶, may each independently be, for example, 1 or more and 3 or less, for example, 1 or more and 2 or less, or, for example, 1 or less.

If Ar¹¹ to Ar¹⁶, Ar²¹ to Ar²⁵, and Ar³¹ to Ar³⁶ are groups substituted with a substituent, the type of the substituent is not particularly limited. The substituent of Ar¹¹ to Ar¹⁶, Ar²¹ to Ar²⁵, and Ar³¹ to Ar³⁶ may include, for example, an alkyl group, a hydroxyalkyl group, an alkoxy group, an alkoxyalkyl group, an alkenyl group, an alkynyl group, an alkylthio group, an alkoxy carbonyl group, an hydroxyl group (—OH), a carboxyl group (—COOH), a thiol group (—SH), a cyano group (—CN), a halogen group, and the like.

If Ar¹¹ to Ar¹⁶, Ar²¹ to Ar²⁵, and Ar³¹ to Ar³⁶ are groups substituted with a substituent, the substituents may be the same as or different from each other. If each of the groups, Ar¹¹ to Ar¹⁶, Ar²¹ to Ar²⁵, and Ar³¹ to Ar³⁶, is substituted with two or more substituents, the two or more of substituents may be the same as or different from each other.

In Chemical Formulae (1) to (3), the alkyl group that may constitute each of R¹¹, R¹², R³¹, and R³² is not particularly limited. The number of carbon atoms of the alkyl group is not particularly limited, but may be, for example, 1 to 20.

The alkyl group is not particularly limited and may be linear, branched, or cyclic. For example, the alkyl group may include methyl group, ethyl group, n-propyl group, isopropyl group, n-butyl group, isobutyl group, sec-butyl group, tert-butyl group, n-pentyl group, isopentyl group, tert-pentyl group. group, neopentyl group, 1,2-dimethyl propyl group, n-hexyl group, isohexyl group, 1,3-dimethylbutyl group, 1-isopropyl propyl group, 1,2-dimethylbutyl group, n-heptyl group, 1,4-dimethyl pentyl group, 3-ethyl pentyl group, 2-methyl-1-isopropyl propyl group, 1-ethyl-3-methyl butyl group, n-octyl group, 2-ethylhexyl group, 3-methyl-1-isopropyl butyl group, 2-methyl-1-isopropyl group, 1-tert-butyl-2-methyl propyl group, n-nonyl group, 3,5,5-trimethylhexyl group, n-decyl group, isodecyl group, n-undecyl group, 1-methyldecyl group, n-dodecyl group, n-tridecyl group, n-tetradecyl group, n-pentadecyl group, n-hexadecyl group, n-heptadecyl group, n-octadecyl group, cyclopropyl group, cyclobutyl group, cyclopentyl group, cyclohexyl group, and the like.

In Chemical Formulae (1) to (3), the hydroxyalkyl group that may constitute each R¹¹, R¹², R³¹, and R³² is not particularly limited, but may include an alkyl group substituted with 1 or more and 3 or less hydroxy groups, for example, 1 or more and 2 or less hydroxy groups, or for example, 1 hydroxy group, such as, for example, hydroxy methyl group, hydroxy ethyl group, and the like.

In Chemical Formulae (1) to (3), the alkoxy group is not particularly limited, but may include, for example, methoxy group, ethoxy group, propoxy group, isopropoxy group, butoxy group, pentyloxy group, hexyloxy group, heptyloxy group, octyloxy group, nonyloxy group, decyloxy group, undecyloxy group, dodecyloxy group, tridecyloxy group, tetradecyloxy group, pentadecyloxy group, hexadecyloxy group, heptadecyloxy group, octadecyloxy group, 2-ethylhexyloxy group, 3-ethylpentyloxy group, cyclopropyloxy group, cyclobutyloxy group, cyclopentyloxy group, cyclohexyloxy group, and the like.

In Chemical Formulae (1) to (3), the alkoxyalkyl group that may constitute each of R¹¹, R¹², R³¹, and R³² is not particularly limited, but may include an alkyl group substituted with, for example, 1 or more and 3 or less, for example, 1 or more and 2 or less, or for example, 1 of the above alkoxy group.

In Chemical Formulae (1) to (3), the alkenyl group that may constitute each of R¹¹, R¹², R³¹, and R³² is not particularly limited, but may include, for example, vinyl group, allyl group, 1-propenyl group, isopropenyl group, 1-butenyl group, 2-butenyl group, 3-butenyl group, 1-pentenyl group, 2-pentenyl group, 3-pentenyl group, 1-hexenyl group, 2-hexenyl group, 3-hexenyl group, 1-heptenyl group, 2-heptenyl group, 5-heptenyl group, 1-octenyl group, 3-octenyl group, 5-octenyl group, 1,3-butadienyl group, and the like.

In Chemical Formulae (1) to (3), the alkynyl group is not particularly limited, but may include, for example, acetylenyl group (ethynyl group), 1-propynyl group, 2-propynyl group (propargyl group), 1-butynyl group, 2-butynyl group, 3-butynyl group, 1-pentynyl group, 2-pentynyl group, 3-pentynyl group, 1-hexynyl group, 2-hexynyl group, 3-hexynyl group, 1-heptynyl group, 2-heptynyl group, 5-heptynyl group, 1-octynnyl group, 3-octynnyl group, 5-octynyl group, and the like.

In Chemical Formulae (1) to (3), the alkylthio group that may constitute each of R¹¹, R¹², R³¹, and R³² is not particularly limited, but may include, for example, methylthio group, ethylthio group, propylthio group, pentylthio group, hexylthio group, octylthio group, dodecylthio group, cyclopentylthio group, cyclohexylthio group, and the like.

In Chemical Formulae (1) to (3), the alkoxy carbonyl group may constitute each of R¹¹, R¹², R³¹, and R³² is not particularly limited, but may include, for example, methoxy carbonyl group, ethoxy carbonyl group, butyl oxycarbonyl group, octyl oxycarbonyl group, dodecyl oxycarbonyl group, and the like.

In Chemical Formulae (1) to (3), the halogen group that may constitute each of R¹¹, R¹², R³¹, and R³² is not particularly limited, but may include, for example, a fluoro group, a chloro group, a bromo group and an iodine group.

Meanwhile, in Chemical Formulae (1) to (3), the alkyl group, hydroxyalkyl group, alkoxy group, alkoxyalkyl group, alkenyl group, alkynyl group, alkylthio group, alkoxy carbonyl group, and halogen group that may constitute each of R¹¹, R¹², R³¹, and R³² may also be applied to the substituent that may be substituted to any of Ar¹¹ to Ar¹⁶, Ar²¹ to Ar²⁵, and Ar³¹ to Ar³⁶.

For example, Ar¹¹, Ar¹², and Ar¹³ may each independently be a substituted or unsubstituted aromatic hydrocarbon group having 6 to 40 carbon atoms, a substituted or unsubstituted aromatic hydrocarbon group having 6 to 20 carbon atoms, or an unsubstituted aromatic hydrocarbon group having 6 to 20 carbon atoms.

For example, Ar¹¹, Ar¹², and Ar¹³ may each independently be a group derived from an aromatic hydrocarbon ring, such as, for example, a phenylene group, naphthalene, anthracene, phenalene, fluorene, phenanthrene, pyrene, and the like, or a group derived from a ring assembly containing 2 or more aromatic hydrocarbon rings linked by a single bond, such as, for example, biphenyl (biphenylene) group, terphenyl (terphenylene) group, quarterphenyl (quartephenylene) group, and the like, and they may each independently be a phenylene group, or a biphenyl (biphenylene) group.

For example, Ar¹⁴ may be a substituted or unsubstituted aromatic hydrocarbon group having 6 to 60 carbon atoms, for example, a substituted aromatic hydrocarbon group having 6 to 40 carbon atoms, or for example, a substituted aromatic hydrocarbon group having 6 to 20 carbon atoms.

For example, Ar¹⁴ may be a group derived from an aromatic hydrocarbon ring, such as, for example, a substituted phenylene group, a substituted naphthalene, a substituted anthracene, a substituted phenalene, a substituted fluorene, a substituted phenanthrene, a substituted pyrene, and the like, or a group derived from an aromatic hydrocarbon ring, such as, for example, a substituted phenylene group, a substituted naphthalene, or a substituted fluorene. For example, Ar¹⁴ may be a substituted fluorene group. In this case, a substituent that substitutes the aromatic hydrocarbon group may, for example, be an alkyl group having 2 to 20 carbon atoms, or for example, an alkyl group having 5 to 15 carbon atoms.

Ar¹⁵ may be a single bond.

For example, Ar¹⁶ may be a substituted or unsubstituted aromatic hydrocarbon group having 6 to 60 carbon atoms, for example, a substituted or unsubstituted aromatic hydrocarbon group having 6 to 40 carbon atoms, or for example, a substituted or unsubstituted aromatic hydrocarbon group having 6 to 20 carbon atoms.

For example, Ar¹⁶ may be a group derived from an aromatic hydrocarbon ring, such as, for example, a substituted or unsubstituted benzene (phenylene group), substituted or unsubstituted indene, substituted or unsubstituted naphthalene, substituted or unsubstituted anthracene, substituted or unsubstituted fluorene, substituted or unsubstituted phenanthrene, substituted or unsubstituted pyrene, and the like; or a group derived from a ring assembly containing 2 or more aromatic hydrocarbon rings linked by a single bond, such as, for example, a substituted or unsubstituted biphenyl (biphenylene group), a substituted or unsubstituted terphenyl (terphenylene) group, a substituted or unsubstituted quarter phenyl (quarterphenylene) group, a substituted or unsubstituted quinquephenyl (quinquephenylene) group, and the like.

In an exemplary embodiment, Ar¹⁶ may be a group derived from a ring assembly containing 2 or more aromatic hydrocarbon rings linked by a single bond, such as, for example, a substituted or unsubstituted biphenyl (biphenylene) group, a substituted or unsubstituted terphenyl (terphenylene) group, a substituted or unsubstituted quarterphenyl (quarterphenylene) group, a substituted or unsubstituted quinquephenyl (quinquephenylene) group, or for example, a substituted or unsubstituted biphenyl (biphenylene) group, a substituted or unsubstituted terphenyl (terphenylene) group, or a substituted or unsubstituted quarterphenyl (quarterphenylene) group. In this case, the substituent that substitutes the aromatic hydrocarbon group may be an alkyl group having 2 to 15 carbon atoms, or for example, an alkyl group having 3 to 10 carbon atoms.

In an exemplary embodiment, the amine-based polymer according to an embodiment may include a structural unit represented by Chemical Formula (1), in which Ar¹³ may be selected from Group I below.

In Chemical Formula (1), Ar¹³ may be selected from Group I below, and Ar¹⁵ may be a single bond.

In Chemical Formula (1), Ar¹³ may be represented by any one of Chemical Formula 1-1 or Chemical Formula 1-4 below, and Ar¹⁵ may be a single bond.

In Chemical Formula (1), Ar¹³ may be represented by Chemical Formula 1-1 below, and Ar¹⁵ may be a single bond.

In Chemical Formula (1), Ar¹³ may be a phenylene group, and Ar¹⁵ may be a single bond.

In Chemical Formula (1), Ar¹³ may be a p-phenylene group, and Ar¹⁵ may be a single bond.

According to these structures, an electroluminescent device including a laminate according to an embodiment, for example, a quantum dot electroluminescent device may have further improved lifespan.

In an exemplary embodiment, in Chemical Formula (1), Ar¹³ may be selected from Group I below, Ar¹¹, Ar¹², and Ar¹⁴ may be selected from Group II below, and Ar¹⁶ may be selected from Group III below.

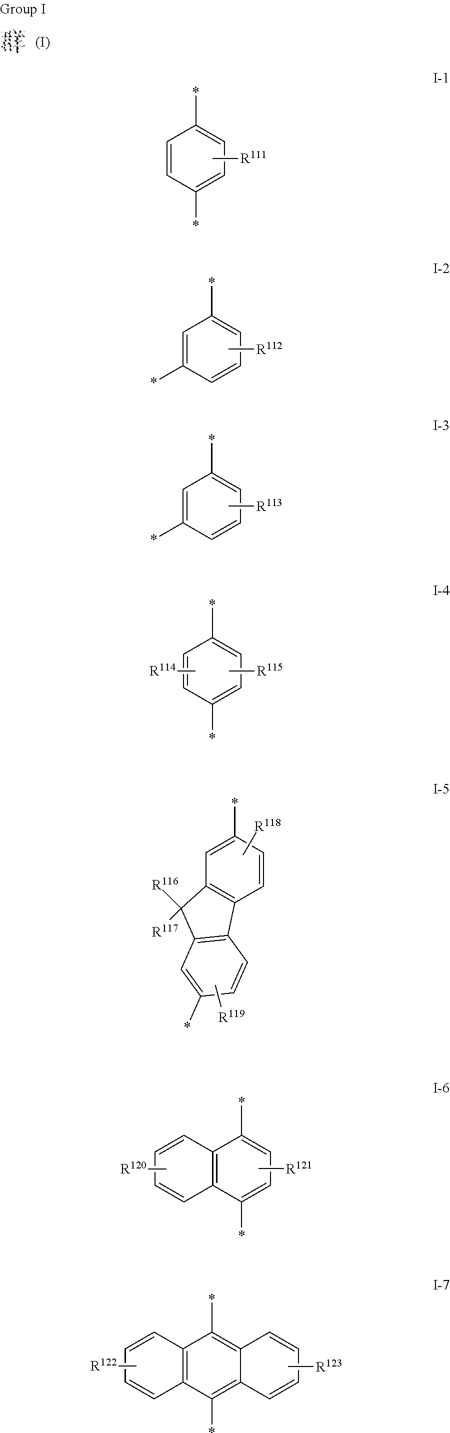

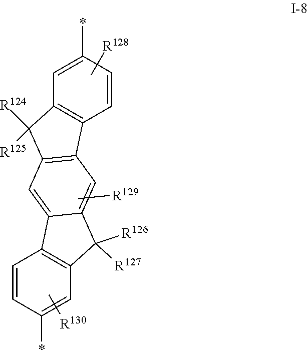

In Group I,
R¹¹¹ to R¹³⁰ may each independently be a hydrogen atom, or a linear or branched hydrocarbon group having 1 to 18 carbon atoms, and
* indicates the bonding position with an adjacent atom.

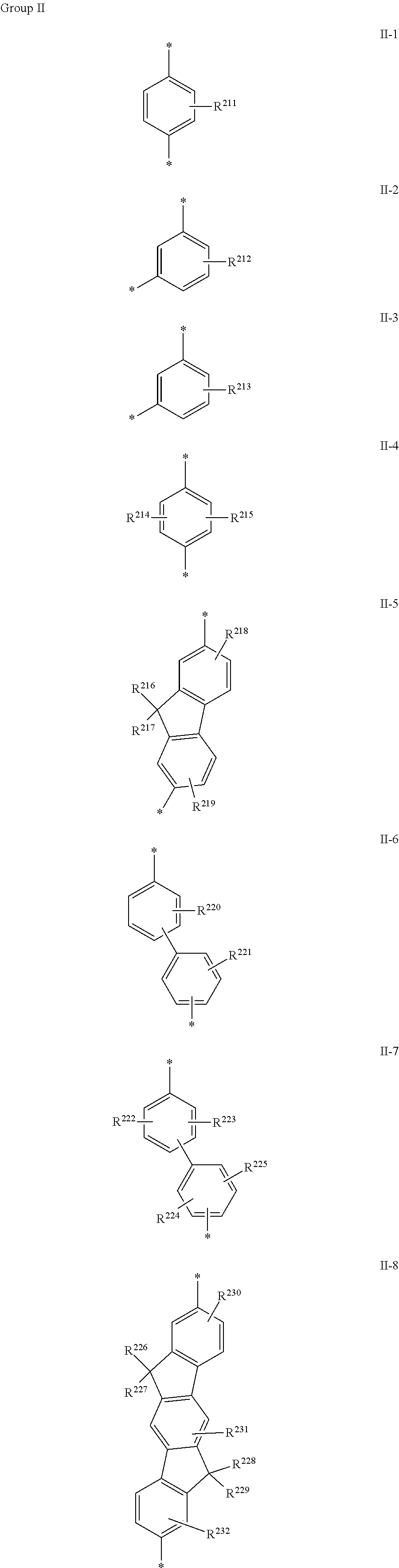

In Group II,
R²¹¹ to R²³² may each independently be a hydrogen atom, or a linear or branched hydrocarbon group having 1 to 18 carbon atoms, and
* indicates the bonding position with an adjacent atom.

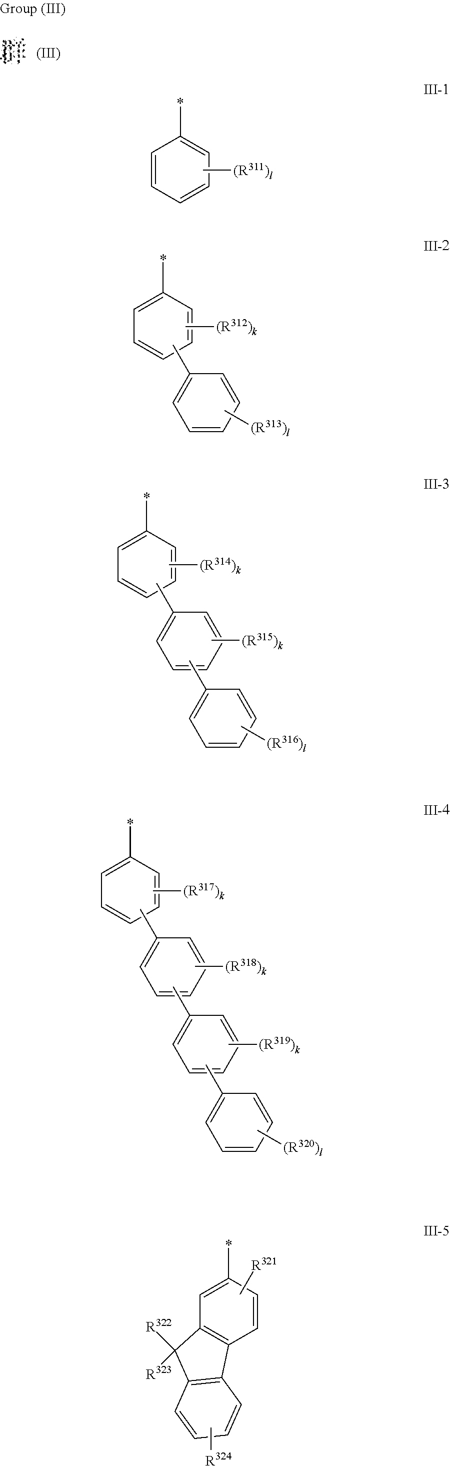

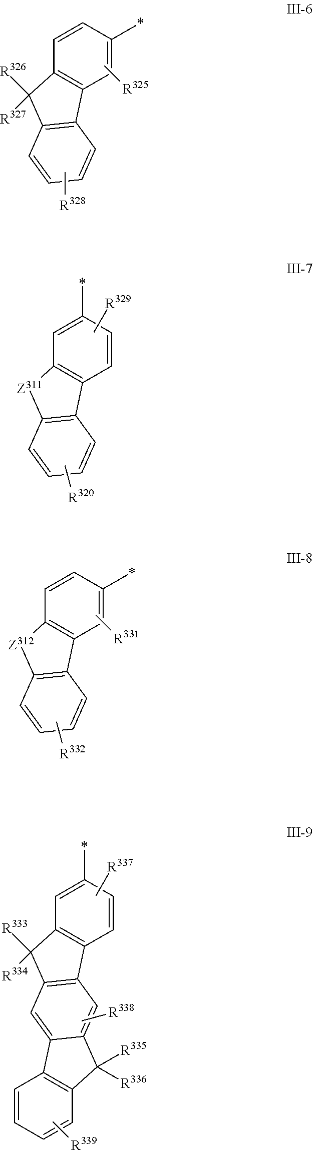

In Group III,
R³¹¹ to R³³⁹ may each independently be an hydrogen atom, or a linear or branched hydrocarbon group having 1 to 18 carbon atoms,
Z³¹¹ and Z³¹² may each independently be an oxygen atom or a sulfur atom,
k is an integer of 0 to 4,
l is an integer of 0 to 5, and
* indicates the bonding position with an adjacent atom.

In Chemical Formula (2), Ar²³ and Ar²⁴ may be selected from Group IV below, and Ar²⁵ may be selected from Group II above.

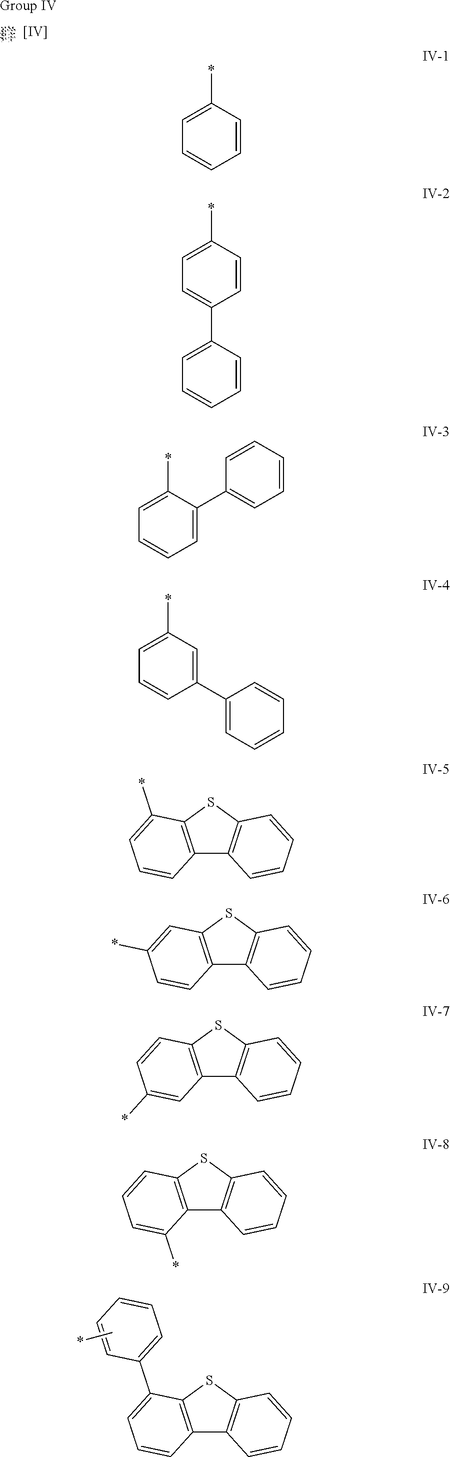

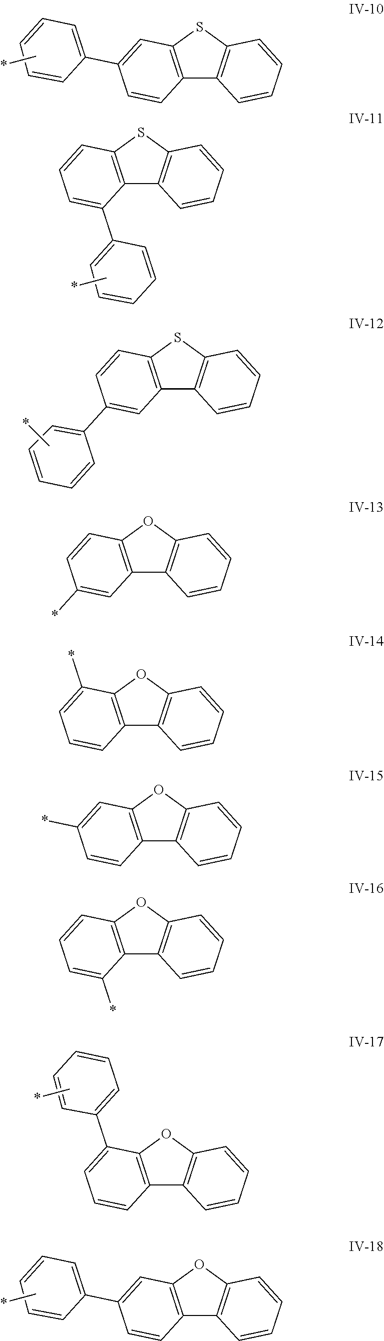

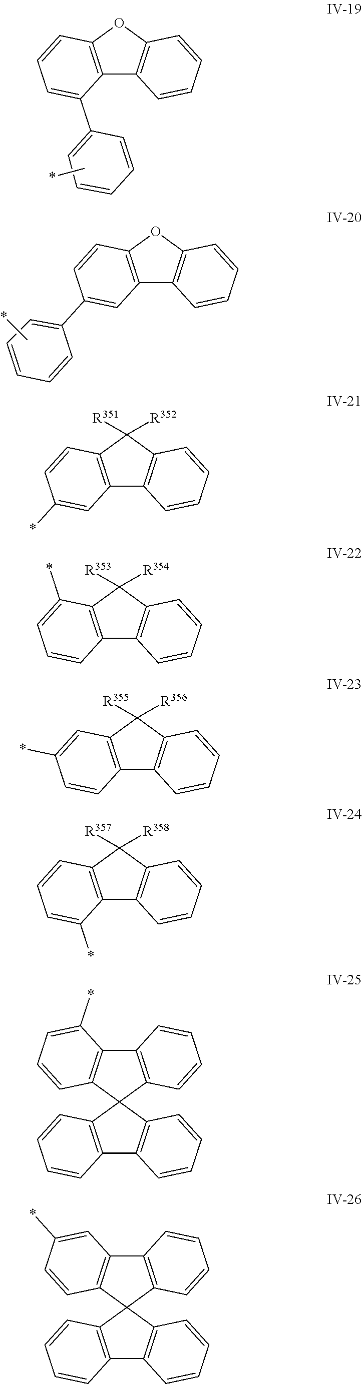

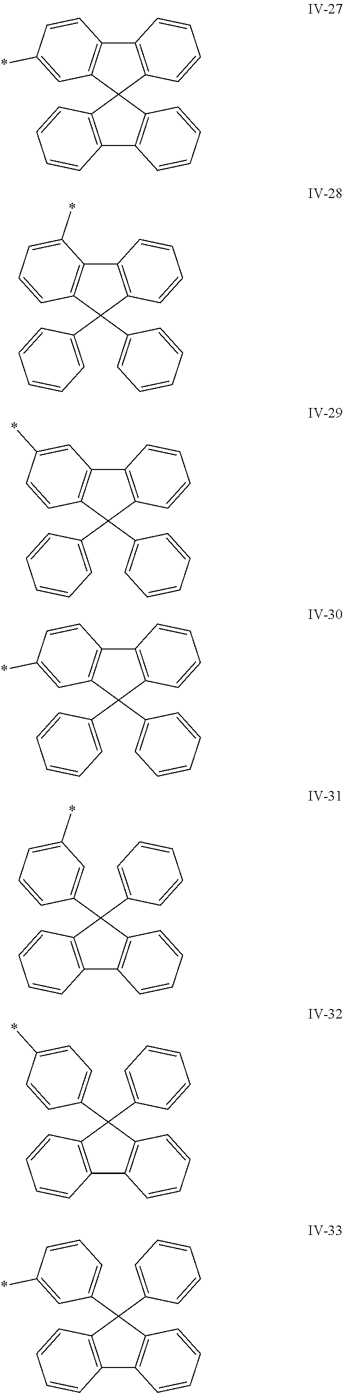

The structural unit represented by Chemical Formula (3) may be selected from Group V below.

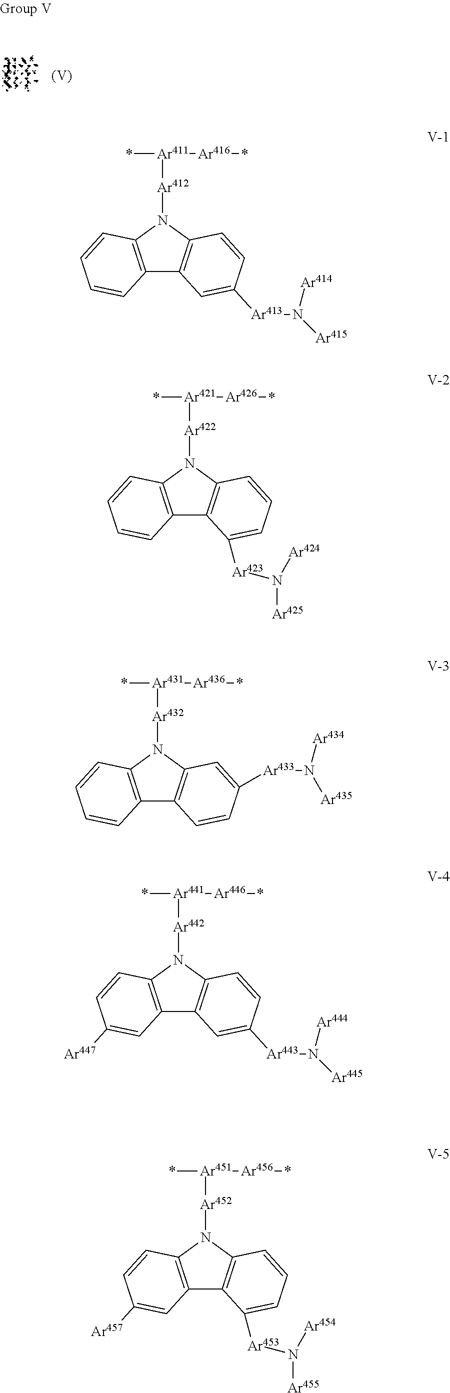

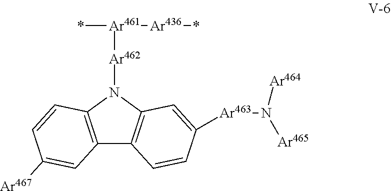

In Group V,
Ar⁴¹¹, Ar⁴²¹, Ar⁴³¹, Ar⁴⁴¹, Ar⁴⁵¹, and Ar⁴⁶¹ may each independently be a substituted or unsubstituted aromatic hydrocarbon group having 6 to 60 carbon atoms,
Ar⁴¹², Ar⁴²², Ar⁴³², Ar⁴², Ar⁴⁵², and Ar⁴⁶², and Ar⁴¹³, Ar⁴²³, Ar⁴³³, Ar⁴⁴³, Ar⁴⁵³, and Ar⁴⁶³ may each independently be a substituted or unsubstituted aromatic hydrocarbon group having 6 to 120 carbon atoms,
Ar⁴¹⁴, Ar⁴²⁴, Ar⁴³⁴, Ar⁴, Ar⁴⁵⁴, Ar⁴⁶⁴, Ar⁴¹⁵, Ar⁴²⁵, Ar⁴³⁵, Ar⁴⁴⁵, Ar⁴⁵⁵, and Ar⁴⁶⁵ may each independently be a group selected from Group IV above,
Ar⁴¹⁶, Ar⁴²⁶, Ar⁴³⁶, Ar⁴⁶, Ar⁴⁵⁶, and Ar⁴⁶⁶ may each independently be a group selected from Group II above,
Ar⁴⁴⁷, Ar⁴⁵⁷, and Ar⁴⁶⁷ may each independently be a hydrogen atom, or a linear or branched hydrocarbon group having 1 to 18 carbon atoms, and
* indicates the bonding position with an adjacent atom.

In an exemplary embodiment, in Chemical Formula (1), Ar¹³ may be selected from Group I, Ar¹¹ and Ar¹² may each independently be selected from Group II, and Ar¹⁴ may be a group represented by Chemical Formula (5).

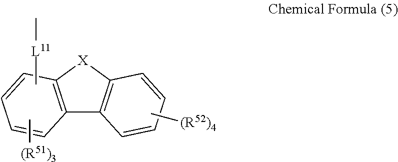

In Chemical Formula (5),
L¹¹ may be a single bond, a substituted or unsubstituted aromatic hydrocarbon group having 6 to 30 carbon atoms, or a substituted or unsubstituted aromatic heterocyclic ring having 3 to 30 ring-forming atoms,
R⁵¹ and R⁵² may be the same as or different from each other, and may each independently be a hydrogen atom, a substituted or unsubstituted alkyl group having 1 to 20 carbon atoms, a substituted or unsubstituted alkoxy group having 1 to 20 carbon atoms, a substituted or unsubstituted aromatic hydrocarbon group having 6 to 30 carbon atoms, or a substituted or unsubstituted aromatic heterocyclic ring having 3 to 30 ring-forming atoms,
X may be —C(R⁵³)(R⁵⁴)—, —O—, or —S—, wherein, R⁵³ and R⁵⁴ may each independently be a substituted or unsubstituted aryl group having 6 to 30 carbon atoms, or a substituted or unsubstituted alkyl group having 1 to 20 carbon atoms, which may optionally be bonded to each other to form a ring structure along with the carbon atom to R⁵³ and R⁵⁴ are bonded.

The amine-based polymer according to an embodiment of the present invention may include one or more structural units selected from Group A below. In an exemplary embodiment, the structural unit represented by Chemical Formula (1) contained in the polymer may be one or more types of structural units selected from Group A below.

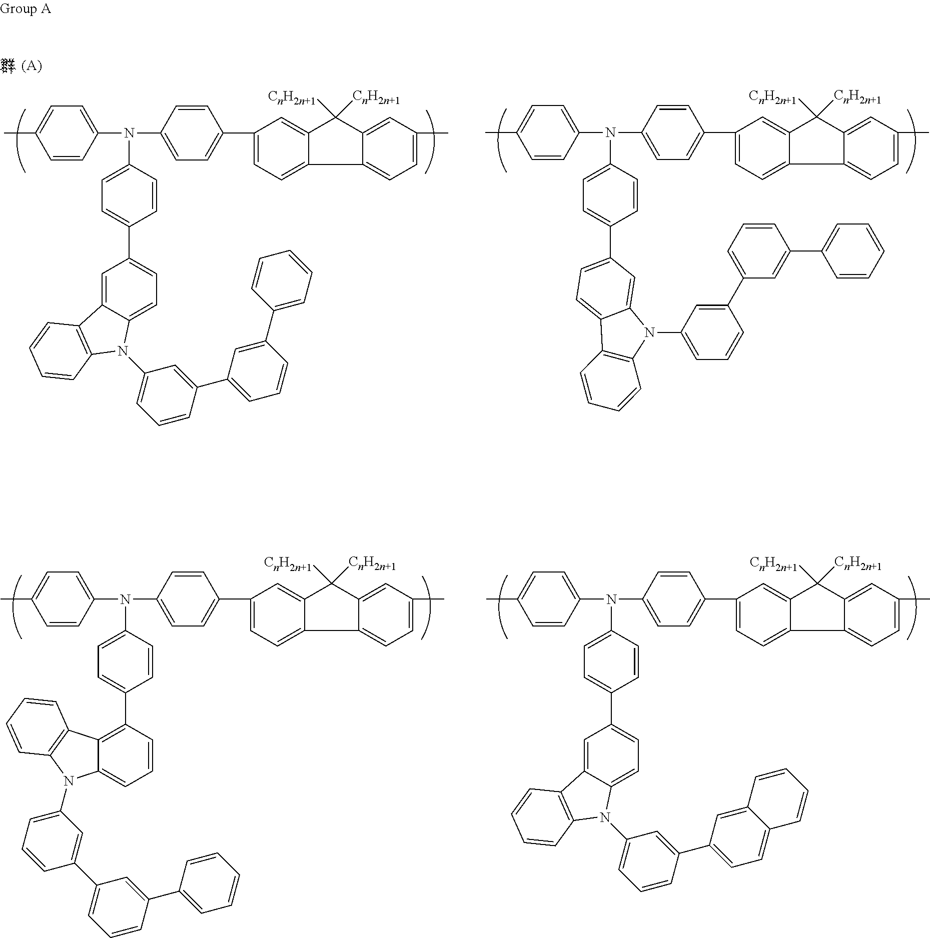

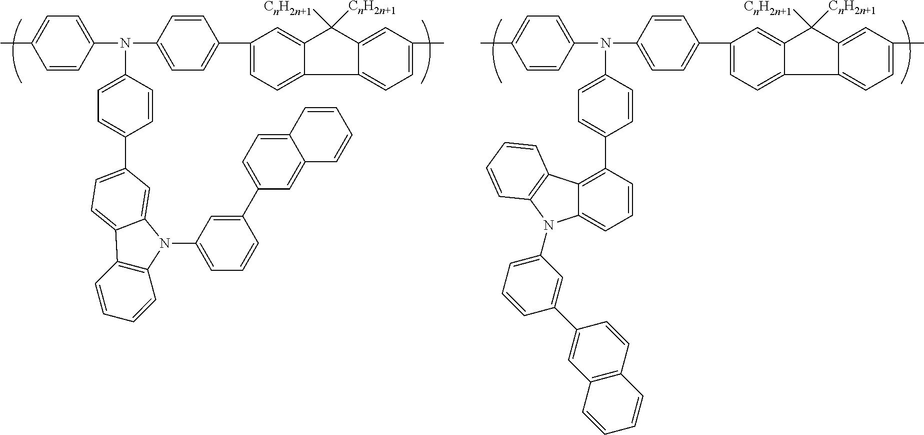

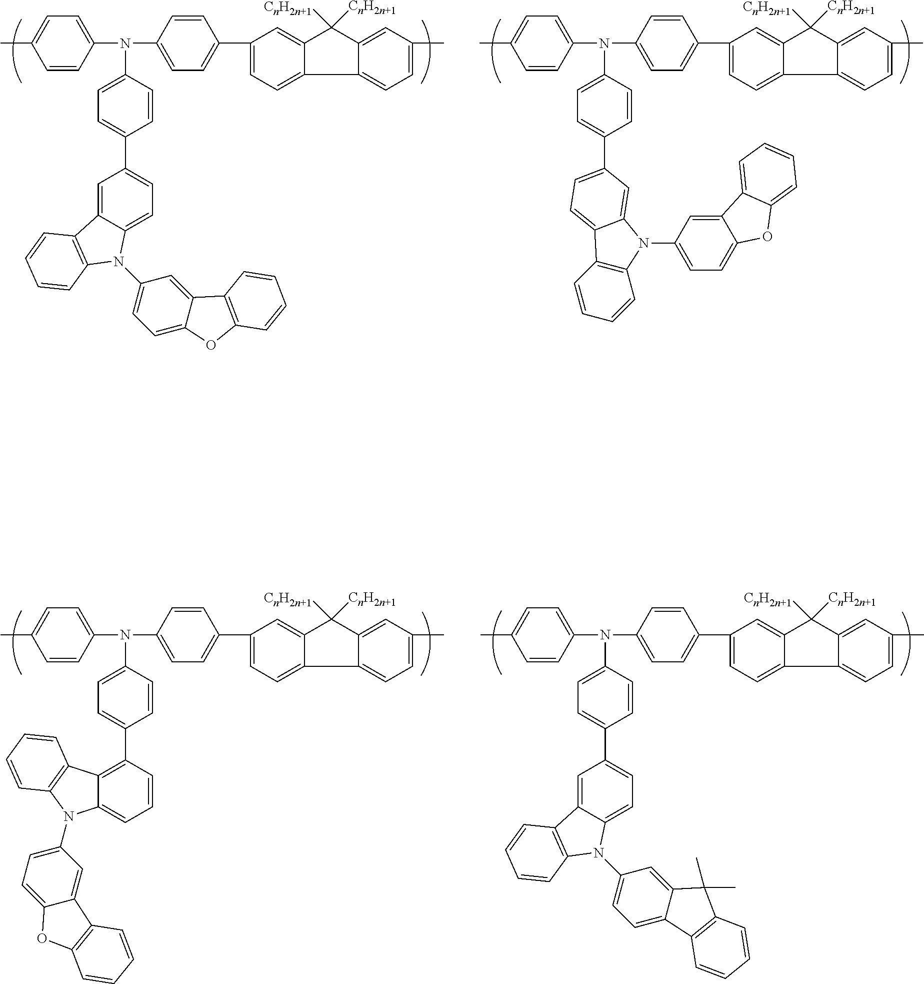

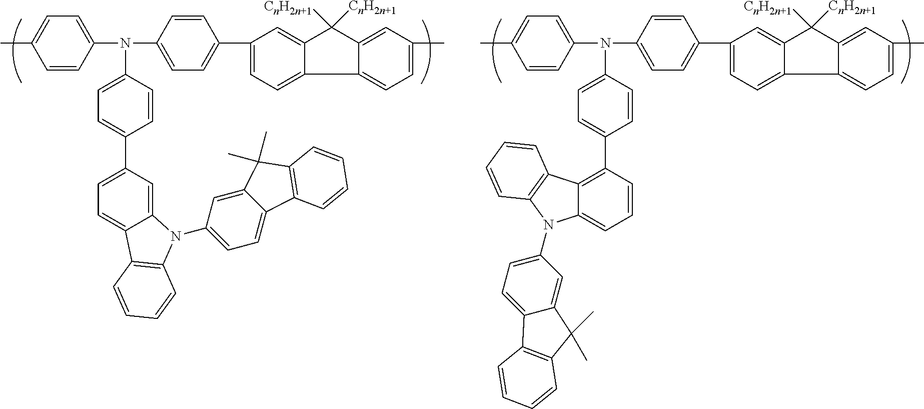

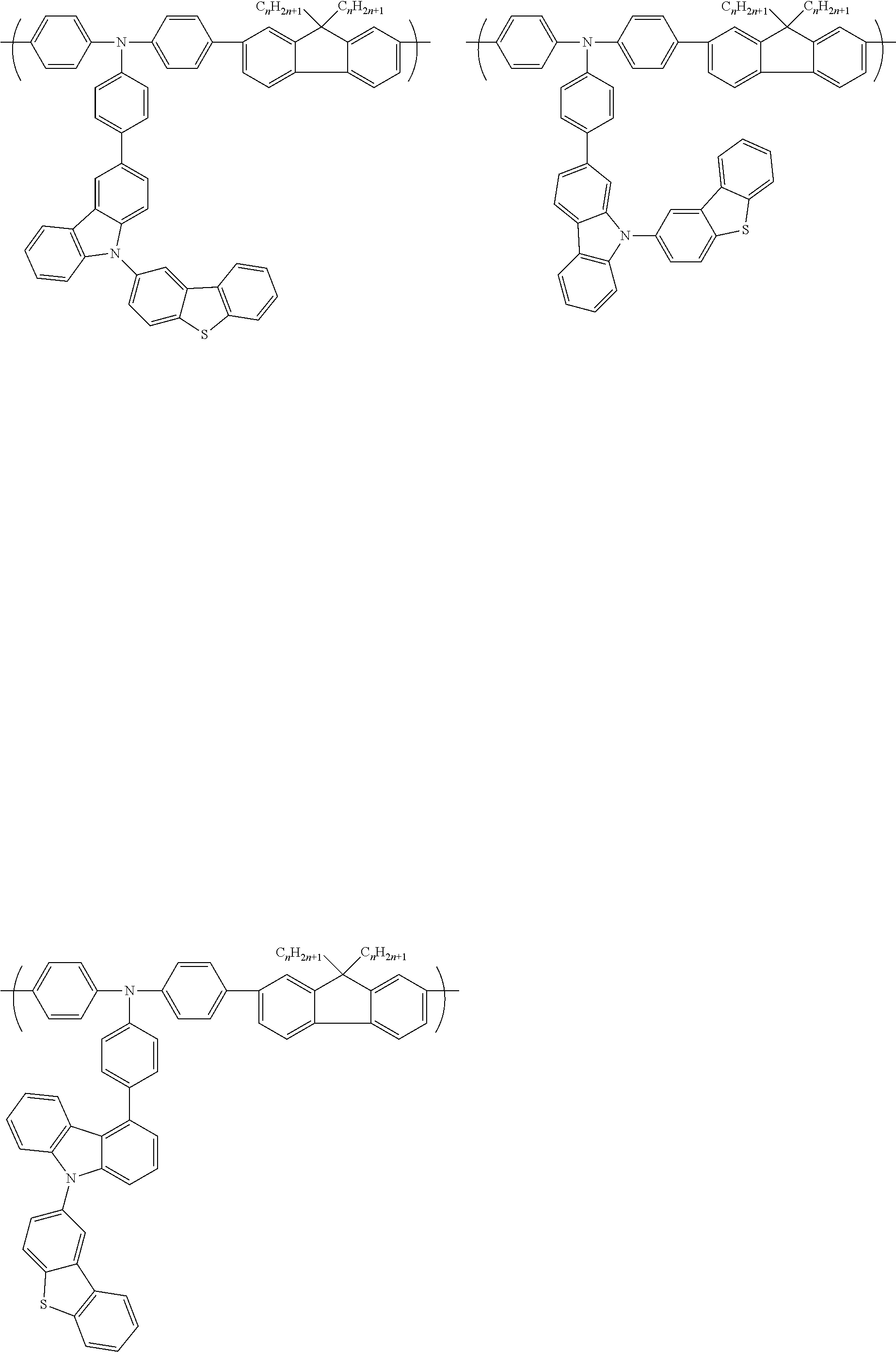

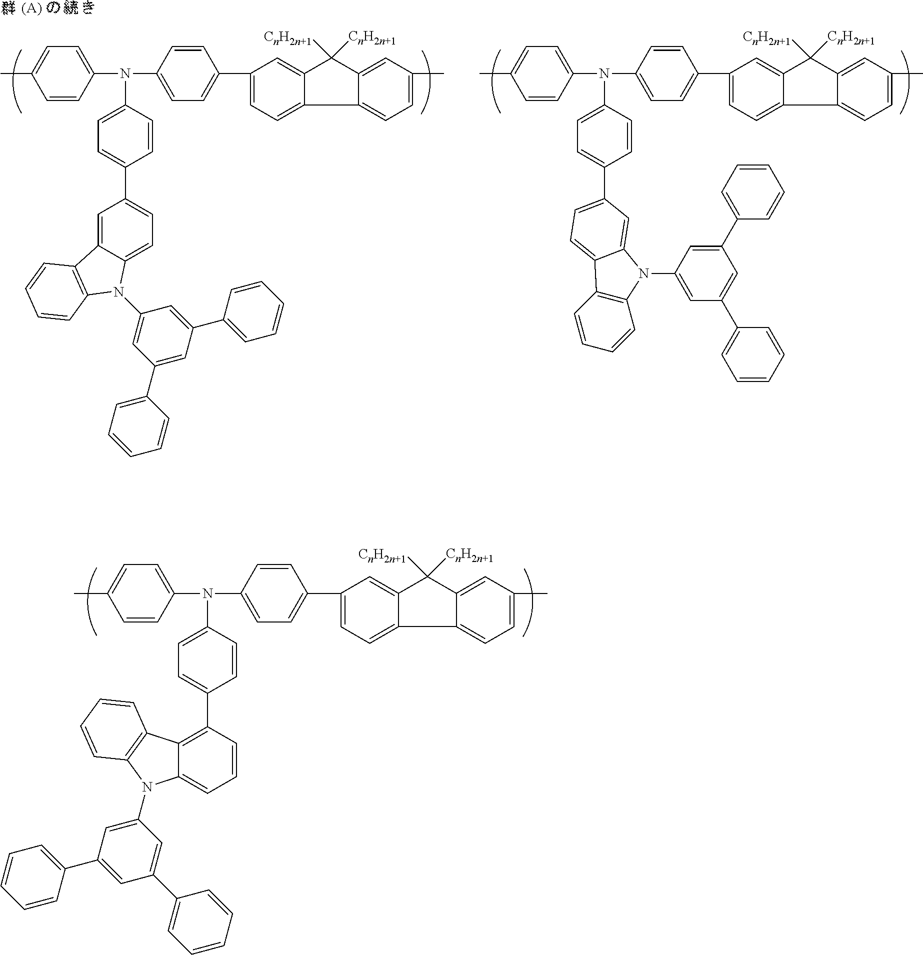

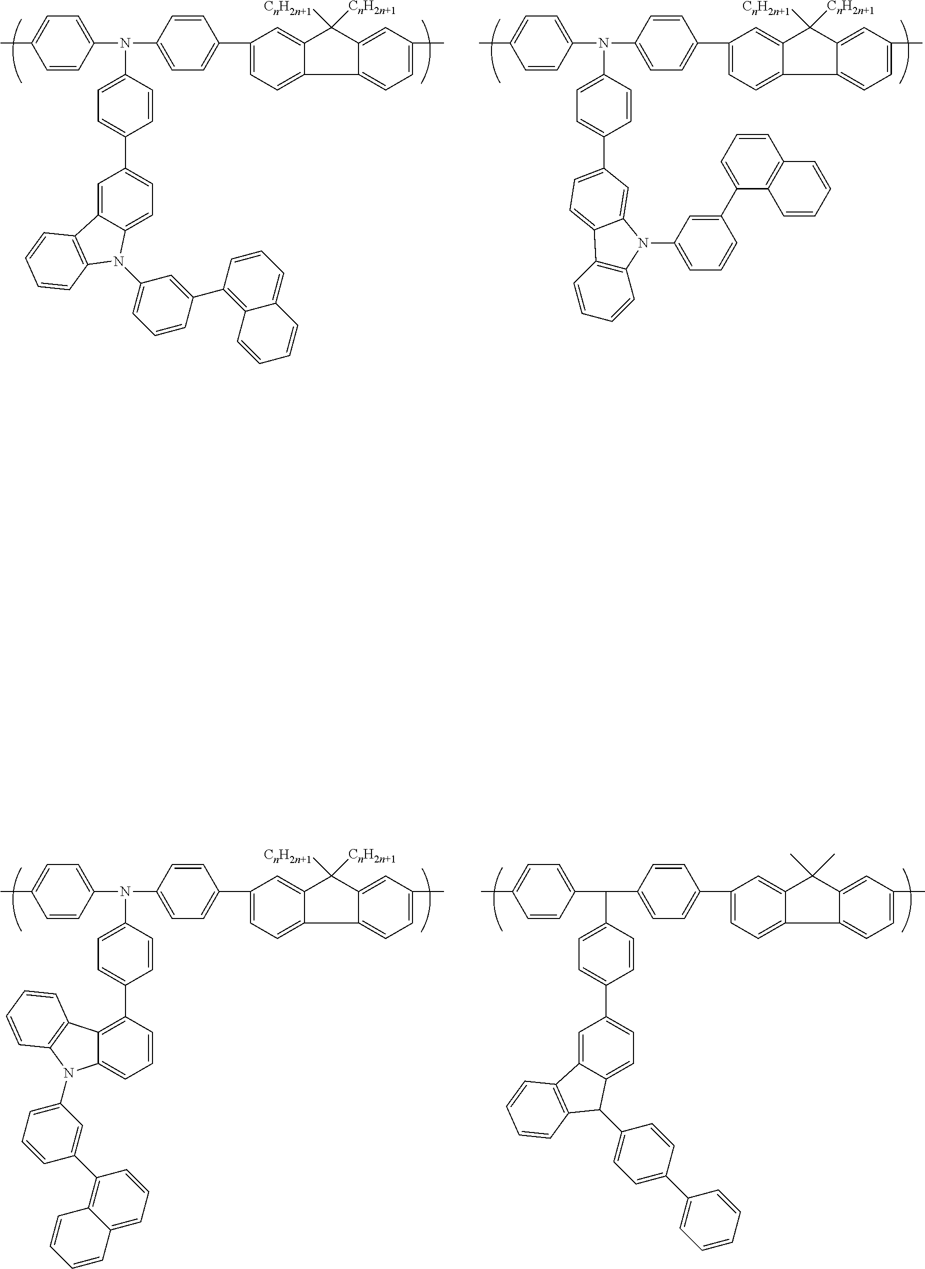

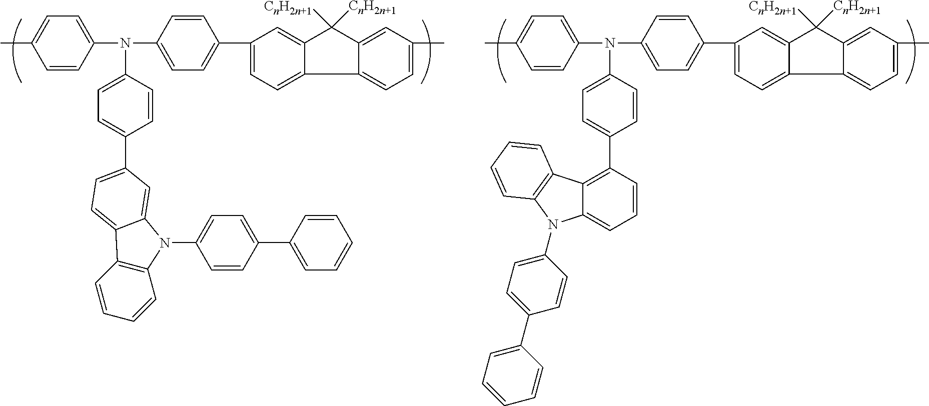

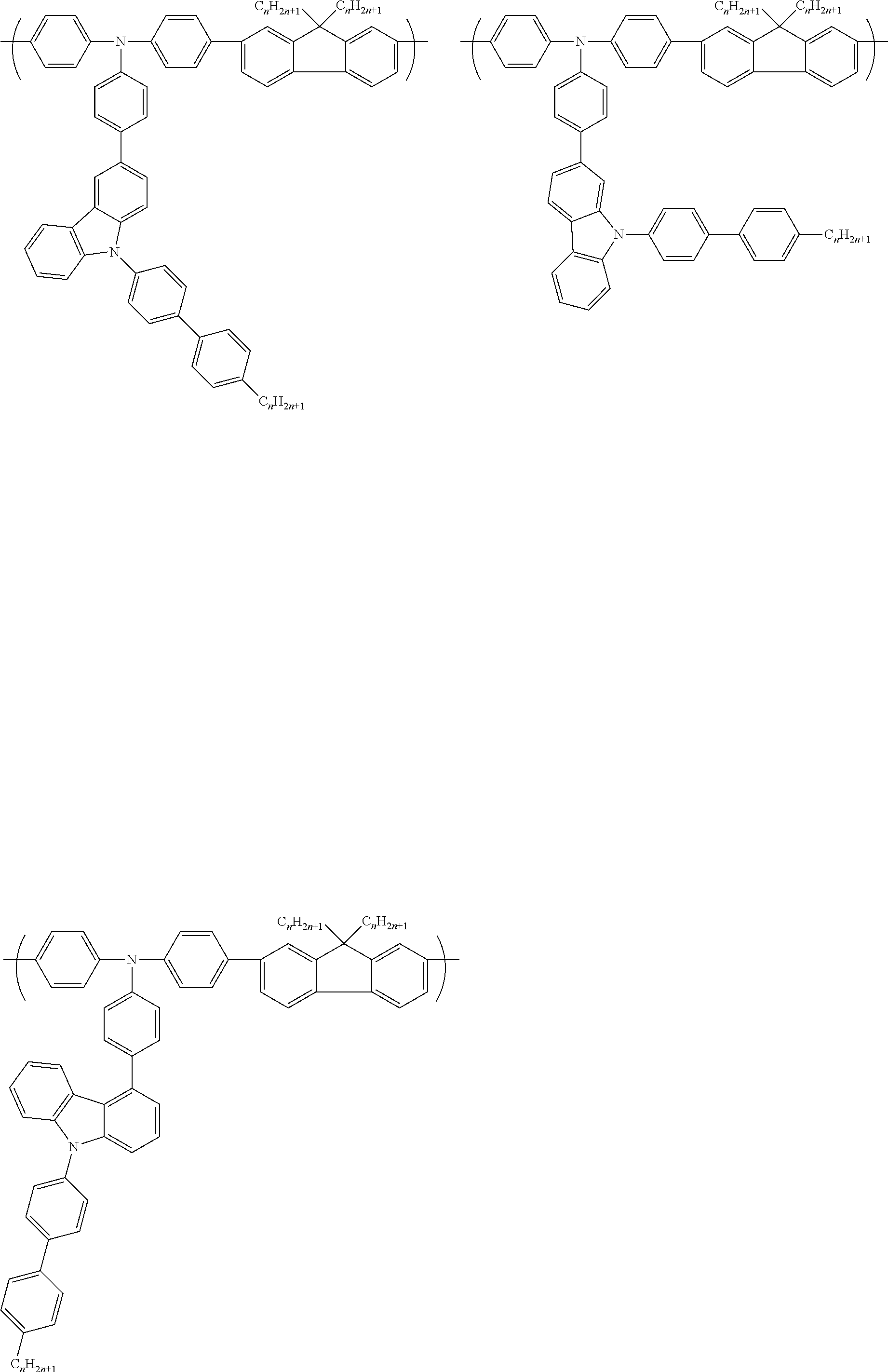

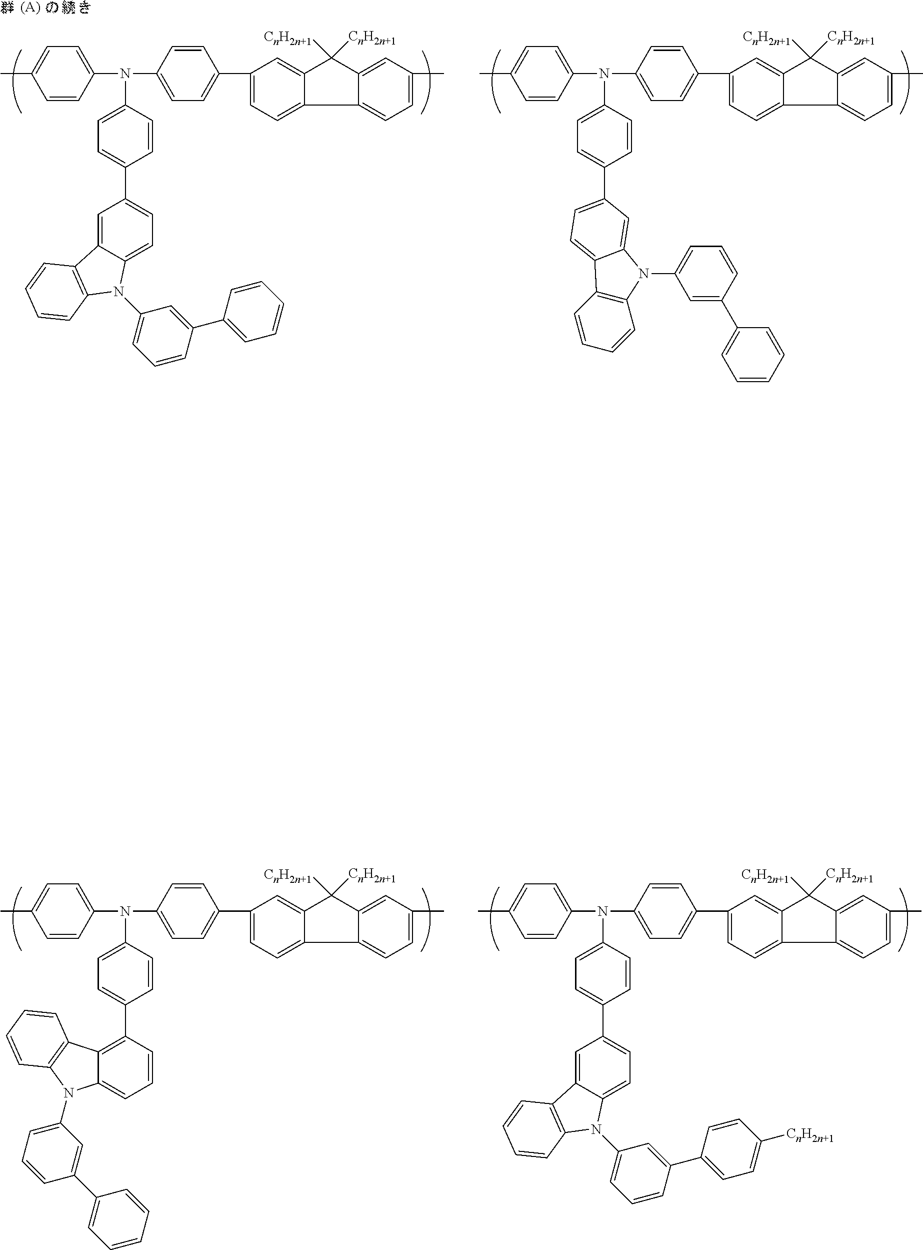

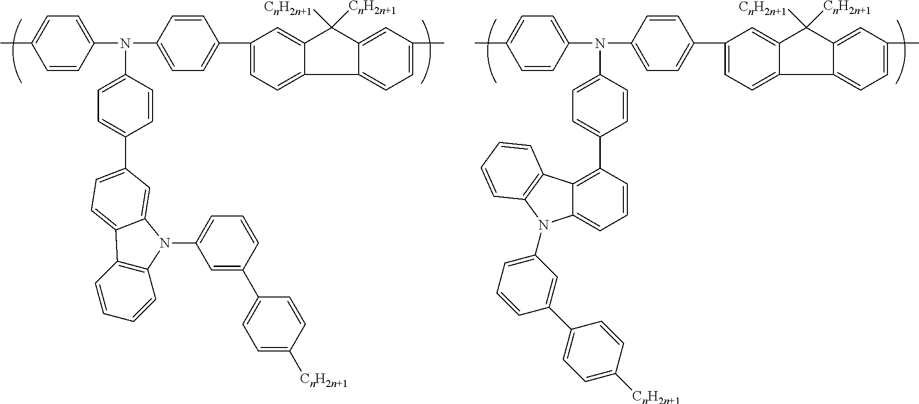

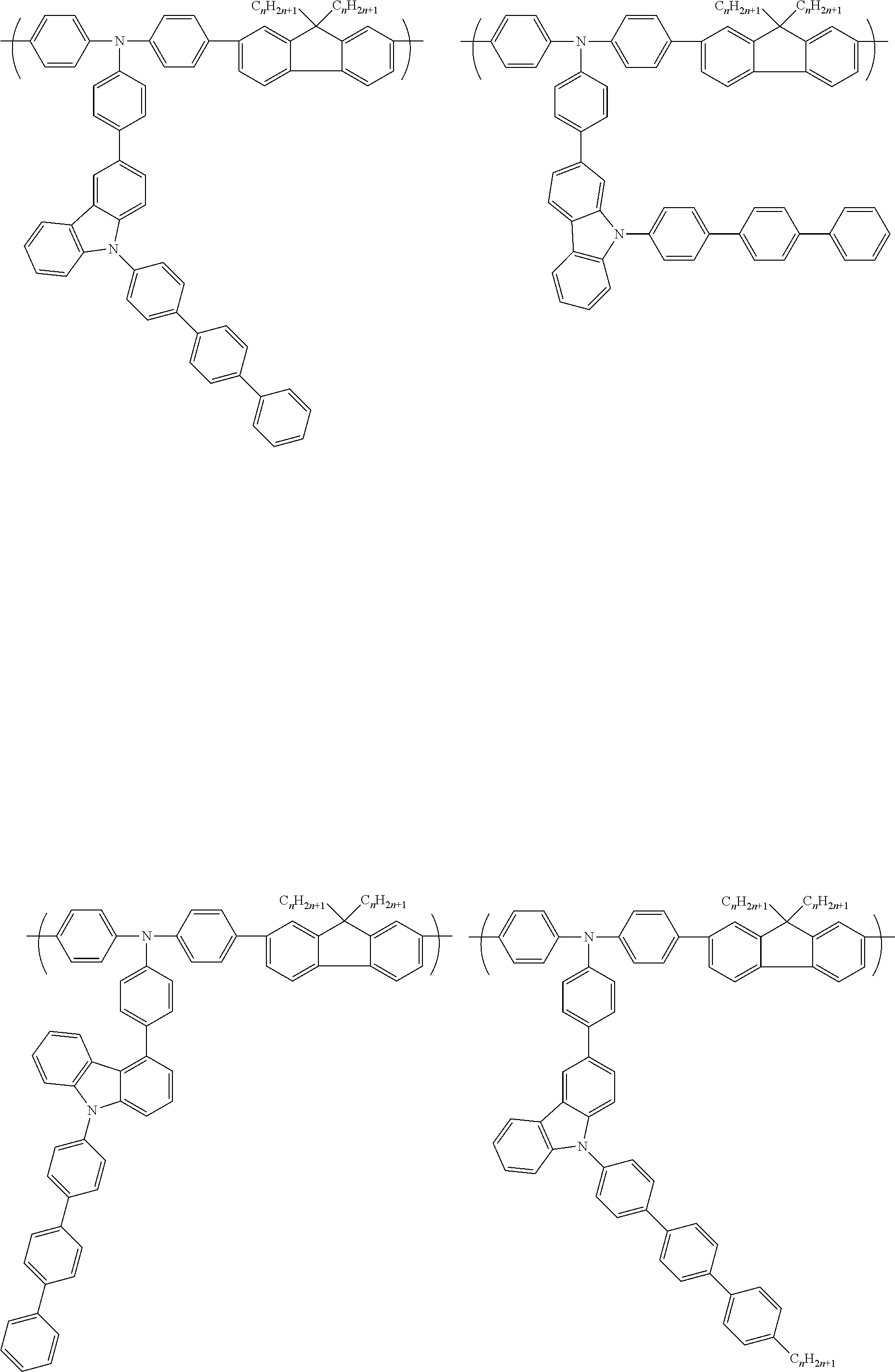

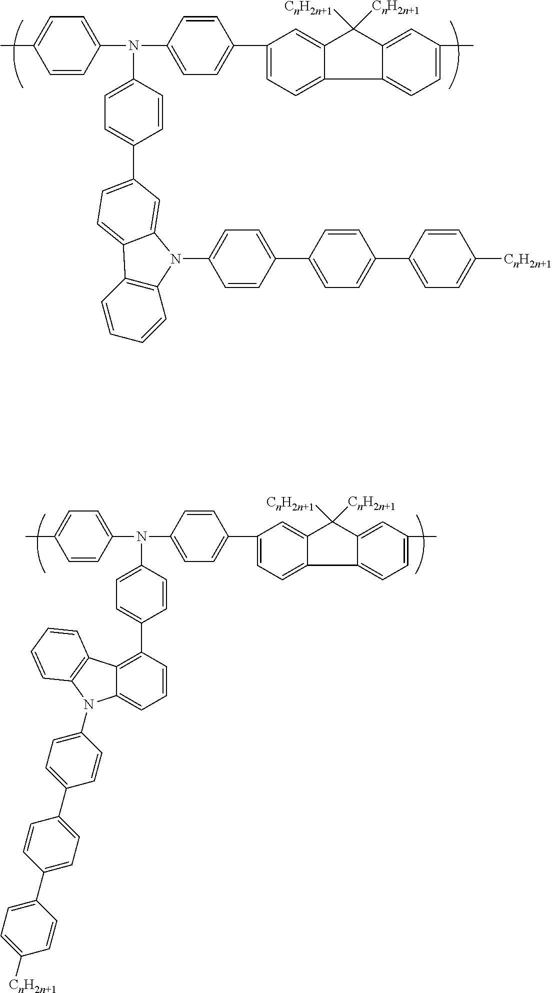

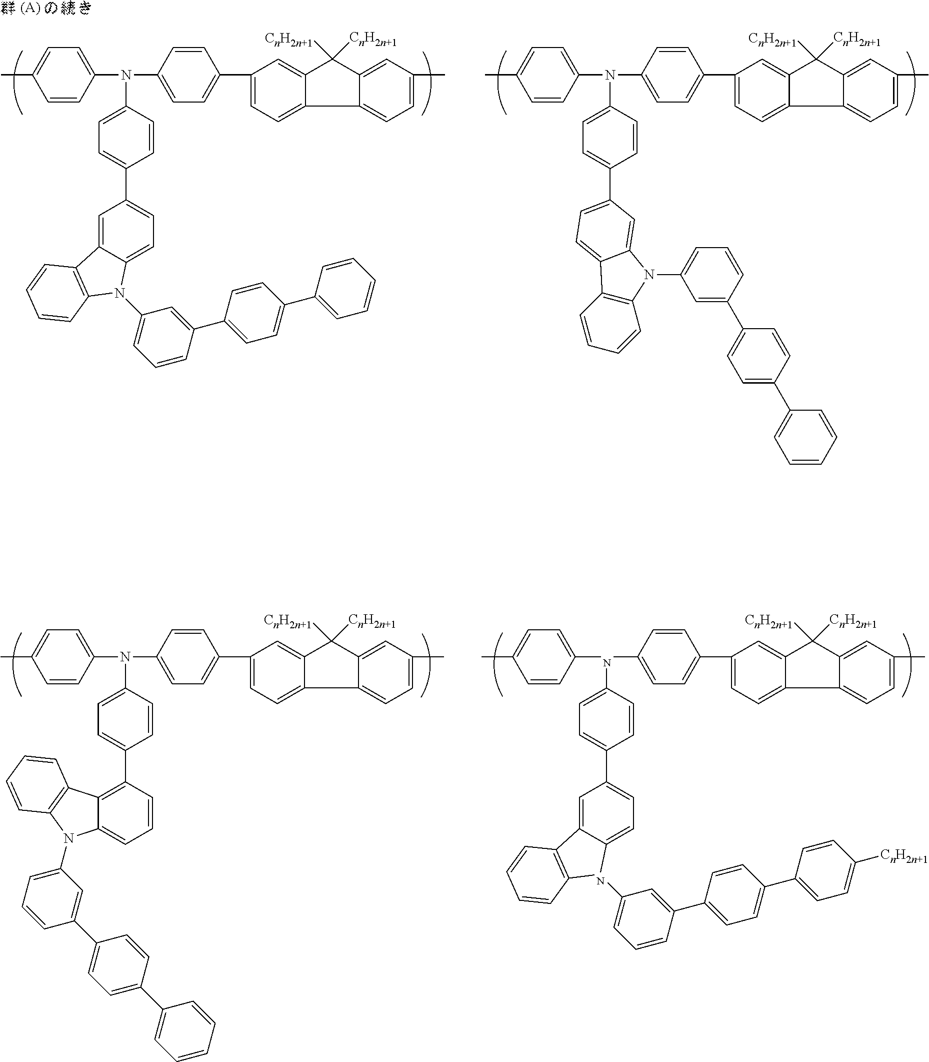

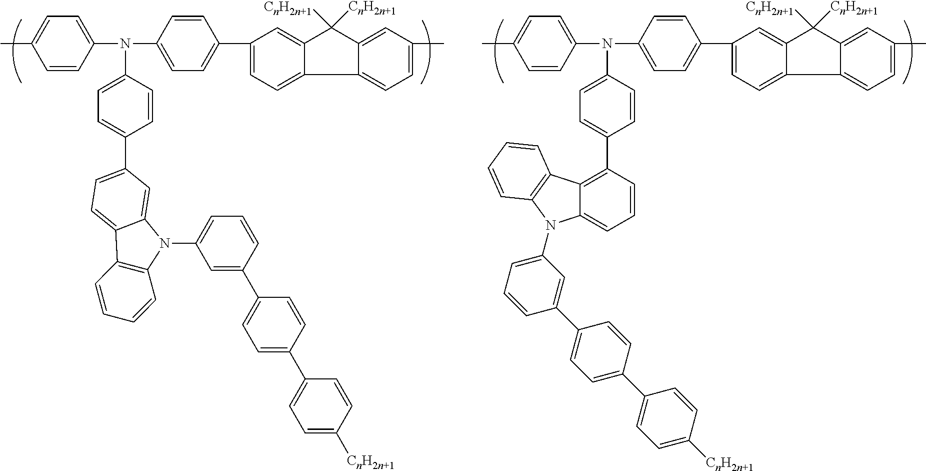

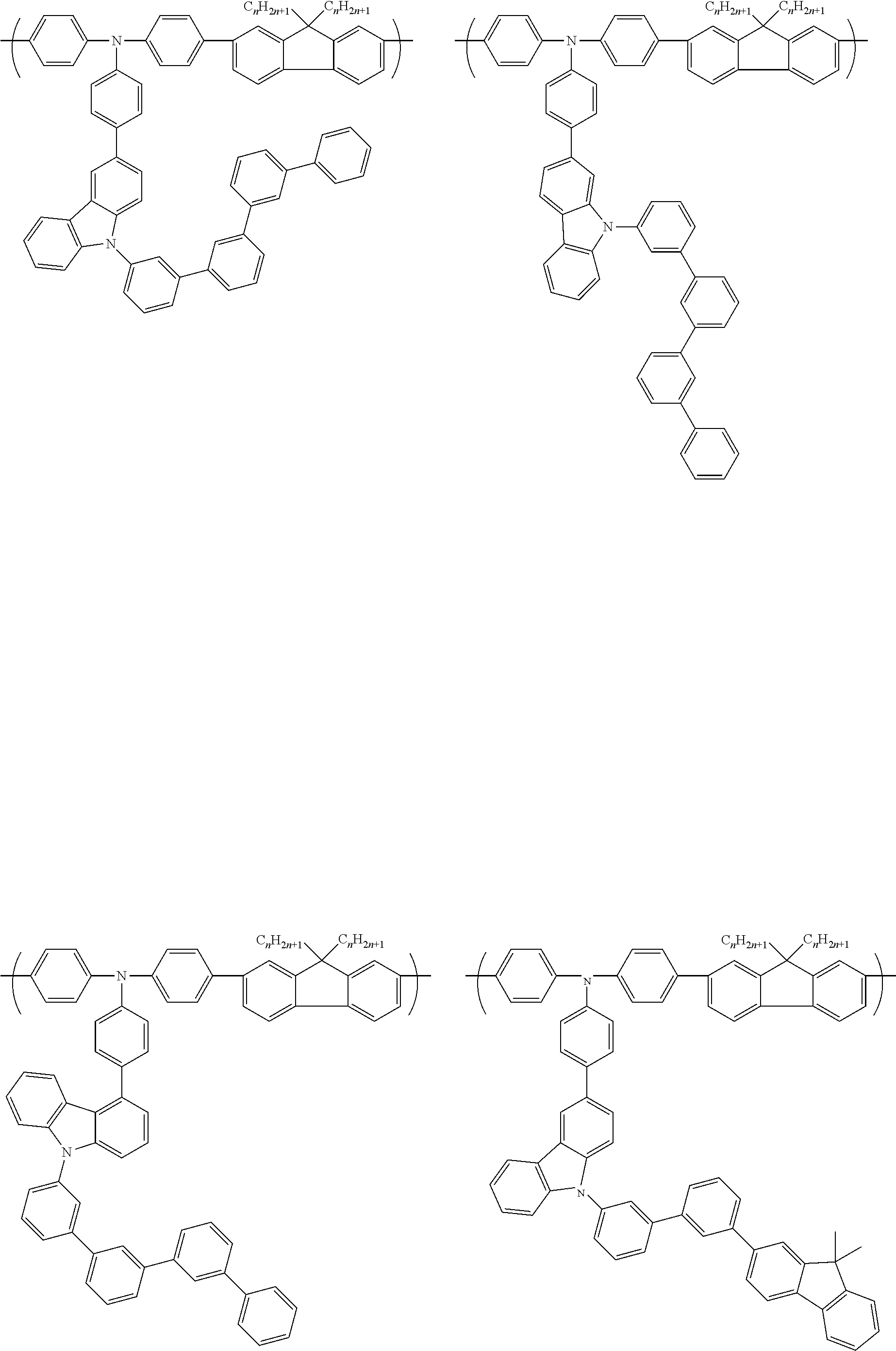

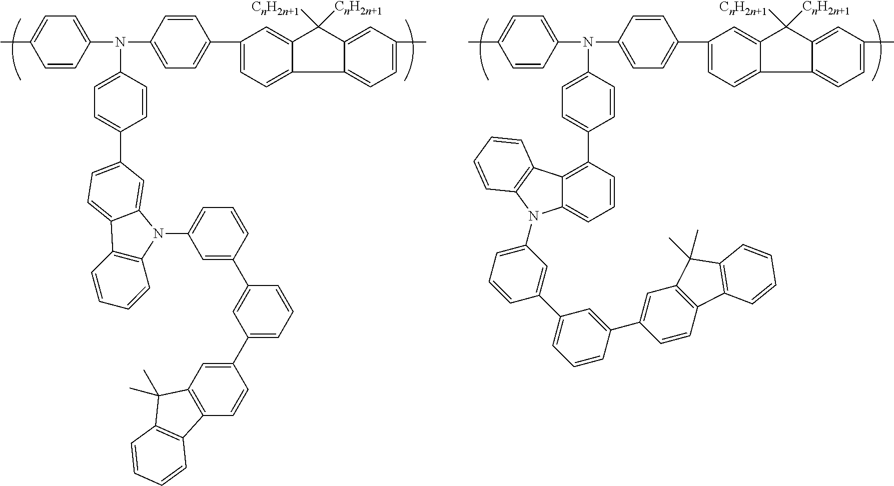

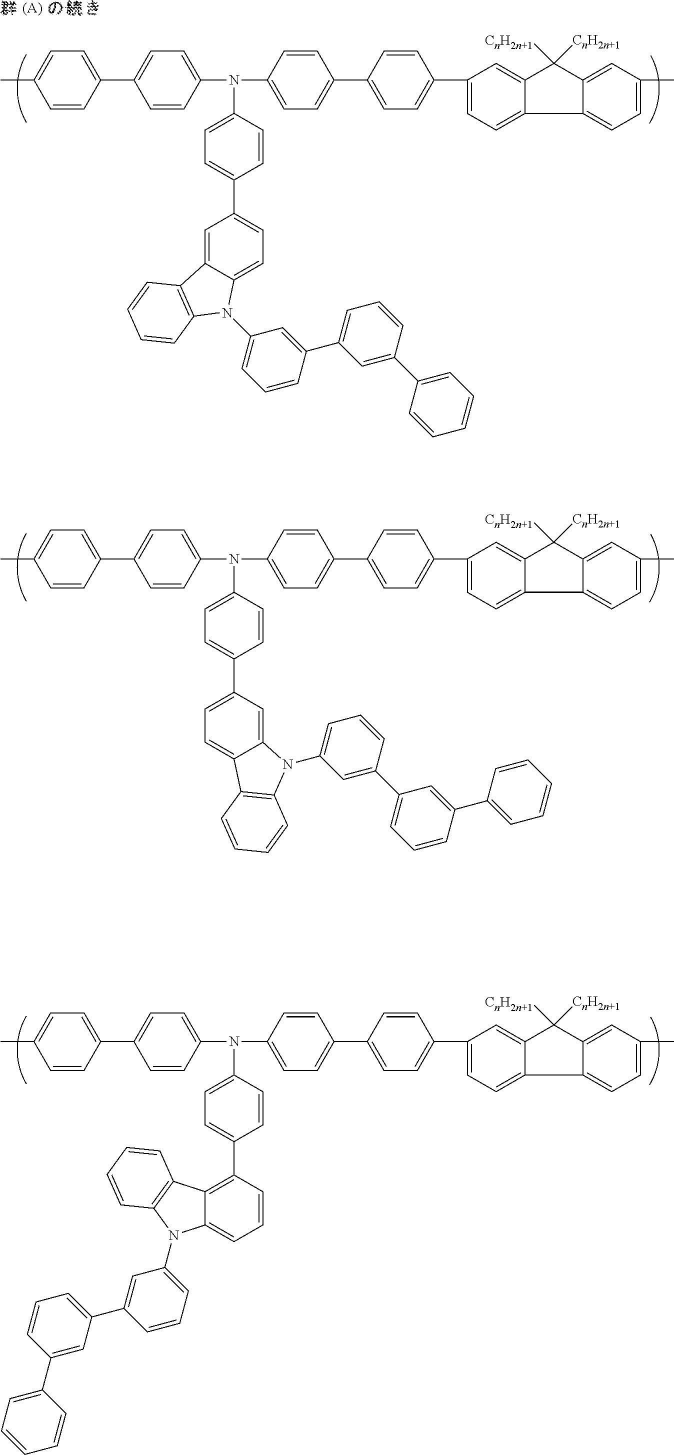

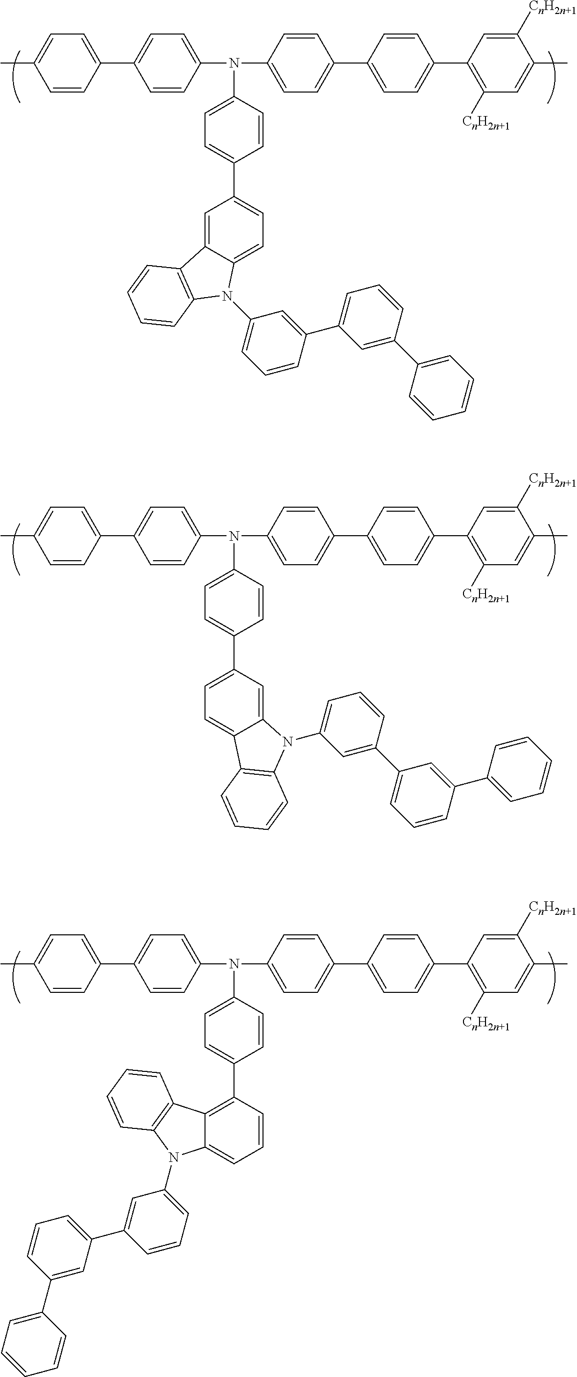

In Group A above,
n represents an integer, and may each independently be an integer of from 1 to 20, for example, an integer of from 6 to 12, or for example, 6, 8, 10 or 12.

When the compound shown in Group A includes two or more groups represented by “CₙH₂ₙ₊₁—”, each n in “CₙH₂ₙ₊₁—” may be the same as or different from each other.

When the compound shown in Group A includes two or more groups represented by “CₙH₂ₙ₊₁—”, each group represented by “CₙH₂ₙ₊₁—” may be the same as or different from each other.

The group represented by “CₙH₂ₙ₊₁—” may be linear or branched, and for example, it may be linear.

The amine-based polymer may include, for example, a polymer that contains one or more of the following structural units.

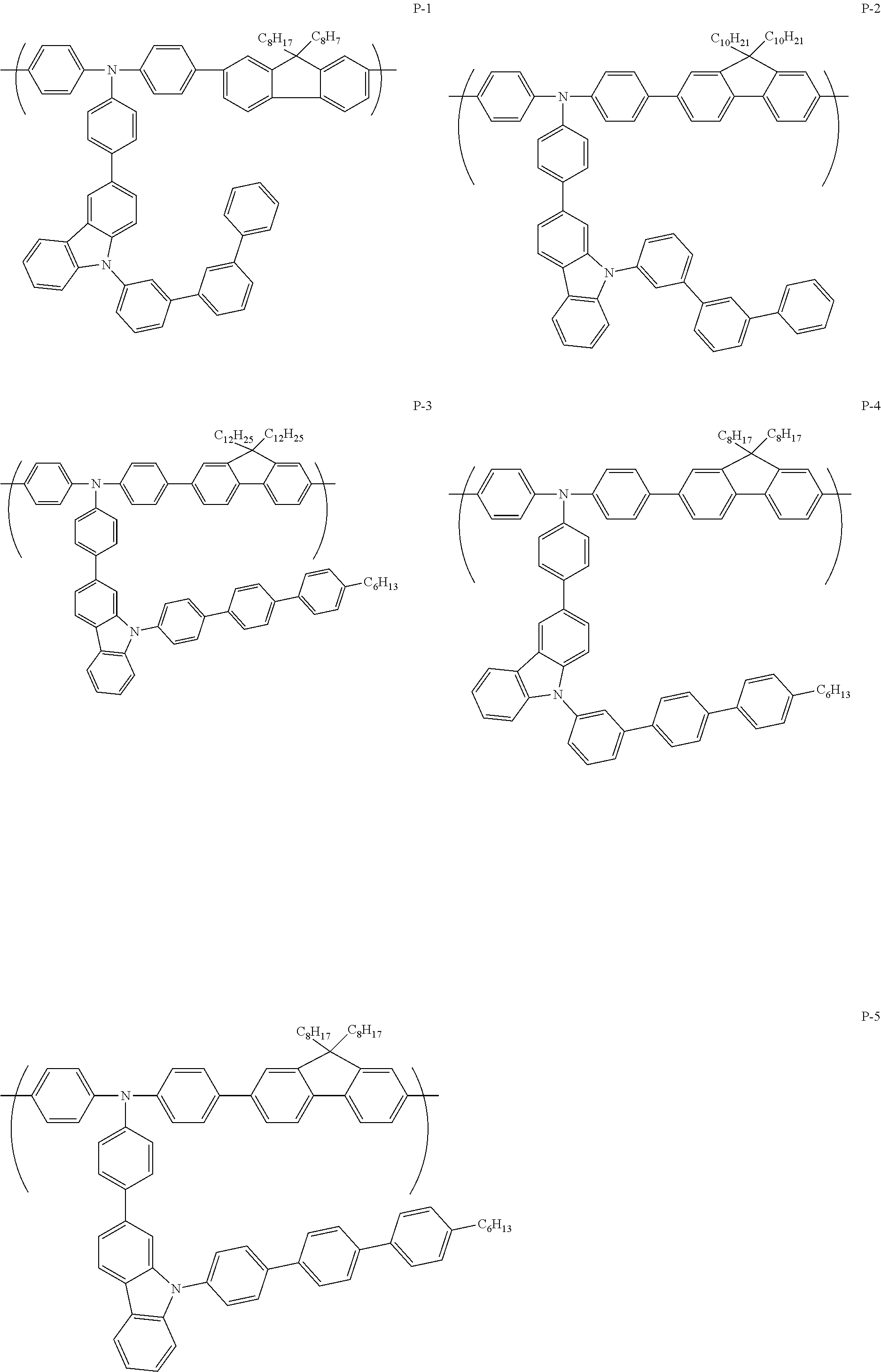

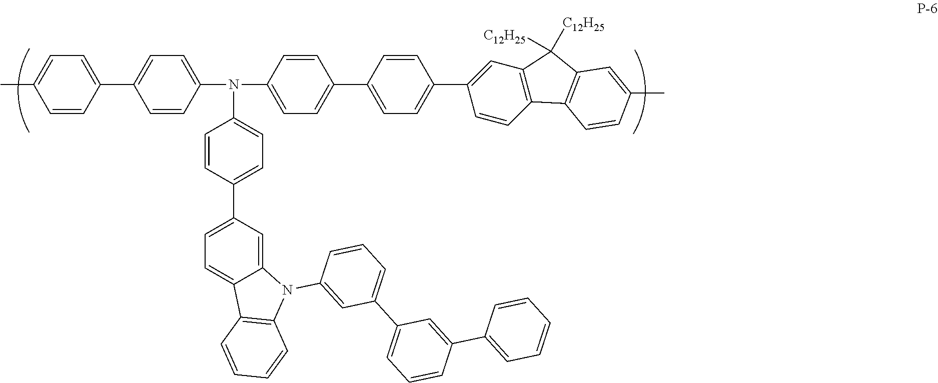

In the amine-based polymer, the composition ratio among the structural units represented by Chemical Formulae (1) to (3) is not particularly limited.

When considering the improvement in lifespan or hole transport capacity of the electroluminescent device including the amine-based polymer, the amine-based polymer according to an embodiment may include the structural units represented by Chemical Formulae (1) to (3) in an amount of 10 mol % to 100 mol %, based on the total mole number of all structural units constituting the amine-based polymer. For example, the amine-based polymer may include the structural units represented by Chemical Formulae (1) to (3) in an amount of greater than or equal to 50 mol % and less than or equal to 100 mol %, or for example, 100 mol %, based on the total mole number of all structural units constituting the amine-based polymer. That is, in an exemplary embodiment, the amine-based polymer may consist of the structural units represented by Chemical Formulae (1) to (3), and terminal groups.

Meanwhile, if the amine-based polymer includes two or more types of the structural units represented by Chemical Formulae (1) to (3), the ratio of the structural units represented by Chemical Formulae (1) to (3) refers to the ratio of total amount of the structural units represented by Chemical Formulae (1) to (3).

As described above, the amine-based polymer according to an embodiment may consists of the above structural units.

According to an exemplary embodiment, the amine-based polymer may include a structural unit represented by Chemical Formula (1), and further include a structural unit represented by other than the structural units represented by Chemical Formulae (1) to (3). The additional different structural unit is not particularly limited as long as it does not impair the effect of the embodiment.

For example, if any of Ar¹¹, Ar¹², Ar¹⁴, Ar²⁵, Ar³¹, and Ar³⁶, which constitute the main chain of Chemical Formulae (1) to (3), is not selected from the following group VI, the amine-based polymer may include at least one type of structural unit selected from group VI below in the main chain of Chemical Formulae (1) to (3), as an additional different structural unit.

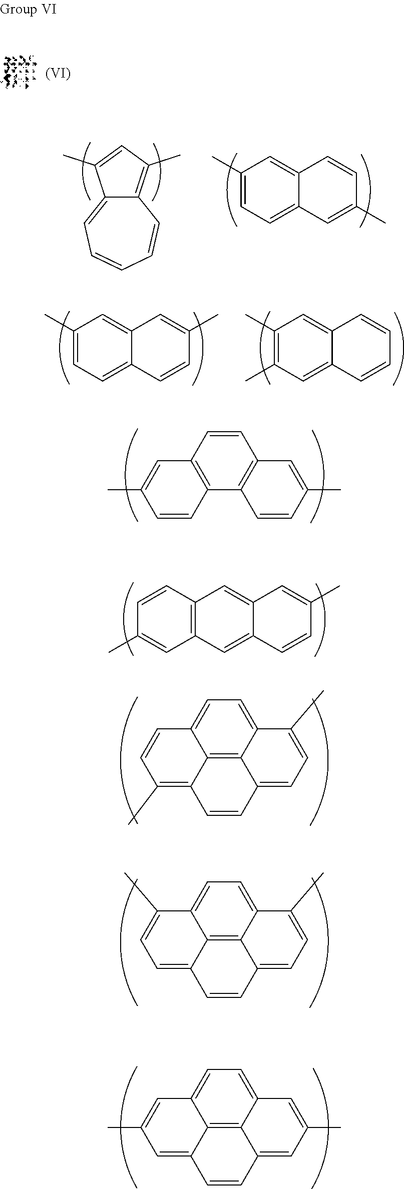

In the amine-based polymer, a composition ratio of the structural unit selected from Group VI is not particularly limited.

When considering feasibility of film fabrication, and other effects achieved by improved film strength, etc. by using a composition containing the amine-based polymer, the amine-based polymer according to an embodiment may include a structural unit selected from Group VI in an amount of from 1 mol % to 10 mol %, based on the total mole number of all structural units constituting the amine-based polymer.

Meanwhile, if the amine-based polymer includes two or more types of the structural units selected from Group VI, the ratio means a ratio of the total amount of the structural units selected from Group VI.

In an exemplary embodiment, the terminal group of the main chain of the amine-based polymer is not particularly limited and appropriately defined depending on the type of raw material used, and may be, for example, a hydrogen atom.

Weight average molecular weight (Mw) of the amine-based polymer according to one embodiment is not particularly limited as long as the effect of the invention is achieved. For example, the weight average molecular weight (Mw) may be greater than or equal to about 12,000 Da and less than or equal to about 1,000,000 Da, or for example, greater than or equal to about 50,000 Da and less than or equal to about 500,000 Da. Within the range of the weight average molecular weight, it may be possible to appropriately control the viscosity of the coating solution to form a layer, for example, a hole injection layer, a hole transport layer, etc., or to form a layer with a uniform thickness using the amine-based polymer.

The number average molecular weight (Mn) of the amine-based polymer according to one embodiment is not particularly limited as long as the effect of the invention is achieved. For example, the number average molecular weight (Mn) may be greater than or equal to about 10,000 Da and less than or equal to about 300,000 Da, or for example, greater than or equal to about 30,000 Da and less than or equal to about 200,000 Da. Within the range of the number average molecular weight, it may be possible to appropriately control the viscosity of the coating solution to form a layer, for example, a hole injection layer, a hole transport layer, etc., or to form a layer with a uniform thickness using the amine-based polymer.

The polydispersity (“PDI,” weight average molecular weight/number average molecular weight) of the amine-based polymer according to an embodiment may be greater than or equal to about 1.2 and less than or equal to about 4.0, or for example, greater than or equal to about 1.5 and less than or equal to about 3.5.

The method of measurement of the number average molecular weight (Mn) and weight average molecular weight (Mw) is not particularly limited, and any method known to persons skilled in the art to which the invention pertains or the method appropriately modified can be used.

In the present specification, the number average molecular weight (Mn) and the weight average molecular weight (Mw) are measured by a method as described later. Meanwhile, polydispersity (Mw/Mn) is calculated by dividing the weight average molecular weight (Mw) by the number average molecular weight (Mn) measured by the method.

The number average molecular weight (Mn) and the weight average molecular weight (Mw)) of the amine-based polymer according to an exemplary embodiment are measured by size exclusion chromatography (SEC) using polystyrene as a standard material under the following conditions.
(SEC measurement conditions)
Analysis equipment (SEC): Shimadzu Corporation Prominence
Column: Polymer Laboratories, PLgel MIXED-B
Column temperature: 40° C.
Flow rate: 1.0 milliliter/minute (ml/min)
Injection volume of sample solution: 20 microliter (μl) (Polymer concentration: approximately 0.05 wt %)
Eluent: Tetrahydrofuran (THF)
Detector (UV-VIS detector): Shimadzu Corporation, SPD-10AV
Standard sample: polystyrene

The glass transition temperature (T_{g}) of the amine-based polymer according to an embodiment is not particularly limited, but may be greater than or equal to about 70° C., for example, greater than or equal to about 80° C., greater than or equal to about 100° C., greater than or equal to about 110° C., or greater than or equal to about 120° C. The glass transition temperature (T_{g}) of the amine-based polymer according to an embodiment is not particularly limited, but may be less than or equal to about 250° C., for example, less than or equal to about 180° C., less than or equal to about 170° C., less than or equal to about 160° C., or less than or equal to about 155° C. Within the range, a device with more improved properties may be obtained.

The glass transition temperature may be measured by using a differential scanning calorimeter (DSC) (manufactured by Seiko Instruments, DSC6000). Details of the measurement method are described in the examples.

The HOMO (Highest Occupied Molecular orbital) level of the amine-based polymer according to an embodiment is not particularly limited, but may be greater than or equal to about −5.75 eV (electron volts), for example, greater than or equal to about −5.7 eV, or for example, greater than or equal to about −5.65 eV. The HOMO level of the polymer according to an embodiment is not particularly limited, but may be less than or equal to about −4.5 eV, for example, less than or equal to about −5.0 eV, or for example, less than or equal to about −5.3 eV. Within the range, hole injection efficiency into the light emitting layer may be further improved, and a device with improved characteristics may be obtained.

The HOMO level may be measured by using optoelectronics spectroscopy (Riken Keiki Co., Ltd., AC-3) in air.

The LUMO (Lowest Unoccupied Molecular Orbital) level of the amine-based polymer according to an embodiment is not particularly limited, but may be greater than or equal to about −3.0 eV, for example, greater than or equal to about −2.8 eV, or for example, greater than or equal to about −2.7 eV or more. The LUMO level of the amine-based polymer according to an embodiment is not particularly limited, but may be less than or equal to about −2.0 eV, for example, less than or equal to about −2.2 eV, or for example, less than or equal to about −2.4 eV. Within the range, electrons may be efficiently confined in the light-emitting layer, and a device with improved characteristics may be obtained.

The LUMO level can be calculated by assuming that the energy of the absorption end (edge) on the side of longer wavelength of the absorption spectrum is the energy difference between the HOMO level and the LUMO level, and adding the energy to the HOMO level.

The amine-based polymer according to an embodiment of the present invention can be synthesized by using a known organic synthesis method.

The first organic compound may further include an additional organic compound in addition to the amine-based polymer.

The content ratio of the amine polymer in the first organic compound is not particularly limited.

An amount of the amine-based polymer according to an embodiment of the present invention may be greater than or equal to about 60 wt % and less than or equal to about 100 wt %, for example, greater than or equal to about 80 wt % and less than or equal to about 100 wt %, greater than or equal to about 90 wt % and less than or equal to about 100 wt %, or for example, greater than or equal to about 95 wt % and less than or equal to about 100 wt %. In an exemplary embodiment, the first organic compound may consist solely of the amine-based polymer.

Meanwhile, if the amine-based polymer includes two or more amine-based polymers, the ratio of the amount refers to the ratio of the total amount of the amine-based polymers.

In the hole transport layer, the first organic compound may be included in an amount of greater than or equal to about 30 wt % and less than or equal to about 99 w %, for example, greater than or equal to about 35 wt % and less than or equal to about 98 w %, greater than or equal to about 40 wt % and less than or equal to about 95 wt %, greater than or equal to about 50 wt % and less than or equal to about 95 w %, or for example, greater than or equal to about 50 wt % and less than or equal to about 90 w %, based on the total weight of all organic compounds constituting the hole transport layer.

### [Second Organic Compound]

The hole transport layer according to an embodiment includes a second organic compound. The second organic compound is a liquid crystalline compound. The second organic compound forms a domain within the matrix of the amine-based polymer in the hole transport layer.

Liquid crystalline compounds are those that become liquid crystals under certain conditions.

The liquid crystalline compound, which is the second organic compound, may have a molecular weight of greater than or equal to about 100 gram/mole or more and less than or equal to about 1,000 gram/mole, for example, greater than or equal to about 150 gram/mole and less than or equal to about 800 gram/mole, or for example, greater than or equal to about 200 gram and less than or equal to about 700 gram/mole.

Molecular weight can be calculated based on the mass of the element from a structural formula.

Temperature range of liquid crystalline state of a liquid crystalline compound according to an exemplary embodiment may be from about 30° C. to about 280° C.

Here, the temperature range of liquid crystalline state refers to the temperature range between a transition point from a solid phase to an intermediate phase (temperature at the peak of the absorption peak on a side of the lowest temperature) and a transition point from an intermediate phase to an isotropic fluid phase (temperature at the peak of the absorption peak on a side of the highest temperature) of a material having two or more endothermic peaks in the process of temperature rise in differential scanning calorimetry when measured by a differential scanning calorimeter (DSC) (manufactured by TA Instruments, DSC25) using the method described in the Examples described later.

In an exemplary embodiment, the temperature range of liquid crystalline state of a liquid crystalline compound according to an embodiment may be greater than or equal to about 40° C., for example, greater than or equal to about 50° C., greater than or equal to about 60° C., greater than or equal to about 70° C., greater than or equal to about 80° C., or for example, greater than or equal to about 90° C. In addition, the temperature range of liquid crystalline state of a liquid crystalline compound according to an embodiment may be less than or equal to about 270° C., for example, less than or equal to about 260° C., for example, less than 260° C., less than or equal to about 250° C., or for example, less than 250° C.

Therefore, the temperature range of the liquid crystalline state of a liquid crystalline compound according to an exemplary embodiment may be, for example, greater than or equal to about 40° C. and less than or equal to about 270° C., greater than or equal to about 50° C. and less than or equal to about 260° C., greater than or equal to about 60° C. and less than 260° C., greater than or equal to about 80° C. and less than or equal to about 250° C., or for example, greater than or equal to about 90° C. and less than 250° C.

For example, the temperature range of the liquid crystalline state of a liquid crystalline compound according to an exemplary embodiment may be, for example, greater than or equal to about 30° C. and less than or equal to about 250° C. Also, for example, the temperature range of the liquid crystalline state of a liquid crystalline compound according to an exemplary embodiment may be, for example, greater than or equal to about 80° C. and less than or equal to about 250° C., greater than or equal to about 90° C. and less than or equal to about 230° C., or for example, greater than or equal to about 95° C. and less than or equal to about 200° C.

In an exemplary embodiment, the temperature range of the liquid crystalline state of a liquid crystalline compound according to an exemplary embodiment may be greater than or equal to about 100° C. and less than or equal to about 190° C., or for example, greater than or equal to about 110° C. and less than or equal to about 180° C.

When the temperature range of the liquid crystalline state of a liquid crystalline compound according to an embodiment is in the above range, the hole transport layer containing the liquid crystalline compound may have an improved solvent resistance by being prevented from mixing with another layer when manufactured by a solution coating method, for example, an inkjet method, and the like.

Also, the hole transport layer containing a liquid crystalline compound having the temperature range of the liquid crystalline state in the above range is applied to, for example, an electroluminescent device described later, an electroluminescent device with further improved luminous efficiency and luminous lifetime may be obtained.

In an exemplary embodiment, the hole transport layer may include a liquid crystalline compound having a temperature range of the liquid crystalline state of greater than or equal to 30° C. and less than or equal to about 280° C., and a first organic compound having a glass transition temperature of greater than or equal to about 70° C. and less than or equal to about 200° C. For example, the hole transport layer may include a liquid crystalline compound having a temperature range of the liquid crystalline state of greater than or equal to 40° C. and less than or equal to about 270° C., and a first organic compound having a glass transition temperature of greater than or equal to about 70° C. and less than or equal to about 200° C. Also, for example, the hole transport layer may include a liquid crystalline compound having a temperature range of the liquid crystalline state of greater than or equal to 50° C. and less than or equal to about 260° C., and a first organic compound having a glass transition temperature of greater than or equal to about 80° C. and less than or equal to about 180° C. In an exemplary embodiment, the hole transport layer may include a liquid crystalline compound having a temperature range of the liquid crystalline state of greater than or equal to 60° C. and less than about 260° C., and a first organic compound having a glass transition temperature of greater than or equal to about 100° C. and less than or equal to about 170° C.

The second organic compound may include a compound represented by at least one of Chemical Formulae (L1) to (L4).

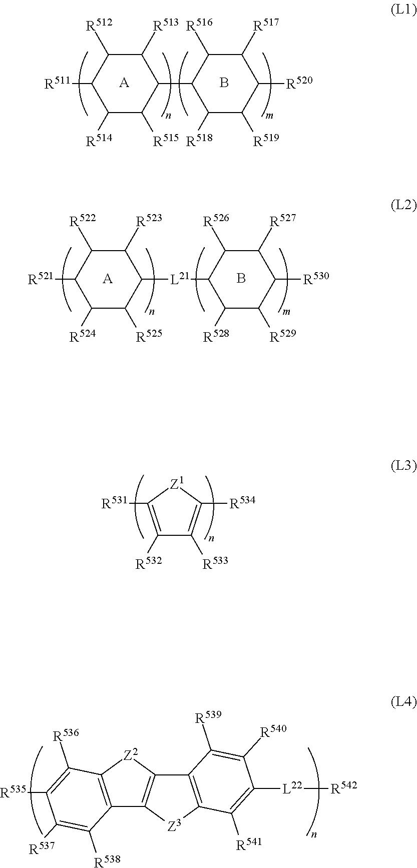

In Chemical Formulae (L1) to (L4),
ring A and ring B may each independently be a benzene ring or a cyclohexane ring,
R⁵¹¹ to R⁵⁴² may each independently be hydrogen, deuterium (D), a cyano group, a nitro group, a halogen group, a carboxyl group (—COOH), an alkyl group having 1 to 20 carbon atoms, and alkoxy group having 1 to 20 carbon atoms, —R⁵⁴³—COOH (R⁵⁴³ is an alkylene group having 1 to 20 carbon atoms or an alkenylene group having 2 to 20 carbon atoms), deuterated —R⁵⁴³—COOH (R⁵⁴³ is an alkylene group having 1 to 20 carbon atoms or an alkenylene group having 2 to 20 carbon atoms), a silyl group (—Si(R⁵⁴⁴)₃) (R⁵⁴⁴ is each independently hydrogen or an alkyl group having 1 to 20 carbon atoms), a siloxanyl group (—O—Si(R⁵⁴⁵)₃) (R⁵⁴⁵ is each independently hydrogen or an alkyl group having 1 to 20 carbon atoms), an amino group (—N(R⁵⁴⁶) 2) (R⁵⁴⁶ is each independently hydrogen or an alkyl group having 1 to 20 carbon atoms), or —R⁵⁴⁷—C(═O)—R⁵⁴⁸ (R⁵⁴⁷ is a single bond, an alkylene group having 1 to 20 carbon atoms, or an alkenylene group having 2 to 20 carbon atoms, and R⁵⁴⁸ is an alkyl group having 1 to 20 carbon atoms, or an alkenyl group having 2 to 20 carbon atoms),
L²¹ may be selected from the following structures:

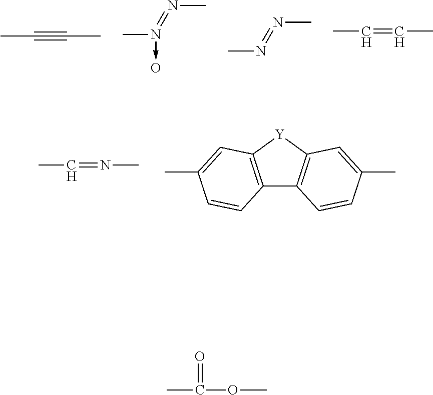

wherein in the above structures,
Y may be —Si(R⁵⁴⁹)(R⁵⁵⁰)—, —C(R⁵⁵¹)(R⁵⁵²)—, S, O, Se, or Te, wherein R⁵⁴⁹ to R⁵⁵² are each independently hydrogen, deuterium (D), an alkyl group having 1 to 20 carbon atoms, an alkoxy group having 1 to 20 carbon atoms, —R⁵⁴³—COOH (R⁵⁴³ is an alkylene group having 1 to 20 carbon atoms or an alkenylene group having 2 to 20 carbon atoms), a silyl group (—Si(R⁵⁴⁴)₃) (R⁵⁴⁴ is each independently hydrogen or an alkyl group having 1 to 20 carbon atoms) or a siloxanyl group (—O—Si(R⁵⁴⁵)₃) (R⁵⁴⁵ is each independently hydrogen or an alkyl group having 1 to 20 carbon atoms),
Z¹, Z², and Z³ may each independently be S, O, Se, or Te,
L²² may be a single bond or a phenylene group, and
n and m may each independently be an integer of from 1 to 10.

In Chemical Formulae (L¹) to (L⁴),
when ring A and ring B are both benzene rings, at least one of R⁵¹¹ to R⁵²⁰, and at least one of R⁵²¹ to R⁵³⁰ may, each independently, be a cyano group, a nitro group, a halogen group (e.g., a fluoro group), a carboxyl group (—COOH), —R⁵⁴³—COOH (R⁵⁴³ is an alkylene group having 1 to 20 carbon atoms or an alkenylene group having 2 to 20 carbon atoms), or —R⁵⁴⁷—C(═O)—R⁵⁴⁸ (R⁵⁴⁷ is a single bond, an alkylene group having 1 to 20 carbon atoms, or an alkenylene group having 2 to 20 carbon atoms, and R⁵⁴⁸ is an alkyl group having 1 to 20 carbon atoms, or an alkenyl group having 2 to 20 carbon atoms), and
when ring A and ring B are both cyclohexane rings, at least one of R⁵¹¹ to R⁵²⁰, and at least one of R⁵²¹ to R⁵³⁰ may, each independently, be hydrogen, deuterium (D), a cyano group, a nitro group, a halogen group, an alkyl group having 1 to 20 carbon atoms, an alkoxy group having 1 to 20 carbon atoms, —R⁵⁴³—COOH (R⁵⁴³ is an alkylene group having 1 to 20 carbon atoms or an alkenylene group having 2 to 20 carbon atoms), a silyl group (—Si(R⁵⁴⁴)₃) (R⁵⁴⁴ is each independently hydrogen or an alkyl group having 1 to 20 carbon atoms), a siloxanyl group (—O—Si(R⁵⁴⁵)₃) (R⁵⁴⁵ is each independently hydrogen or an alkyl group having 1 to 20 carbon atoms), an amino group (—N(R⁵⁴⁶)₂) (R⁵⁴⁶ is each independently hydrogen or an alkyl group having 1 to 20 carbon atoms), or a deuterated —R⁵⁴³—COOH (R⁵⁴³ is an alkylene group having 1 to 20 carbon atoms or an alkenylene group having 2 to 20 carbon atoms).

Here, deuterium (D) is an isotope of hydrogen, in which the atomic nucleus consists of one proton and one neutron.

Deuterated —R—COOH means that at least one of the hydrogens constituting “—R—COOH” has been replaced with deuterium. For example, hydrogen at the a position of carboxylic acid (—COOH) may be replaced with deuterium.

A liquid crystalline compound may include any one of the compounds represented by the following formulae.

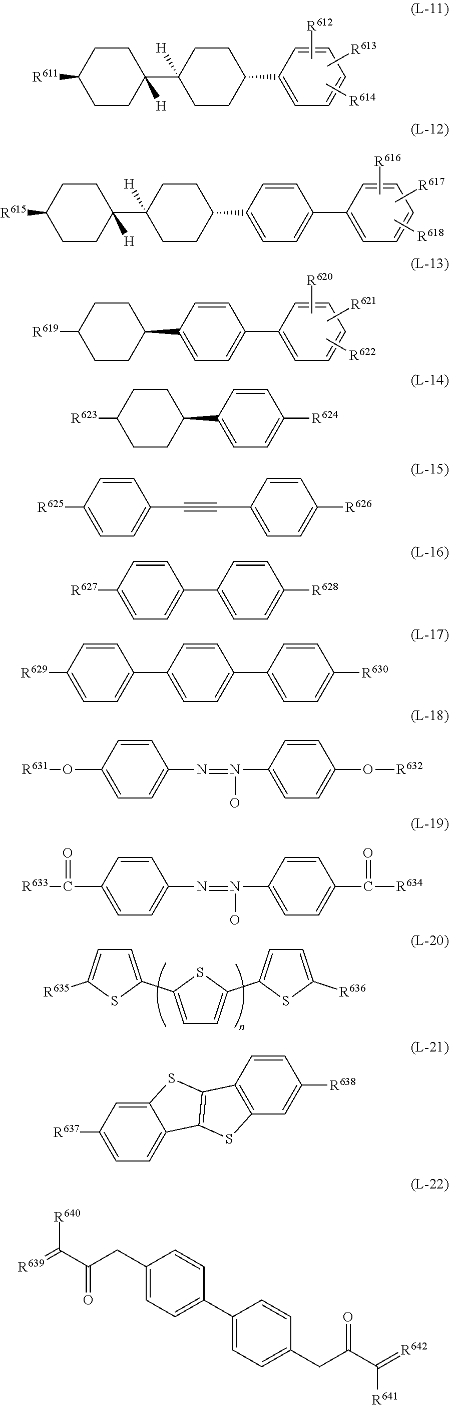

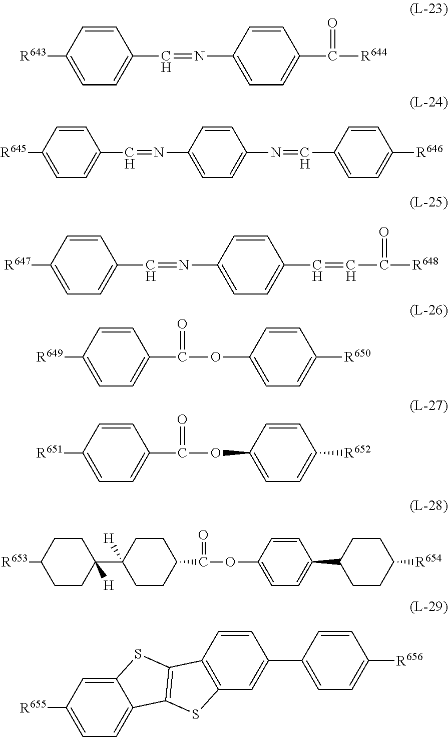

In the above formulae (L-11) to (L-29),
R⁶¹¹ to R⁶³¹, R⁶³⁵ to R⁶³⁸, R⁶⁴³, R⁶⁴⁵ to R⁶⁴⁷, and R⁶⁴⁹ to R⁶⁵⁶ are each independently hydrogen, deuterium, a cyano group, a nitro group, a halogen group, a carboxyl group, an alkyl group having 1 to 20 carbon atoms, an alkoxy group having 1 to 20 carbon atoms, —R⁶⁵⁷—COOH (R⁶⁵⁷ is an alkylene group having 1 to 20 carbon atoms or an alkenylene group having 2 to 20 carbon atoms), deuterated —R⁶⁵⁸—COOH (R⁶⁵⁸ is an alkylene group having 1 to 20 carbon atoms or an alkenylene group having 2 to 20 carbon atoms), a silyl group (—Si(R⁶⁵⁹)₃) (R⁶⁵⁹ is each independently hydrogen or an alkyl group having 1 to 20 carbon atoms), a siloxanyl group (—O—Si(R⁶⁶⁰)₃) (R⁶⁶⁰ is each independently hydrogen or an alkyl group having 1 to 20 carbon atoms), or an amino group (—N(R⁶⁶¹)₂) (R⁶⁶¹ is each independently hydrogen or an alkyl group having 1 to 20 carbon atoms),
R⁶³² to R⁶³⁴, R⁶³⁹ to R⁶⁴², R⁶⁴⁴, and R⁶⁴⁸ are each independently an alkyl group, for example, an alkyl group having 1 to 20 carbon atoms.

For example, among the above compounds, a liquid crystalline compound may include a compound represented by Chemical Formulae (L-12), (L-13), (L-16), (L-17), or (L-29).

In the above Chemical Formulae (L-11) to (L-29), R⁶¹¹ to R⁶³¹, R⁶³⁵ to R⁶³⁸, R⁶⁴³, R⁶⁴⁵ to R⁶⁴⁷ and R⁶⁴⁹ to R⁶⁵⁶ may each independently be a cyano group, a halogen group, a carboxyl group, an alkyl group having 1 to 20 carbon atoms, an alkoxy group having 1 to 20 carbon atoms, or —R⁶⁵⁷—COOH (R⁶⁵⁷ is an alkynyl group having 1 to 20 carbon atoms), in case when they are not hydrogen atoms.

For example, the liquid crystalline compound may include any one of the following compounds.

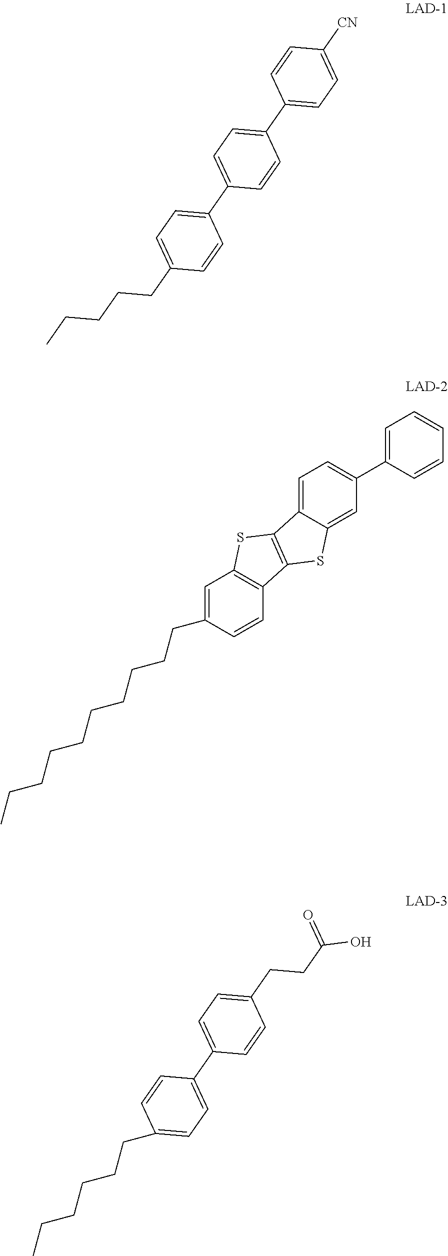 [SMILES: CCCCCc1ccc(-c2ccc(-c3ccc(C#N)cc3)cc2)cc1 ; CCCCCCCCCCc1ccc2c(c1)sc1c3ccc(-c4ccccc4)cc3sc21 ; CCCCCCc1ccc(-c2ccc(CCC(=O)O)cc2)cc1]

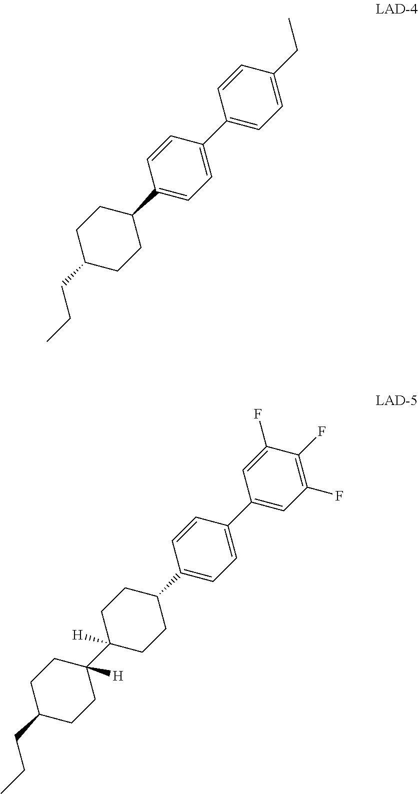

The liquid crystalline compounds may be commercially available or may be synthesized by using a known synthetic method.

In the hole transport layer according to an exemplary embodiment, the liquid crystalline compound may be included in an amount of greater than or equal to about 1 wt % and less than or equal to about 70 wt %, for example, greater than or equal to about 2 wt % and less than or equal to about 65 wt %, greater than or equal to about 5 wt % and less than or equal to about 60 wt %, greater than or equal to about 5 wt % and less than or equal to about 50 wt %, or for example, greater than or equal to about 10 wt % and less than or equal to about 50 wt %, based on a total weight of all organic compounds included in the hole transport layer, i.e., when the total weight of all compounds constituting the hole transport layer is regarded as 100 wt %.

In an exemplary embodiment, in the hole transport layer, a weight ratio of the amine-based polymer and the liquid crystalline compound may be from about 99:1 to about 30:70, for example, from about 98:2 to about 35:65, from about 95:5 to about 40:60, from about 95:5 to about 50:50, or from about 90:10 to about 50:50.

In an exemplary embodiment, the hole transport layer 140 may include the first organic compound, the second organic compound, which are described above, and a hole transport material known in the art to which the invention pertains.

The hole transport material known in the art may include, for example, 1,1-bis [(di-4-tolylamino)phenyl] cyclohexane (TAPC), carbazole derivatives such as N-phenylcarbazole, polyvinylcarbazole, and the like, N,N′-bis(3-methylphenyl)-N,N′-diphenyl-[1,1-biphenyl]-4,4′-diamine (TPD), 4,4′,4″-tris(N-carbazolyl)triphenylamine (TCTA), and N,N′-di(1-naphthyl)-N,N′-diphenylbenzidine (NPB), and the like.

The hole transport material may include only one type, or two or more types of hole transport materials may also be used.

### [Emitting Layer]

An emitting layer (also referred to as a light emitting layer) is formed above the hole transport layer.

The emitting layer is a layer that emits light by fluorescence, phosphorescence, and the like, and may be formed by using, for example, vacuum deposition, spin coating, inkjet printing method, and the like.

The emitting layer 150 may be formed to have a thickness of, for example, greater than or equal to about 10 nanometer (nm) and less than or equal to about 60 nm, for example, greater than or equal to about 20 nm and less than or equal to about 50 nm.

The emitting material of the emitting layer (hereinafter, also referred to as “emitting layer material”) is not particularly limited, and the emitting material known in the art may be used. The emitting materials contained in the emitting layer may be those that are able to emit light from triplet excitons, i.e., perform phosphorescent light emission. In this case, the EL device may have a further improved lifespan.

The emitting material may include only one type, or a mixture of two or more types of material.

The emitting layer is not particularly limited, and may have a structure known in the art.

For example, the emitting layer may be made of quantum dots or organic metal complex, and in an exemplary embodiment, made of quantum dots. That is, the laminate according to an embodiment may include an emitting layer that contains quantum dots or organic metal complex, and in an exemplary embodiment, the laminate may include an emitting layer that contains quantum dots.

Meanwhile, when the emitting layer includes quantum dots, the EL device is a quantum dot electroluminescent device, i.e., QLED, or a quantum dot light emitting device.

When the emitting layer includes an organic metal complex, the EL device is an organic electroluminescent device, i.e., OLED.

When the emitting layer includes quantum dots (in the case of QLED), the emitting layer may have a single layer or multiple layers that contain quantum dots. Here, the quantum dots are semiconductor nanoparticles of a certain size that have a quantum confinement effect. A diameter of the semiconductor nanoparticle (quantum dot) is not particularly limited, but, for example, may be greater than or equal to about 1 nm and less than or equal to about 15 nm, or for example, greater than or equal to about 1 nm and less than or equal to about 10 nm.

Semiconductor nanoparticles (quantum dots) contained in the emitting layer may be made by using a wet chemical process, an organic metal chemical vapor deposition process, a molecular beam epitaxy process, or other similar processes. Among these, a wet chemical process involves converting precursors to particles in an organic solvent to grow.

In a wet chemical process, the organic solvent naturally coordinates on the surface of the quantum dot crystal and acts as a dispersant as the crystal grows, whereby the growth of the crystal may be controlled. Because of this, in the wet chemical process, growth of the semiconductor nanoparticles may be controlled easily and at a low cost compared with the vapor deposition method, such as, for example, the metal organic chemical vapor deposition (MOCVD) method or molecular beam epitaxy (MBE) method.

The energy band gap can be controlled by adjusting the size of the semiconductor nanoparticles (quantum dots), and light in various wavelength ranges can be obtained from the light emitting layer (quantum dot light emitting layer). Therefore, a display device can be obtained that emits light of plural wavelength regions by using plurality of quantum dots of different sizes.

The size of the quantum dots may be selected such that the quantum dots emit red, green, and/or blue lights such that a color display can be constructed. Additionally, quantum dots having various sizes can be combined to emit white light from the combined various colored lights.

The semiconductor nanoparticle (quantum dot) may include a Group II-VI semiconductor compound; a Group III-V semiconductor compound; a Group IV-VI semiconductor compound; a Group IV element or compound; or a combination thereof.

The Group II-VI semiconductor compounds are not particularly limited, but, for example, may include a two element compound selected from the group consisting of CdSe, CdTe, ZnS, ZnSe, ZnTe, ZnO, HgS, HgSe, HgTe, or mixtures thereof; a 3 element compound selected from the group consisting of CdSeS, CdSeTe, CdSTe, ZnSeS, ZnTeSe, ZnSTe, HgSeS, HgSeTe, HgSTe, CdZnS, CdZnSe, CdZnTe, CdHgS, CdHgSe, CdHgTe, HgZnS, HgZnSe, HgZnTe, or mixtures thereof; a 4 element compound selected from the group consisting of CdZnSeS, CdZnSeTe, CdZnSTe, CdHgSeS, CdHgSeTe, CdHgSTe, HgZnSeS, HgZnSeTe, HgZnSTe, or mixtures thereof; or a combination thereof.

Group III-V semiconductor compounds are not particularly limited, but, for example, may include a two element compound selected from the group consisting of GaN, GaP, GaAs, GaSb, AlN, AlP, AlAs, AlSb, InN, InP, InAs, InSb, or mixtures thereof; a 3 element compound selected from the group consisting of GaNP, GaNAs, GaNSb, GaPAs, GaPSb, AlNP, AlNAs, AlNSb, AlPAS, AlPSb, InNP, InNAs, InNSb, InPAs, InPSb, GaAlNP, or mixtures thereof; a 4 element compound selected from the group consisting of GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, or mixtures thereof; or a combination thereof.

Group IV-VI semiconductor compounds are not particularly limited, but, for example, may include a two element compound selected from the group consisting of SnS, SnSe, SnTe, PbS, PbSe, PbTe, or mixtures thereof; a 3 element compound selected from the group consisting of SnSeS, SnSeTe, SnSTe, PbSeS, PbSeTe, PbSTe, SnPbS, SnPbSe, SnPbTe, or mixtures thereof; a 4 element compound selected from the group consisting of SnPbSSe, SnPbSeTe, SnPbSTe, or mixtures thereof; or a combination thereof.

A Group IV element or compound is not particularly limited, but, for example, may include an element selected from the group consisting of Si, Ge, and mixtures thereof; a two element compound selected from the group consisting of SiC, SiGe, or mixtures thereof; or a combination thereof.

Semiconductor nanoparticles (quantum dots) may have a homogeneous single structure or may have a core/shell dual structure.

The core/shell structure may contain different materials.

Each of the core and the shell may be composed of different semiconductor compounds. However, the energy band gap of the shell material may be larger than that of the core material.

For example, the semiconductor nanocrystal may have a structure of ZnTeSe/ZnSe/ZnS, InP/ZnSe/ZnS, CdSe/ZnS, or InP/ZnS.

For example, a case of manufacturing a quantum dot having a core (CdSe)/shell (ZnS) structure will be explained.

First, precursors of core (CdSe), such as (CH₃)₂Cd (dimethylcadmium) and TOPSe (trioctylphosphine selenide), may be added to an organic solvent that contains TOPO (trioctylphosphine oxide) as a surfactant to form crystals. At this time, the temperature is maintained at a constant high temperature for a predetermined time, such that the crystals grow to a certain size. Subsequently, precursors of the shell (ZnS) are injected to form a shell on the surface of the already formed core. Accordingly, quantum dots of CdSe/ZnS capped with TOPO may be synthesized.

Semiconductor nanoparticles (quantum dots) may be modified with an organic compound.

Quantum dots may include only one type, or a mixture of two or more types.

When the emitting layer includes quantum dots, the emitting layer may further include other materials in addition to the quantum dots. Other materials are not particularly limited, but may include, for example, organic compounds.

When the emitting layer includes organic metal complex (in the case of OLED), the emitting layer 150 may include, as a host material, for example, 6,9-diphenyl-9′-(5′-phenyl-[1,1′:3′,1″-terphenyl]-3-yl) 3,3′-bi [9H-carbazole], 3,9-diphenyl-5-(3-(4-phenyl-6-(5′-phenyl-[1,1′:3′,1″-terphenyl]-3-yl)-1,3,5-triazin-2-yl)phenyl)-9H-carbazole, 9,9′-diphenyl-3,3′-bi [9H-carbazole], tris(8-quinolinato)aluminum (Alq₃), 4,4′-bis(carbazol-9-yl) biphenyl (CBP), poly(N-vinyl carbazole) (PVK), 9,10-di(naphthalen-2-yl) anthracene (ADN), 4,4′,4″-tris(N-carbazolyl)triphenylamine (TCTA), 1,3,5-tris(N-phenylbenzimidazol-2-yl) benzene (PBI), 3-tert-butyl-9,10-di(naphth-2-yl) anthracene (TBADN), distyrylarylene (DSA), 4,4′-bis(9-carbazolyl)-2,2′-dimethyl-biphenyl (dmCBP), and the like.

The host material may include only one type, or a mixture of two or more types.

The emitting layer may further include a dopant material, for example, perylene and its derivatives, rubrene and its derivatives, coumarin and its derivatives, 4-dicyanomethylene-2-(p-dimethylaminostyryl)-6-methyl-4H-pyran (DCM) and its derivatives, an iridium (III) complex, such as, for example, bis [2-(4,6-difluoro) phenyl) pyridinate] picolinate iridium (III) (Flrpic), (bis(1-phenylisoquinoline) (acetylacetonate)iridium(III) (Ir(piq)₂(acac)), tris(2-phenylpyridine)iridium (III) (Ir(ppy)₃), tris(2-(3-p-xylyl(phenyl)pyridine iridium) (III), and the like, an osmium (Os) complex, a platinum complex, and the like.

For example, among these, emitting material may include a luminescent organic metal complex compound.

The dopant material may include only one type, or a mixture of two or more types.

### [Method of Manufacturing Laminate]

The manufacturing method of the laminate according to an embodiment is not particularly limited, but the hole transport layer and the emitting layer may be formed by a solution coating method.

The solution coating method is a method in which a solution that contains a component for forming a layer dissolved or dispersed therein is applied to an area where the layer is to be formed (hereinafter, referred to as “layer-forming area”).

The first and second organic compounds according to an embodiment of the present invention have excellent solubility in an organic solvent. Therefore, the first organic compound and the second organic compound according to an embodiment may advantageously be used in production of a laminate (for example, an electroluminescent device) by a solution coating method.

The hole transport layer according to an embodiment may be formed by applying a solution in which a first organic compound, a second organic compound, and, if necessary, other hole transport materials are dissolved in a solvent to the layer-forming area.

In addition, the emitting layer according to an embodiment may be formed by applying a solution in which a material for forming the emitting layer, for example, quantum dots or organic metal complex, is dissolved or dispersed in a solvent to the layer-forming area.

The hole transport layer according to an embodiment includes a domain of a liquid crystalline compound in a matrix of an amine-based polymer, whereby the packing of the amine-based polymer becomes denser, and may have excellent solvent resistance. Therefore, even when forming a light-emitting layer on the hole transport layer by a solution coating method, the hole transport layer hardly dissolves in a composition for forming the light-emitting layer, i.e., the solvent contained in the composition. Accordingly, for example, when applying the laminate according to an embodiment to an electroluminescent device described later, the device may have excellent performance (in particular, high luminous efficiency and long luminous lifetime).

Accordingly, an embodiment of the present invention may provide a composition for forming a hole transport layer including the above-described first organic compound and the second organic compound. With the above composition, a hole transport layer may properly be formed by a solution coating method, and the hole transport layer may have high resistance to a solvent.

The hole transport layer according to an embodiment may be formed by applying a composition for forming a hole transport layer to the layer-forming area by a solution coating method, followed by heat-treating the coated layer. The temperature of the heat treatment for the composition for forming a hole transport layer may be, for example, greater than or equal to about 80° C. and less than or equal to about 250° C., for example, greater than or equal to about 90° C. and less than or equal to about 230° C., for example, greater than or equal to about 95° C. and less than or equal to about 200° C., for example, greater than or equal to about 100° C. and less than or equal to about 190° C., or for example, greater than or equal to about 110° C. and less than or equal to about 180° C.

In an exemplary embodiment, the temperature of heat treatment to the composition for forming a hole transport layer may be greater than or equal to about 120° C. and less than or equal to about 170° C.

The time for the heat treatment is not particularly limited, but may be, for example, greater than or equal to about 1 minute and less than or equal to about 100 minutes, for example, greater than or equal to about 2 minutes and less than or equal to about 60 minutes, for example, greater than or equal to about 3 minutes and less than or equal to about 30 minutes, or for example, greater than or equal to about 5 minutes and less than or equal to about 15 minutes.

By heat-treating the composition for forming the hole transport layer, the second organic compound may exhibit an orientation into the matrix of the amine-based polymer, and thus, the packing of the amine-based polymer becomes dense. As a result, it becomes difficult for the solvent in the subsequent process to penetrate into the gaps of the organic compounds forming the hole transport layer, for example, the first organic compound. As a result, penetration of the solvent from the surface of the hole transport layer may be suppressed, thereby suppressing the penetration of the solvent into the hole transport layer. Accordingly, solubility of the hole transport layer may decrease, and solvent resistance of the hole transport layer may be improved.

For example, if a heat treatment to the composition for forming a hole transport layer is performed at a temperature that greatly exceeds the glass transition temperature of the amine-based polymer in the composition, for example, at a temperature greater than or equal to about 40° C. higher than the glass transition temperature of the amine-based polymer, packing of the amine-based polymer may progress and the solvent tolerance of the hole transport layer may be improved.

On the other hand, the composition for forming a hole transport layer containing the second organic compound does not require heat treatment at a temperature significantly exceeding the glass transition temperature of the amine-based polymer, and the packing of the amine-based polymer is believed to proceeds by the domain of the liquid crystalline compound.

Meanwhile, an embodiment of the present invention is not limited to the above mechanism.

As described above, another embodiment of the present invention is to provide a method of manufacturing a laminate including a hole transport layer that contains the above described first organic compound and second organic compound, and a light-emitting layer, the method includes forming the laminate including the hole transport layer and the light-emitting layer by a solution coating method.

In addition, another embodiment of the present invention is to provide a method of manufacturing a laminate including a hole transport layer including the above-described first organic compound and second organic compound, and a light-emitting layer, the method includes applying a composition for forming the hole transport layer that includes the first organic compound and the second organic compound dissolved in a solvent to a layer-formed area, and heat-treating the composition applied to the layer-forming area to form the hole transport layer.

In this embodiment, the heat treatment temperature of the composition for forming a hole transport layer may be greater than or equal to the temperature of the liquid crystalline state of the liquid crystalline compound contained in the composition for forming a hole transport layer. Due to this, the liquid crystalline compound may easily form a domain.

In an exemplary embodiment, if the composition for forming a hole transport layer includes a liquid crystalline compound of which the temperature range of the liquid crystalline state is greater than or equal to about 30° C. and less than or equal to about 280° C., for example, greater than or equal to about 40° C. and less than or equal to about 270° C., heat treatment of the composition for forming a hole transport layer may be performed at a temperature of greater than or equal to about 80° C. and less than or equal to about 250° C.

In an exemplary embodiment, if the composition for forming a hole transport layer includes a liquid crystalline compound of which the temperature range of the liquid crystalline state is greater than or equal to about 50° C. and less than or equal to about 260° C., for example, greater than or equal to about 60° C. and less than about 260° C., heat treatment of the composition for forming a hole transport layer may be performed at a temperature of greater than or equal to about 90° C. and less than or equal to about 230° C.

In an exemplary embodiment, if the composition for forming a hole transport layer includes a liquid crystalline compound of which the temperature range of the liquid crystalline state is greater than or equal to about 80° C. and less than or equal to about 250° C., for example, greater than or equal to about 90° C. and less than about 250° C., heat treatment of the composition for forming a hole transport layer may be performed at a temperature of greater than or equal to about 100° C. and less than or equal to about 200° C., for example, greater than or equal to about 120° C. and less than or equal to about 190° C.

A solution coating method may include a spin coating, a casting, a micro gravure coating, a gravure coating, a bar coating, a roll coating, a wire bar coating method, a dip coating method, a spray coating method, a screen printing method, a flexographic printing method, an offset printing method, an ink jet printing method, and the like.

Solvent that may be used to form a hole transport layer (the solvent that can be used in the composition for forming a hole transport layer) is not particularly limited as long as it can dissolve the first and second organic compounds described above.

The solvent that may be in the solution coating method may be appropriately selected depending on the type of the solute.

Examples of the solvent include toluene, xylene, ethyl benzene, diethylbenzene, methyl benzene, propyl benzene, cyclohexyl benzene, dimethoxy benzene, anisole, ethoxy toluene, phenoxy toluene, isopropyl biphenyl, dimethyl anisole, phenyl acetate, phenyl propionate, methyl benzoate, ethyl benzoate, cyclohexane, and the like.

The solvent may include only one type, or a mixture of two or more types.

Also, the amount of solvent that may be used (content of solvent in the composition for forming a hole transport layer) is not particularly limited, but, in view of a point of ease in application, the total concentration of the above-described first organic compound and second organic compound may be, for example, greater than or equal to about 0.1 wt % and less than or equal to about 10 wt %, or for example, greater than or equal to about 0.5 wt % and less than or equal to about 5 wt %.

Solvent that may be used to form the emitting layer (solvent that may be used in a composition for forming a light-emitting layer) may be the same as the solvent that may be used in the composition for forming a hole transport layer, but a solvent that does not dissolve a material contained in a hole transport layer, such as, for example, the first organic compound and the second organic compound may advantageously be selected.

Also, the amount of the solvent used (content of the solvent in the composition for forming a light-emitting layer) may also be the same as in the case of the composition for forming a hole transport layer.

### [An Example of Electroluminescent Device]

Hereinafter, with reference to FIG. 2, an electroluminescent device according to an embodiment will be described in detail.

FIG. 2 is a schematic diagram showing an electroluminescent device according to an embodiment.

In the present specification, “electroluminescent device” may be abbreviated as “EL device”.

Meanwhile, in the description of the drawings, the same elements are given the same symbols, and overlapping descriptions may be omitted. Also, the dimensions in the drawing may be exaggerated for convenience of explanation. There are cases where it is different from the actual ratio.

As shown in FIG. 2, the EL device 100, which includes a laminate according to an embodiment, includes a substrate 110, a first electrode 120 disposed on the substrate 110, a hole injection layer 130 disposed on the first electrode 120, a hole transport layer 140 disposed on the hole injection layer 130, a light emitting layer 150 disposed on the hole transport layer 140, an electron transport layer 160 disposed on the light emitting layer 150, an electron injection layer 170 disposed on the electron transport layer 160, and a second electrode 180 disposed on the electron injection layer 170.

The hole transport layer 140 and the light emitting layer 150 may correspond to the hole transport layer and the light emitting layer, respectively, in the laminate according to an embodiment.

### [Substrate]

Substrate 110 may be any substrate used in general EL devices. For example, substrate 110 may be a glass substrate, a semiconductor substrate, such as a silicon substrate, or a transparent plastic substrate, and the like.

### [First Electrode]

A first electrode 120 is formed on the substrate 110.

The first electrode 120 is, for example, an anode and is made of a material having a large work function, such as, for example, metal, alloy, or conductive material. For example, the first electrode 120 may be made of a material having excellent transparency and conductivity, such as, for example, indium tin oxide (In₂O₃—SnO₂: ITO), indium zinc oxide (In₂O₃—ZnO), tin oxide (SnO₂), transmissive type zinc oxide (ZnO) etc., to form a transparent electrode.

Additionally, the first electrode 120 may be a reflective electrode formed by laminating magnesium (Mg), aluminum (Al), and the like, on the transparent conductive layer.

Additionally, after forming the first electrode 120 on the substrate 110, cleaning, UV-ozone treatment, and the like may be performed, if required.

### [Hole Injection Layer]

A hole injection layer 130 is formed on the first electrode 120.

The hole injection layer 130 is a layer that facilitates injection of holes from the first electrode 120, and may have a thickness (dry film thickness; hereinafter, the same) of, for example, greater than or equal to about 10 nm and less than or equal to about 1,000 nm, or for example, greater than or equal to about 20 nm and less than or equal to about 50 nm.

The hole injection layer 130 may be formed from a known hole injection material.

Examples of the hole injection material may include, for example, poly(ether ketone)-containing triphenylamine (TPAPEK), 4-isopropyl-4′-methyldiphenyliodonium tetrakis(pentafluorophenyl) borate (PPBI), N,N′-diphenyl-N,N′-bis-[4-(phenyl-m-tolyl-amino)-phenyl]-biphenyl-4,4′-diamine (DNTPD), copper phthalocyanine, 4,4′,4″-tris(3-methylphenylphenylamino)triphenylamine (m-MTDATA), N,N′-di(1-naphthyl)-N,N′-diphenylbenzidine (NPB), 4,4′,4″-tris(diphenylamino)triphenylamine (TDATA), 4,4′,4″-tris(N,N-2-naphthylphenylamino)triphenylamine (2-TNATA), polyaniline/dodecylbenzenesulfonic acid, poly(3,4-ethylenedioxythiophene)/poly(4-styrenesulfonate) (PEDOT/PSS), polyaniline/10-camphorsulfonic acid, and the like.

### [Hole Transport Layer]

A hole transport layer 140 is formed on the hole injection layer 130.

The hole transport layer 140 is a layer with the function of transporting holes, and may have a thickness of, for example, greater than or equal to about 10 nm and less than or equal to about 150 nm, or for example, greater than or equal to about 20 nm and less than or equal to about 50 nm.

The hole transport layer 140 according to this embodiment may be the hole transport layer according to the above-described hole transport layer. That is, the hole transport layer 140 according to this embodiment includes a first organic compound and a second organic compound having hole transport properties, the first organic compound includes an amine-based polymer, and the second organic compound is a liquid crystalline compound, and the hole transport layer has a domain of the liquid crystalline compound.

In addition, the hole transport layer 140 may be formed by a solution coating method. Therefore, the hole transport layer 140 may be formed by coating a solution that contains the amine-based polymer and the second organic compound. According to this method, the hole transport layer 140 may have improved solvent resistance. Additionally, it is possible to extend the durability (luminescence life) of the EL device 100. In addition, it is possible to improve the performance (luminous efficiency) of the EL device 100. Further, as the hole transport layer can be formed by using a solution coating method, a large area layer may efficiently be formed.

The hole transport layer 140 according to this embodiment may be the same as the hole transport layer described above, detailed description is omitted.

### [Emitting Layer]

An emitting layer 150 is formed on the hole transport layer 140.

The emitting layer 150 according to an embodiment may be an emitting layer described as above. That is, the emitting layer 150 according to this embodiment is a layer that emits light by fluorescence, phosphorescence, etc. Although the emitting layer 150 may be applied by vacuum deposition, spin coating, inkjet printing, etc., it may be formed as a film by using a solution coating method.

The emitting layer 150 may be formed to have a thickness of, for example, greater than or equal to about 10 nm and less than or equal to about 60, or, for example, greater than or equal to about 20 nm and less than or equal to about 50 nm.

In an exemplary embodiment, the emitting layer 150 may be formed by a solution coating method.

The emitting layer 150 according to an embodiment has the same structure as the emitting layer described above, and thus, detailed description is omitted.

### [Electron Transport Layer]

An electron transport layer 160 may be formed on the emitting layer 150.

The electron transport layer 160 may be a layer having a function of transporting electrons, and may be formed by vacuum deposition, spin coating, inkjet method, etc.

For example, the electron transport layer 160 may have a thickness of, for example, greater than or equal to about 15 nm and less than or equal to about 50 nm.

The electron transport layer 160 may be formed of a known electron transport material.

Examples of known electron transport materials include, for example, (8-quinolinato) lithium (Liq), tris(8-quinolinato) aluminum (Alq₃), compounds having a nitrogen-containing aromatic ring etc.

Examples of the compound having a nitrogen-containing aromatic ring include, for example, a compound having a pyridine ring, such as, for example, 1,3,5-tri[(3-pyridyl)-phen-3-yl]benzene, a compound having a triazine ring, such as, for example, 2,4,6-tris(3′-(pyridin-3-yl)biphenyl-3-yl)-1,3,5-triazine, a compound having an imidazole ring, such as, for example, 2-(4-(N-phenylbenzoimidazolyl-1-yl-phenyl)-9,10-dinaphthylanthracene, 1,3,5-tris(N-phenylbenzimidazol-2-yl)benzene (TPBI), and the like.

Electron transport material may include only one type, or a mixture or two or more types.

### [Electron Injection Layer]

An electron injection layer 170 may be formed on the electron transport layer 160.

The electron injection layer 170 is a layer that has a function to facilitate injection of electrons from the second electrode 180.

The electron injection layer 170 may be formed by a vacuum deposition method, etc.

The electron injection layer 170 may be formed to have a thickness of, for example, greater than or equal to about 0.1 nm and less than or equal to about 5 nm, or, for example, greater than or equal to about 0.3 nm and less than or equal to about 2 nm.

Electron injection layer 170 may be formed of any known material that can be used as a material for forming an electron injection layer.

For example, electron injection layer 170 may be formed of, for example, a lithium compound, such as, for example, (8-quinolinato) lithium (Liq), Lithium fluoride (LiF), etc., sodium chloride (NaCl), cesium fluoride (CsF), lithium oxide (Li₂O), barium oxide (BaO), and the like.

Electron injection material may be used alone, or a mixture of two or more types of electron injection materials may be used.

A second electrode 180 may be formed on the electron injection layer 170.

The second electrode 180 may be formed by a vacuum deposition method, etc.

The second electrode 180 may be, for example, a cathode, and be made of a metal, alloy, or conductive compound that has a small work function.

For example, the second electrode 180 may be formed of metal, such as, for example, lithium (Li), magnesium (Mg), aluminum (Al), calcium (Ca), etc.; or an alloy, such as, for example, aluminum-lithium (Al—Li), magnesium-indium (Mg—In), magnesium-silver (Mg—Ag), etc.; to form as a reflective electrode.

The second electrode 180 may be formed to have a thickness of, for example, greater than or equal to about 10 nm and less than or equal to about 200 nm, or, for example, greater than or equal to about 50 nm and less than or equal to about 150 nm.

Alternatively, the second electrode 180 may be formed as a transparent electrode by using a thin film of the metal having a thickness of less than or equal to about 20 nm, or a transparent conductive film, such as, for example, indium tin oxide (In₂O₃—SnO₂), indium zinc oxide (In₂O₃—ZnO), and the like.

After reading the laminate and the method for fabricating it described in the present application, other aspects of a method of fabricating the electroluminescent device are not particularly limited, and a method known in the art to which the invention pertains may be used.

In the laminate according to an embodiment, the hole transport layer including the first organic compound and the second organic compound and the light emitting layer may be formed by a solution coating method.

Accordingly, another embodiment of the present invention provides a method of manufacturing an electroluminescent device that includes a laminate according to an embodiment, the laminate including a hole transport layer including a first organic compound and a second organic compound, and a light-emitting layer, wherein the laminate including the hole transport layer and the light-emitting layer is formed by a solution coating method.

Meanwhile, there is no particular limitation on a method of forming other layers than the laminate according to an embodiment. The other layers other than the laminate according to an embodiment may be formed by a method, such as, for example, a vacuum deposition method, or a solution coating method, such as, for example, a spray coating method.

As described above, as an example of an electroluminescent device according to an embodiment of the present invention, the EL device 100 according to an exemplary embodiment of the present invention has been described.

The EL device 100 according to an embodiment of the present invention includes a laminate according to an embodiment, whereby improving lifespan of the EL device 100, for example, a quantum dot electroluminescent device.

The EL device 100 according to an embodiment of the present invention may be formed to have another known stacked structure. For example, the EL device 100 may omit one or more layers selected from the group consisting of a hole injection layer 130, an electron transport layer 160, and an electron injection layer 170, or may further include an additional layer.

Also, each layer of the EL device 100 may be formed as a single layer, or as a plurality of layers.

For example, the EL device 100 may further include a hole blocking layer between the electron transport layer 160 and the light emitting layer 150 to prevent excitons or holes from diffusing into the electron transport layer 160.

Meanwhile, the hole blocking layer may be formed of, for example, an oxadiazole derivative, a triazole or a triazole derivative, a phenanthroline or a phenanthroline derivative, etc.

For example, the EL device 100 may further include an electron blocking layer between the hole transport layer 140 and the light emitting layer 150 to prevent excitons or electrons from diffusing into the hole transport layer 140.

Additionally, the laminate according to an embodiment may be applied to an electroluminescent device other than the QLED or OLED.

Other electroluminescent device is not particularly limited, but examples include organic-inorganic perovskite light-emitting device.

Although embodiments of the invention have been described in detail, this is for illustrative purposes only and is illustrative at the same time, and is not intended to limit the scope of the invention. It is clear that the scope of the invention should be construed in accordance with the appended claims.

### EXAMPLE

The effects of the present invention will be explained using the following examples and comparative examples. However, the technical scope of the invention is not limited to the following examples.

Meanwhile, in the examples, unless otherwise specified, operations were performed at room temperature (i.e., 25° C.).

Also, unless otherwise specified, [%] and “part” mean “weight %” and “weight part”, respectively.

### <Syntheses of Polymer of P-1 to P-6>

As the first organic compound, the compounds (or polymers) shown as P-1 to P-6 are synthesized by the methods described below.

### (Synthesis of Intermediate 1)

Intermediate 1 was synthesized as shown in Scheme 1.

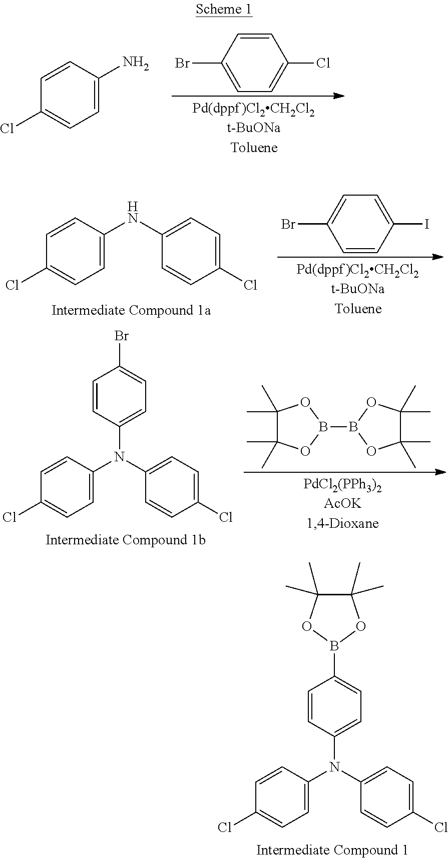

To a 3 liter (L)-4 neck flask, 4-chloroaniline (510 mmol, 65.0 g), 1-bromo-4-chlorobenzene (535 mmol, 102.4 g), sodium t-butoxide (t-BuONa) (764 mmol, 73.4 g), toluene (1,020 ml), and [1,1′-bis(diphenylphosphino)ferrocene]palladium(II) dichloride dichloromethane adduct (Pd(dppf)Cl₂·CH₂Cl₂) (15.3 mmol, 12.5 g) were added, and reaction was started by heating and stirring at 110° C. under a nitrogen atmosphere. Then, the reactants were heated and stirred at 110° C. for 6 hours while confirming the progress of the reaction.

Upon completion of the reaction, the obtained solution was cooled to room temperature and filtered through Celite. After concentrating the obtained solution, silica gel chromatography (hexane:toluene=7:3, v/v) was performed for purification. The obtained solution was concentrated and then purified by recrystallization using toluene and hexane. The obtained solid was vacuum dried (50° C., 16 hours) to obtain Intermediate 1a.

To a 1L-4 neck flask, intermediate 1a (168 mmol, 40.0 g), p-bromoiodobenzene (252 mmol, 71.3 g), t-BuONa (336 mmol, 32.3 g), toluene (336 ml) and Pd(dppf) Cl₂·CH₂Cl₂ (0.50 mmol, 4.12 g) were added, and reaction was started by heating and stirring at 110° C. under a nitrogen atmosphere. Then, the reactants were heated and stirred at 110° C. for 6 hours while confirming the progress of the reaction.

Upon completion of the reaction, the obtained solution was cooled to room temperature and filtered through Celite. The obtained solution was concentrated and purified by silica gel chromatography (hexane:toluene=7:3, v/v). After concentrating the obtained solution, it was purified by recrystallization using tetrahydrofuran (THF) and methanol twice. The obtained solid was vacuum dried (50° C., 16 hours) to obtain Intermediate 1b.

To a 2L-3 neck flask, intermediate 1b (178 mmol, 70.0 g), bis(pinacolato)diboron (267 mmol, 67.8 g), potassium acetate (AcOK) (356 mmol, 34.2 g), and 1,4-dioxane (650 ml) were added, with stirring. Then, bis(triphenylphosphine) palladium (II) dichloride (PdCl₂(PPh₃)₂)) (5.34 mmol, 4.36 g) was added thereto and refluxed under argon atmosphere for 20 hours. The obtained solution was cooled to room temperature and filtered using Celite to remove insoluble material. After concentrating the obtained solution, it was filtered through a silica gel pad and raw material components were removed. The obtained solution was concentrated and then purified by recrystallization using toluene and hexane. The obtained solid was vacuum dried (50° C., 12 hours) to obtain Intermediate 1.

### (Synthesis of Intermediate 2)

Intermediate 2 was synthesized as shown in Scheme 2.

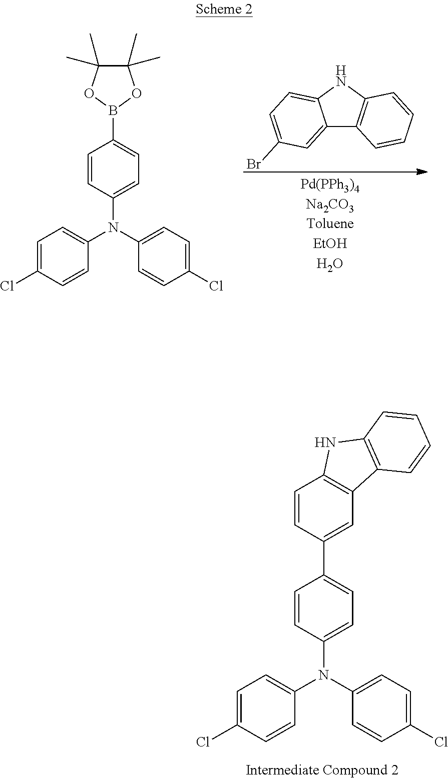 [SMILES: CC1(C)OB(c2ccc(N(c3ccc(Cl)cc3)c3ccc(Cl)cc3)cc2)OC1(C)C ; Brc1ccc2[nH]c3ccccc3c2c1 ; Clc1ccc(N(c2ccc(Cl)cc2)c2ccc(-c3ccc4[nH]c5ccccc5c4c3)cc2)cc1]

To a 500 mL-3 neck flask, Intermediate 1 (73.1 mmol, 9.0 g), 3-bromo-9H-carbazole (73.1 mmol, 16.1 g) and toluene (180 ml) were added and dissolved. Then, an aqueous solution of Na₂CO₃ (109.7 mmol, 5.82 g, 90 mL of pure water) and ethanol (90 mL) were added thereto and dispersed, and nitrogen was bubbled for 30 minutes. Subsequently, tetrakis(triphenylphosphino) palladium (0) (Pd(PPh₃)₄) (3.66 mol, 2.11 g) was added thereto and refluxed under a nitrogen atmosphere for 5 hours.

Upon completion of the reaction, the obtained solution was cooled to room temperature, diluted with toluene, and washed three times with pure water. The obtained solution was dried using MgSO₄ and then filtered through a silica gel pad. The solvent of the obtained filtrate was removed by distillation under reduced pressure, and the residue was washed with toluene and methanol twice for purification. The obtained solid was vacuum dried (50° C., 16 hours) to obtain Intermediate 2.

### (Synthesis of Intermediate 3)

Intermediate 3 was synthesized as shown in Scheme 3.

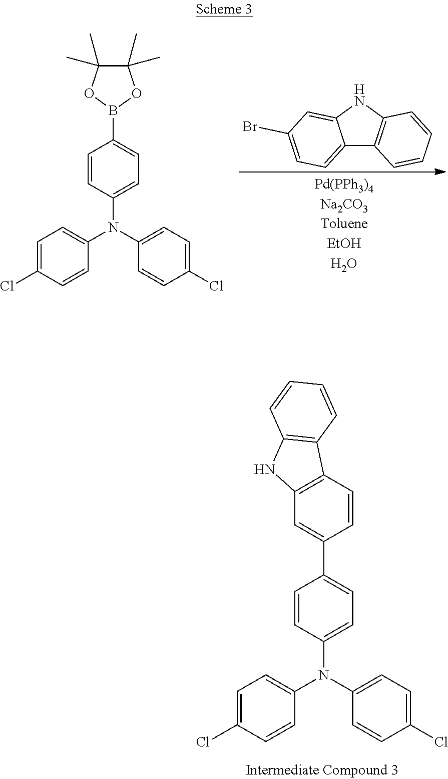 [SMILES: CC1(C)OB(c2ccc(N(c3ccc(Cl)cc3)c3ccc(Cl)cc3)cc2)OC1(C)C ; Brc1ccc2c(c1)[nH]c1ccccc12 ; Clc1ccc(N(c2ccc(Cl)cc2)c2ccc(-c3ccc4c(c3)[nH]c3ccccc34)cc2)cc1]

Intermediate 3 was synthesized in the same manner as that of Intermediate 2, except that 3-bromo-9H-carbazole in Synthesis of Intermediate 2 was changed to 2-Bromo-9H-carbazole.

### (Synthesis of Monomer M-1)

Monomer M-1 was synthesized as shown in Scheme 4.

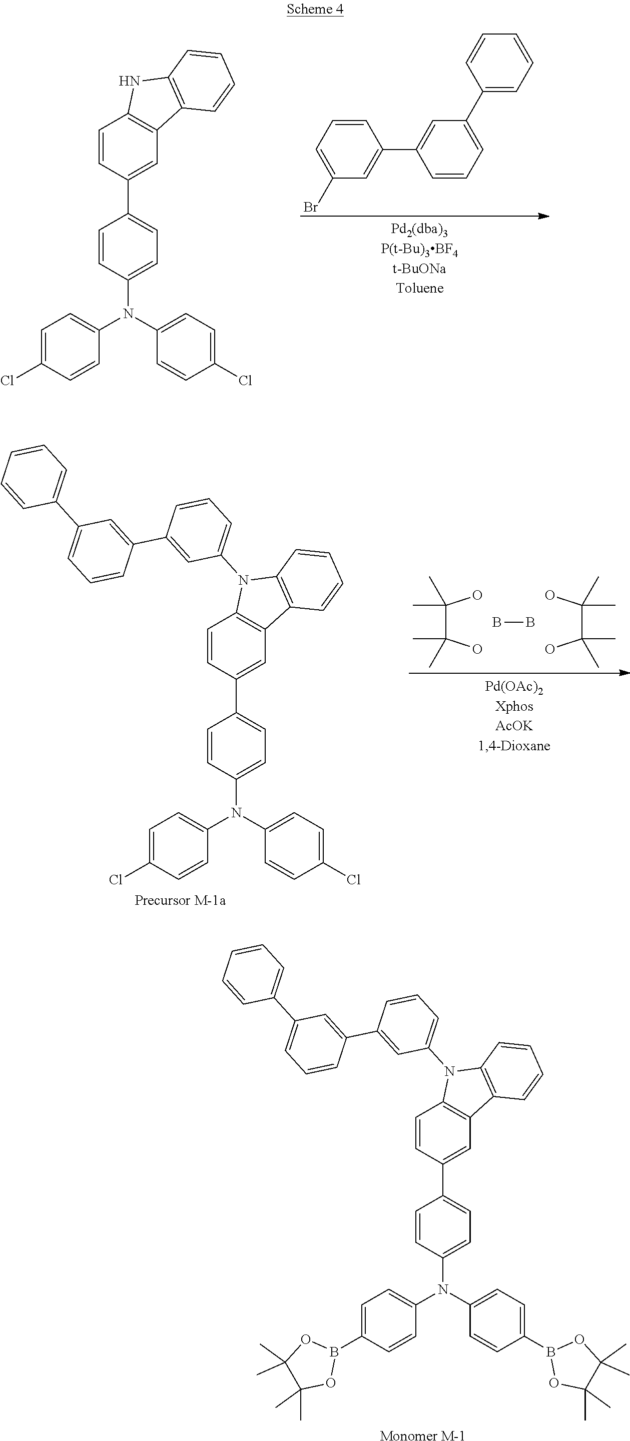

To a 300 mL-4 neck flask, Intermediate 2 (28.8 mmol, 13.8 g), 3-bromo-1,1′:3′,1″-terphenyl (31.7 mmol, 9.79 g), t-BuONa (43.2 mmol, 4.15 g), and toluene (160 ml) were added and dispersed. Then, tris(dibenzylidene acetone) dipalladium (0.58 mmol, 0.53 g) and tri-tert-butyl phosphine tetrafluoro borate (1.15 mmol, 0.33 g) were added, and heated and stirred at 110° C. for 4 hours in a nitrogen atmosphere.

Upon completion of the reaction, the obtained solution was cooled to room temperature, and the insoluble matter was removed by using Celite. The solvent of the filtrate was removed by distillation under reduced pressure, and the residue was purified using column chromatography (silica gel, hexane/toluene) to obtain a precursor M-1a.

To a 2L-3 neck flask, precursor M-1a (15.5 mmol, 11.0 g), bis(pinacolato) diboron (62.2 mmol, 15.8 g), potassium acetate (93.3 mmol, 9.0 g), and 1,4-dioxane (155 ml) were added and stirred to be dispersed. Then, palladium acetate (1.55 mmol, 0.35 g) and 2-dicyclohexylphosphino-2′,4′,6′-triisopropyl biphenyl (Xphos) (1.55 mmol, 0.74 g) were added thereto, and refluxed for 5 hours under argon atmosphere.

The obtained solution was cooled to room temperature and filtered using Celite to remove insoluble material. The solvent of the filtrate was removed by distillation under reduced pressure, and the raw material components were removed by filtration through a silica gel pad.

The obtained solution was concentrated and then purified by recrystallization using toluene and acetonitrile. The obtained solid was vacuum dried (50° C., 12 hours) to obtain monomer M-1.

### (Synthesis of Monomer M-2)

Monomer M-2 was synthesized as in Scheme 5, and in the same manner as the procedure of synthesizing monomer M-1, except for changing Intermediate 2 in the procedure of synthesizing monomer M-1 to Intermediate 3.

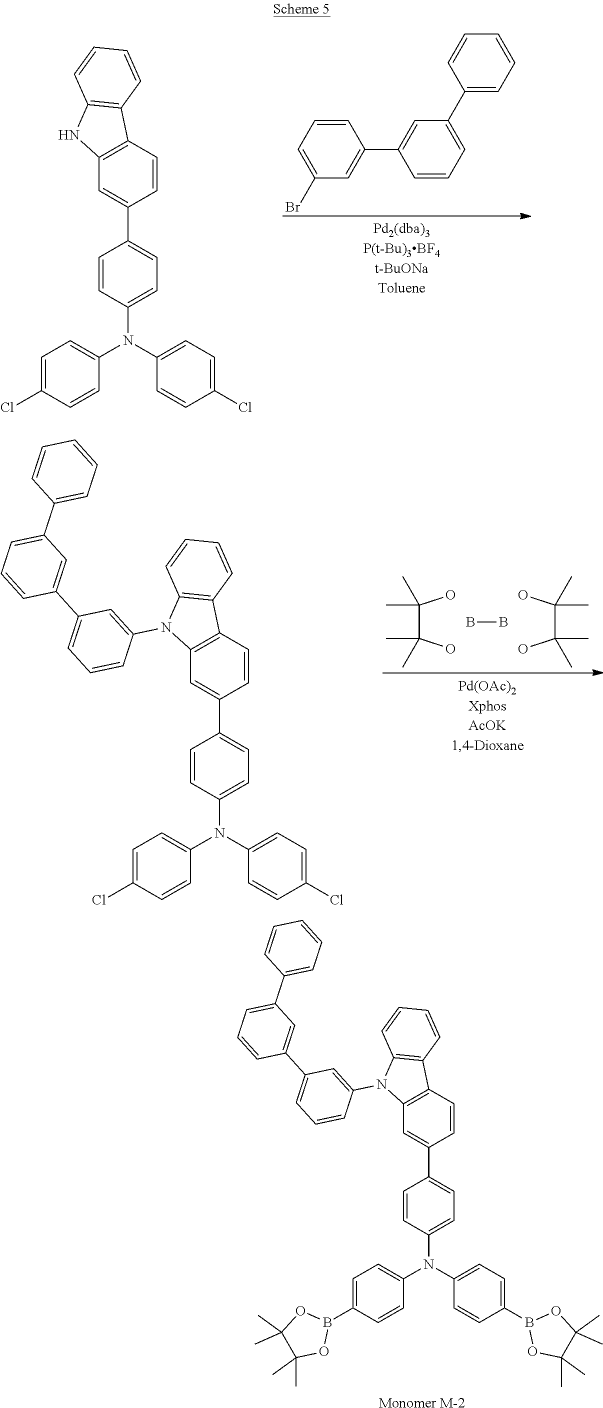

### (Synthesis of Monomer M-3)

Monomer M-3 was synthesized as in Scheme 6, and in the same manner as the procedure of synthesizing monomer M-2, except for changing 3-bromo-1,1′:3′,1″-terphenyl in the procedure of synthesizing monomer M-2 to 4-bromo-4″-hexyl-1,1′: 4′,1″-terphenyl.

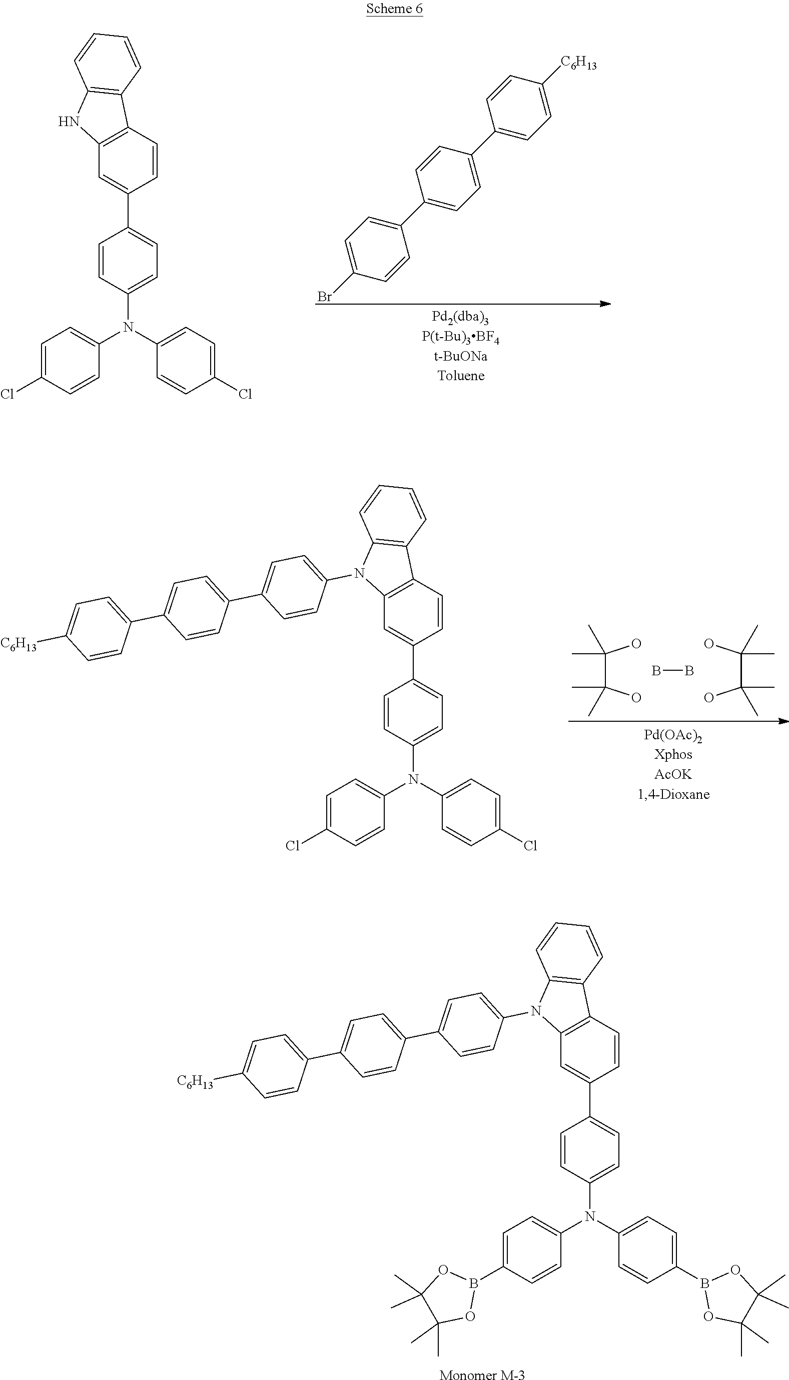

### (Synthesis of Monomer M-4)

Monomer M-4 was synthesized as in Scheme 7, and in the same manner as the procedure of synthesizing monomer M-1, except for changing 3-bromo-1,1′:3′,1″-terphenyl in the procedure of synthesizing monomer M-1 to 4-bromo-4″-hexyl-1,1′: 4′,1″-terphenyl.

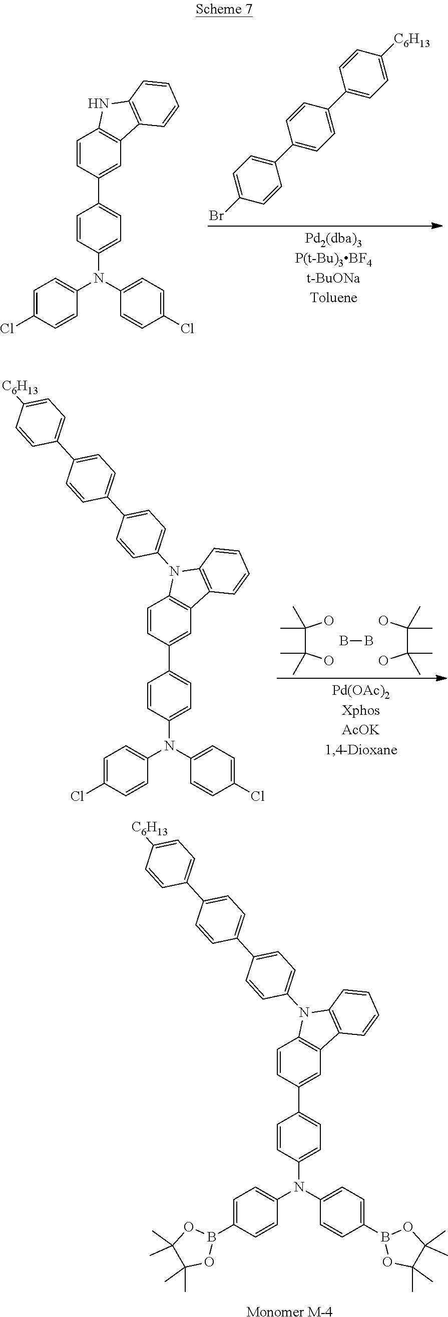

### (Synthesis of Monomer M-5)

Monomer M-5 was synthesized as shown in Scheme 8 by using monomer M-2 as a starting material.

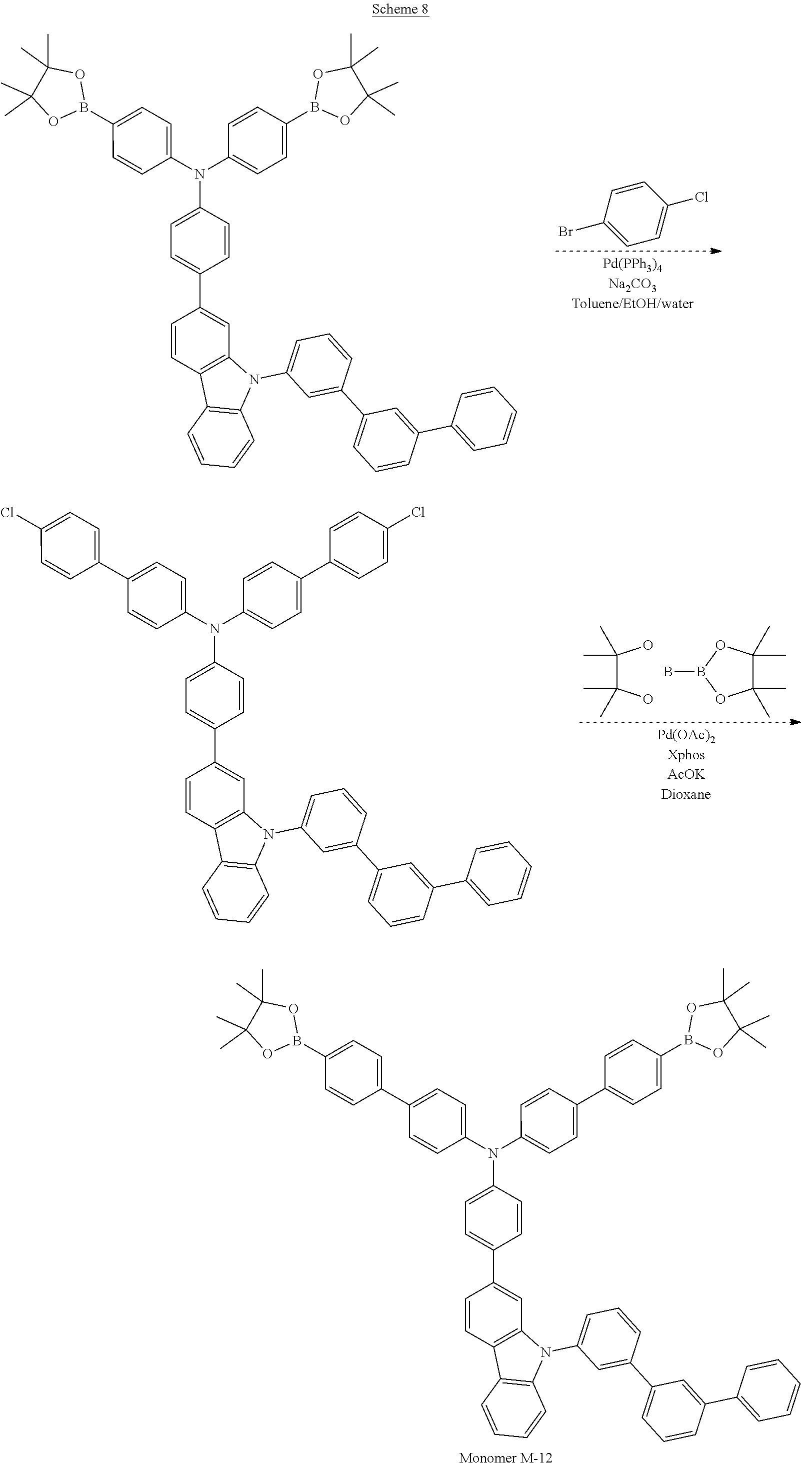

### (Synthesis of Polymer P-1)

Under argon atmosphere, Monomer M-1 (1.978 g), 9,9-dioctyl-3,6-dibromofluorene (1.212 g), palladium acetate (5.0 mg), tris(2-methoxyphenyl) phosphine (47.0 g), toluene (64 mL), and 20 wt % aqueous solution of tetraethylammonium hydroxide (11.5 g) were mixed, and refluxed and stirred for 6 hours. Subsequently, phenylboronic acid (268.8 mg), bis(triphenylphosphine) palladium (II) dichloride (93.5 mg), and 20 wt % aqueous solution of tetraethylammonium hydroxide (11.5 g) were added thereto, and heated and refluxed for 6 hours. Then, the aqueous layer of the obtained solution was removed, and N, N-diethyldithiocarbamide sodium trihydrate (7.51 g) and ion exchanged water (70 mL) were added thereto and stirred at 85° C. for 6 hours.

After separating the organic layer from the aqueous layer of the obtained solution, the organic layer was mixed with water and 3 wt % of acetic acid for washing. The organic layer was added dropwise to methanol to precipitate the polymer, which was then dried to obtain a solid. The solid was dissolved in toluene, passed through a column chromatograph filled with silica gel/alumina, and the solvent was removed by distillation under reduced pressure. The obtained liquid was added dropwise to methanol, and the precipitated solid was separated and dried to obtain polymer P-1.

### (Synthesis of Polymer P-2)

Polymer P-2 was synthesized in the same manner as Polymer P-1, except for changing monomer M-1 and 9,9-dioctyl-3,6-dibromo fluorene in the procedure of synthesizing Polymer P-1 to monomer M-2 and 9,9-didecyl-3,6-dibromo fluorene, respectively.

### (Synthesis of Polymer P-3)

Polymer P-3 was synthesized in the same manner as Polymer P-2, except for changing monomer M-2 and 9,9-didecyl-3,6-dibromo fluorene in the procedure of synthesizing Polymer P-2 to monomer M-3 and 9,9-didodecyl-3,6-dibromo fluorene, respectively.

### (Synthesis of Polymer P-4)

Polymer P-4 was synthesized in the same manner as Polymer P-1, except for changing monomer M-1 in the procedure of synthesizing Polymer P-1 to monomer M-4.

### (Synthesis of Polymer P-5)

Polymer P-5 was synthesized in the same manner as Polymer P-3, except for changing 9,9-didodecyl-3,6-dibromo fluorene in the procedure of synthesizing Polymer P-3 to 9,9-dioctyl-3,6-dibromo fluorene.

### (Synthesis of Polymer P-6)

Polymer P-6 was synthesized in the same manner as Polymer P-3, except for changing monomer M-3 in the procedure of synthesizing Polymer P-3 to monomer M-5.

### <Synthesis of LAD-3>

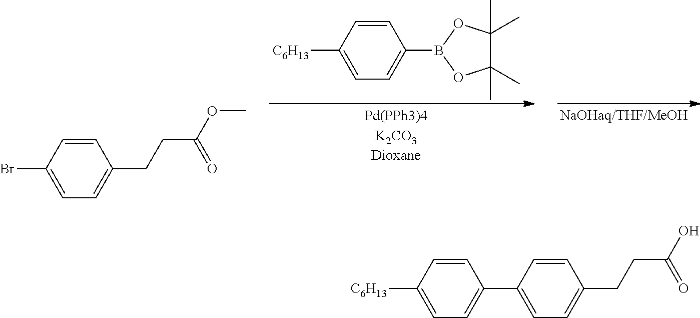

To 300 mL-3-necked flask, methyl 3-(4-bromophenyl) propionate (20.5 mmol, 5.0 g), 4-hexylphenylboronic acid (22.6 mmol, 6.5 g), and dioxane (200 ml) were added and dissolved. Then, aqueous solution of K₂CO₃ (24.7 mmol, 3.41 g, 90 mL of pure water) was added thereto and dispersed, and nitrogen was bubbled for 30 minutes. Subsequently, tetrakis(triphenylphosphino) palladium (0) (Pd(PPh₃)₄) (0.41 mmol, 0.45 g) was added thereto, and the reactants were refluxed under a nitrogen atmosphere for 5 hours.

Upon completion of the reaction, the obtained solution was cooled to room temperature, diluted with toluene, and washed three times with pure water. The obtained organic layer was dried by using MgSO₄, and the solvent was removed by distillation under reduced pressure. The obtained filtrate was re-dissolved in THF (100 ml), 1 M aqueous solution of NaOH (5 ml) and MeOH were added thereto and refluxed under nitrogen atmosphere for 1 hour. The obtained solution was cooled to room temperature, diluted with toluene, and washed three times with pure water. The obtained organic layer was dried by using MgSO₄ and purified by recrystallization using toluene and methanol twice. The obtained solid was vacuum dried (50° C., 16 hours) to obtain LAD-3.

Glass transition temperatures (T_{g}), weight average molecular weights (Mw), and number average molecular weights (Mn) of the obtained polymers P-1 to P-6 are as below.
P-1: T_{g} 134° C., Mw 150,000 Da, Mn 79,000 Da
P-2: T_{g} 121° C., Mw 115,000 Da, Mn 78,000 Da
P-3: T_{g} 135° C., Mw 140,000 Da, Mn 87,000 Da
P-4: T_{g} 140° C., Mw 303,000 Da, Mn 149,000 Da
P-5: T_{g} 152° C., Mw 114,000 Da, Mn 73,000 Da
P-6: T_{g} 123° C., Mw 97,000 Da, Mn 64,000 Da

Meanwhile, the glass transition temperature was measured according to following method.

### (Glass Transition Temperature (T_{g}))

The temperature of each polymer is raised to 270° C. at a temperature increase rate of 10° C./minute (° C./min) using a differential scanning calorimeter (DSC) (manufactured by TA Instruments, brand name: DSC25) and held for 5 minutes, and is rapidly cooled to 0° C. and kept for 5 minutes. Then, the measurement is performed by raising the temperature to 300° C. at a temperature increase rate of 10° C./min. Upon completion of the measurement, the polymer is naturally cooled to room temperature (25° C.).

As a second organic compound, LAD-1 to LAD-5 are prepared as below.

Each of the compounds may be commercially available, or may be synthesized. The temperature range of the liquid crystalline state of each compound are as below.
LAD-1 (product name: 4-cyano-4″-pentyl-p-terphenyl, manufactured by Tokyo Chemical Industry Co., Ltd.): 107° C. to 238° C.
LAD-2 (product name: 2-decyl-7-phenyl [1] benzothieno[3,2-b][1] benzothiophene, manufactured by Tokyo Chemical Industry Co., Ltd.): 138° C. to 250° C.
LAD-3 (product name: 3-(4′-hexyl-[1,1′-biphenyl]-4-yl) propanoic acid, in-house product, synthesized by the above-described “Synthesis of LAD-3”): 106° C. to 152° C.
LAD-4 (product name: 4-ethyl-4′-(trans-4-propylcyclohexyl) biphenyl, manufactured by Tokyo Chemical Industry Co., Ltd.): 69° C. to 166° C.
LAD-5 (product name: trans, trans-3,4,5-trifluoro-4′-(4′-propylbicyclohexyl-4-yl) biphenyl, manufactured by Tokyo Chemical Industry Co., Ltd.): 36° C. to 250° C. or higher.

### (Temperature Range of Liquid Crystalline State)

The temperature of each compound is raised to 300° C. at a temperature increase rate of 2° C./min using a differential scanning calorimeter (DSC) (manufactured by TA Instruments, brand name: DSC25) and held for 5 minutes, and rapidly cooled to 0° C. and kept for 5 minutes. Then, the measurement is performed by raising the temperature to 300° C. at a temperature increase rate of 2° C./min. Upon completion of the measurement, the compound is naturally cooled to room temperature (25° C.).

Here, the temperature range of liquid crystalline state refers to the temperature range between a transition point from a solid phase to an intermediate phase (temperature at the peak of the absorption peak on a side of the lowest temperature) and a transition point from an intermediate phase to an isotropic fluid phase (temperature at the peak of the absorption peak on a side of the highest temperature) of a compound having two or more endothermic peaks in the process of temperature increase by differential scanning calorimetry.

### <Evaluation 1>

### [Solvent Resistance of Hole Transport Layer]

Compositions 1-1 to 1-50 for forming hole transport layers were prepared by dissolving 1 part by weight (total weight of the first organic compound and the second organic compound) of the hole transport materials mixed by the first organic compounds of polymers P-1 to P-6, and the second organic compounds (liquid crystalline compounds) of compounds LAD-1 to LAD-5, in ratios described in Tables 1-1 and 1-2 below, in 99 parts by weight of toluene.

In addition, Comparative Compositions C1-1 to C1-6 for forming comparative hole transport layers were prepared by dissolving only 1 part by weight of the first organic compounds of polymers P-1 to P-6 in 99 parts by weight of toluene.

Example hole transport layers and Comparative hole transport layers were prepared to have a dry film thickness of 30 nm by coating Compositions 1-1 to 1-50 and Comparative Compositions C1-1 to C1-6, respectively, and then, heat-treating the coated films on a hot plate at temperatures described in Tables 1-1 and 1-2 for 10 minutes.

In order to evaluate the solvent resistance of the hole transport layers, the layers were immersed in cyclohexyl benzene for 20 minutes, and the absorption spectra before and after the immersion were compared. The solvent resistance is defined by a percentage ratio (%) of the intensity of the absorption spectrum after solvent immersion divided by the intensity of the absorption spectrum before solvent immersion. The intensity of the absorption spectrum may be measured by a UV-VIS spectroscopy.

Meanwhile, solvent resistance may also be referred to as “remaining film rate”, as the solvent resistance indicates the degree of remaining film after being immersed in a solvent.

In Tables 1-1 and 1-2 below, “A/B/C” in solvent resistance sequentially corresponds to “X/Y/Z” of the “temperature of heat treatment”. For example, the solvent resistance treated at temperature X° C. is A, the solvent resistance treated at temperature Y° C. is B, and the solvent resistance treated at temperature C° C. is C.

### (Hole Transporting First Organic Compounds (Amine-Based Polymers) P-1 to P-6)

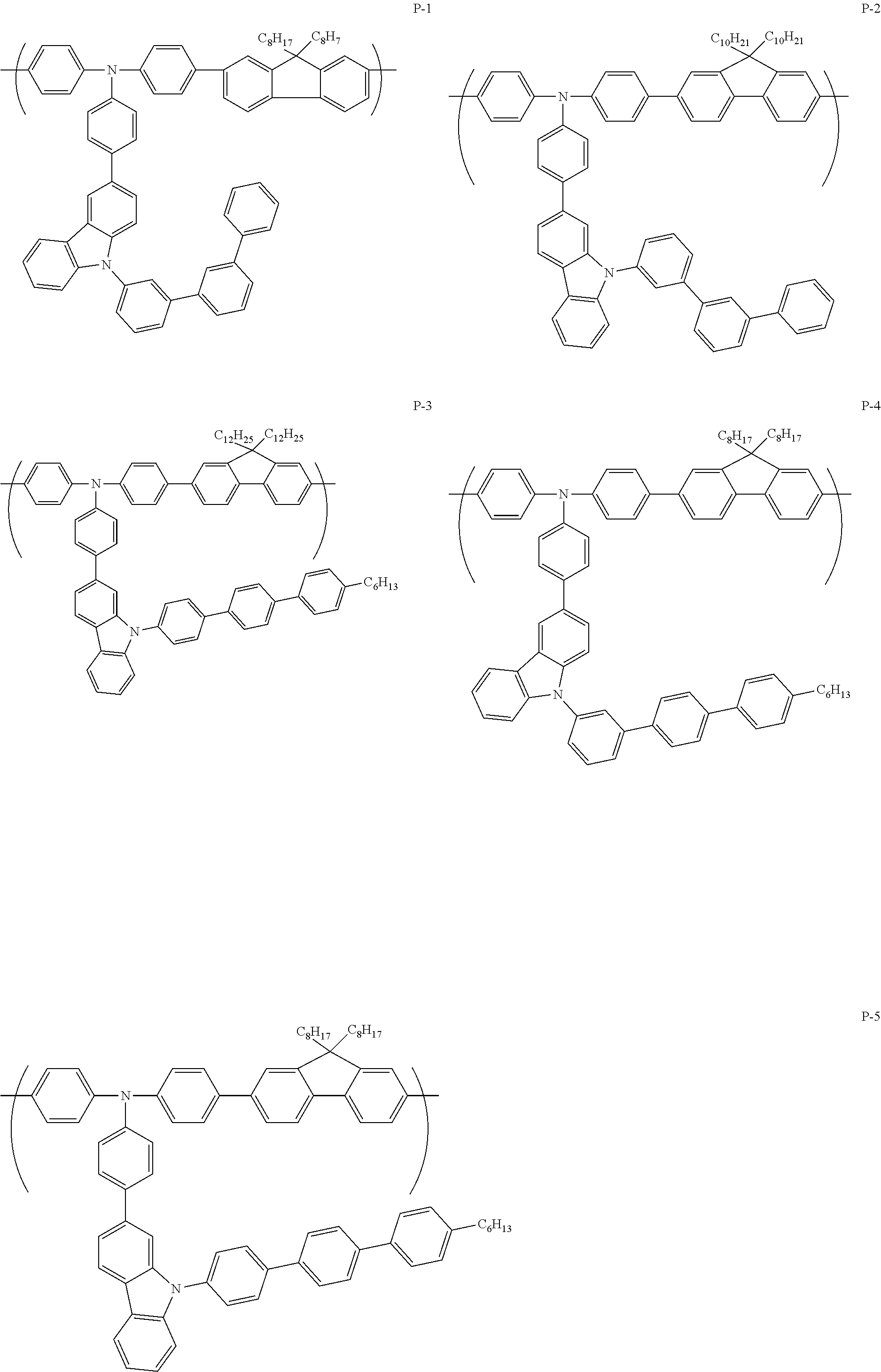

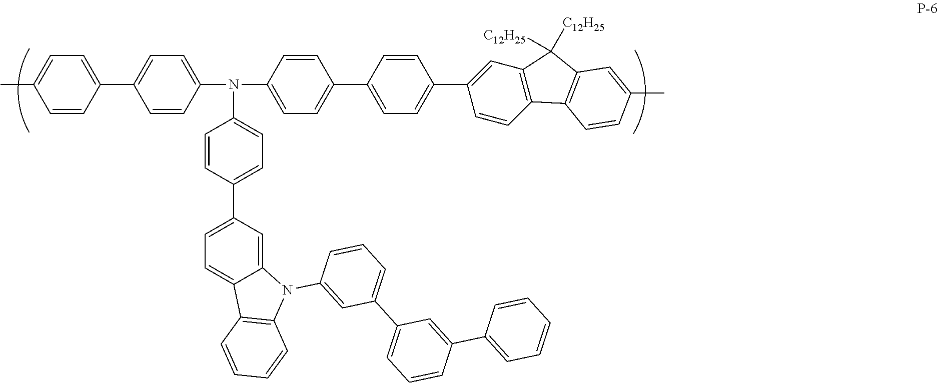

### (Second Organic Compounds (Liquid Crystalline Compounds) LAD-1 to LAD-5)

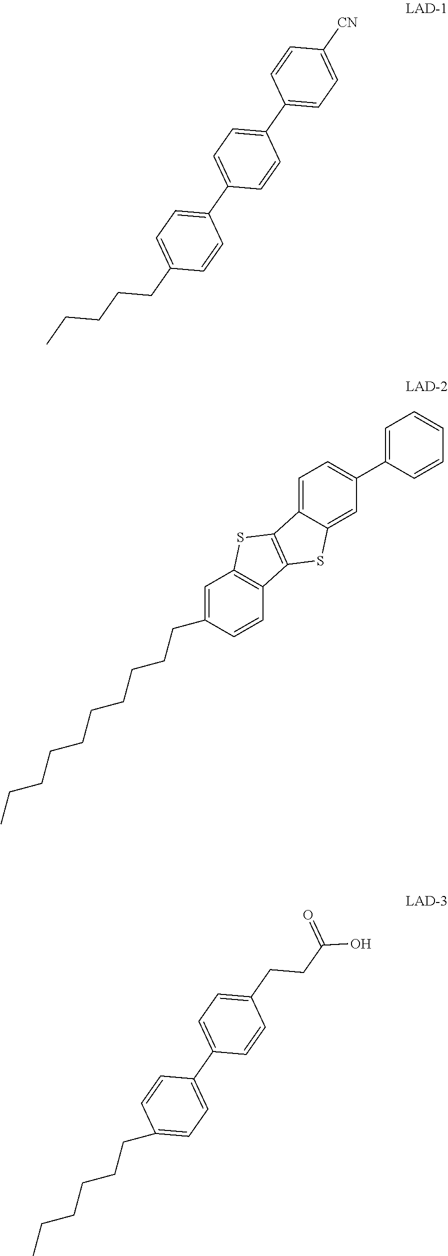 [SMILES: CCCCCc1ccc(-c2ccc(-c3ccc(C#N)cc3)cc2)cc1 ; CCCCCCCCCCc1ccc2c(c1)sc1c3ccc(-c4ccccc4)cc3sc21 ; CCCCCCc1ccc(-c2ccc(CCC(=O)O)cc2)cc1]

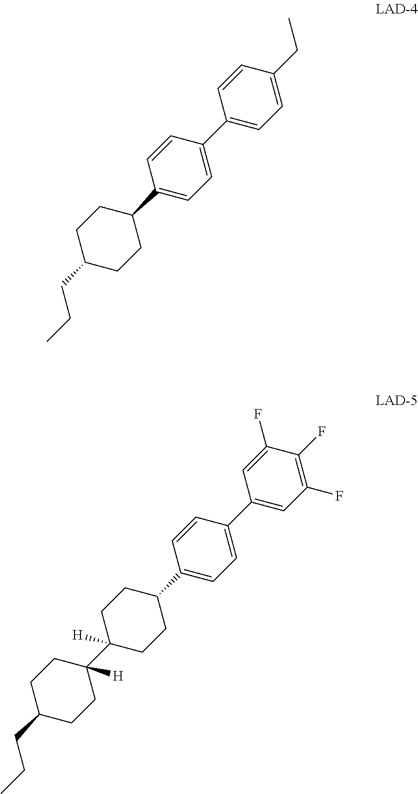

TABLE 1-1

| | | | Ratios of | Tem. of | Solvent- |
|---|---|---|---|---|---|
| Compo- | [1] first | [2] second | [1]:[2] | heat-treating | Resistance |
| sitions | org. com. | org. com. | in weight | [° C.] | [%] |
| 1-1 | P-1 | LAD-1 | 80:20 | 140/160/190 | 100/100/100 |
| 1-2 | P-1 | LAD-1 | 90:10 | 140/160/190 | 99/100/100 |
| 1-3 | P-1 | LAD-1 | 50:50 | 140/160/190 | 99/100/100 |
| 1-4 | P-1 | LAD-2 | 80:20 | 140/160/190 | 100/100/100 |
| 1-5 | P-1 | LAD-2 | 90:10 | 140/160/190 | 99/100/100 |
| 1-6 | P-1 | LAD-2 | 50:50 | 140/160/190 | 99/100/100 |
| 1-7 | P-1 | LAD-3 | 80:20 | 140/160/190 | 100/100/100 |
| 1-8 | P-1 | LAD-3 | 90:10 | 140/160/190 | 99/99/100 |
| 1-9 | P-1 | LAD-3 | 50:50 | 140/160/190 | 99/99/100 |
| 1-10 | P-1 | LAD-4 | 80:20 | 140/160/190 | 100/100/100 |
| 1-11 | P-1 | LAD-4 | 90:10 | 140/160/190 | 99/99/100 |
| 1-12 | P-1 | LAD-4 | 50:50 | 140/160/190 | 99/99/100 |
| 1-13 | P-1 | LAD-5 | 80:20 | 140/160/190 | 99/100/100 |
| 1-14 | P-1 | LAD-5 | 90:10 | 140/160/190 | 99/99/100 |
| 1-15 | P-1 | LAD-5 | 50:50 | 140/160/190 | 99/99/100 |
| 1-16 | P-2 | LAD-1 | 80:20 | 140/160/190 | 100/100/100 |
| 1-17 | P-2 | LAD-2 | 80:20 | 140/160/190 | 100/100/100 |
| 1-18 | P-2 | LAD-3 | 80:20 | 140/160/190 | 100/100/100 |
| 1-19 | P-2 | LAD-4 | 80:20 | 140/160/190 | 100/100/100 |
| 1-20 | P-2 | LAD-5 | 80:20 | 140/160/190 | 100/100/100 |
| 1-21 | P-3 | LAD-1 | 80:20 | 140/160/190 | 100/100/100 |
| 1-22 | P-3 | LAD-2 | 80:20 | 140/160/190 | 100/100/100 |
| 1-23 | P-3 | LAD-3 | 80:20 | 140/160/190 | 99/100/100 |
| 1-24 | P-3 | LAD-4 | 80:20 | 140/160/190 | 99/100/100 |
| 1-25 | P-3 | LAD-5 | 80:20 | 140/160/190 | 99/100/100 |
| 1-26 | P-4 | LAD-1 | 80:20 | 140/160/190 | 100/100/100 |
| 1-27 | P-4 | LAD-2 | 80:20 | 140/160/190 | 100/100/100 |
| 1-28 | P-4 | LAD-3 | 80:20 | 140/160/190 | 100/100/100 |
| 1-29 | P-4 | LAD-4 | 80:20 | 140/160/190 | 99/100/100 |
| 1-30 | P-4 | LAD-5 | 80:20 | 140/160/190 | 99/100/100 |
| 1-31 | P-5 | LAD-1 | 80:20 | 140/160/190 | 100/100/100 |
| 1-32 | P-5 | LAD-2 | 80:20 | 140/160/190 | 100/100/100 |
| 1-33 | P-5 | LAD-3 | 80:20 | 140/160/190 | 100/100/100 |
| 1-34 | P-5 | LAD-4 | 80:20 | 140/160/190 | 98/99/100 |
| 1-35 | P-5 | LAD-5 | 80:20 | 140/160/190 | 99/100/100 |

TABLE 1-2

| | | | Ratios of | Tem. of | Solvent- |
|---|---|---|---|---|---|
| Compo- | [1] first | [2] second | [1]:[2] | heat-treating | Resistance |
| sitions | org. com. | org. com. | in weight | [° C.] | [%] |
| 1-36 | P-6 | LAD-1 | 80:20 | 140/160/190 | 100/100/100 |
| 1-37 | P-6 | LAD-2 | 80:20 | 140/160/190 | 100/100/100 |
| 1-38 | P-6 | LAD-3 | 80:20 | 140/160/190 | 100/100/100 |
| 1-39 | P-6 | LAD-4 | 80:20 | 140/160/190 | 100/100/100 |
| 1-40 | P-6 | LAD-5 | 80:20 | 140/160/190 | 99/100/100 |
| C1-1 | P-1 | none | 100:0 | 140/160/190 | 95/97/100 |
| 1-41 | P-1 | LAD-1 | 95:5 | 140/160/190 | 98/98/100 |
| 1-42 | P-1 | LAD-1 | 40:60 | 140/160/190 | 98/98/100 |
| 1-43 | P-1 | LAD-2 | 95:5 | 140/160/190 | 98/98/100 |
| 1-44 | P-1 | LAD-2 | 40:60 | 140/160/190 | 98/98/100 |
| 1-45 | P-1 | LAD-3 | 95:5 | 140/160/190 | 97/98/100 |
| 1-46 | P-1 | LAD-3 | 40:60 | 140/160/190 | 97/98/100 |
| 1-47 | P-1 | LAD-4 | 95:5 | 140/160/190 | 97/98/100 |
| 1-48 | P-1 | LAD-4 | 40:60 | 140/160/190 | 97/98/100 |
| 1-49 | P-1 | LAD-5 | 95:5 | 140/160/190 | 97/98/100 |
| 1-50 | P-1 | LAD-5 | 40:60 | 140/160/190 | 97/98/100 |
| C1-2 | P-2 | none | 100:0 | 140/160/190 | 98/99/100 |
| C1-3 | P-3 | none | 100:0 | 140/160/190 | 94/98/100 |
| C1-4 | P-4 | none | 100:0 | 140/160/190 | 92/95/100 |
| C1-5 | P-5 | none | 100:0 | 140/160/190 | 94/95/100 |
| C1-6 | P-6 | none | 100:0 | 140/160/190 | 91/94/100 |

### <Evaluation 2>

### [Fabricating of Quantum Dot Electroluminescent Device]

An ITO (Indium tin oxide)-annexed glass substrate was used as a first electrode (anode), in which the ITO is patterned with a film thickness of 150 nm on the glass substrate. The ITO-annexed glass substrate was sequentially cleaned by using a neutral detergent, deionized water, and isopropyl alcohol, and then subjected to UV-ozone treatment. Then, poly(3,4-ethylene dioxythiophene)/poly(4-styrenesulfonate) (PEDOT/PSS) (manufactured by Sigma-Aldrich) was applied onto the ITO-annexed glass substrate by using a spin coating method to have a dry film thickness of 30 nm and dried. As a result, a hole injection layer having a thickness (dry film thickness) of approximately 30 nm was formed on the ITO-annexed glass substrate.

Onto the hole injection layer, compositions for forming hole transport layers in which the hole transport first organic compound and the second (liquid crystalline) organic compound were dissolved in a weight ratio of 8:2 in toluene at a total concentration of 1.0 wt % are coated to have dry film thicknesses of 30 nm by using a coating method. Subsequently, the films were heat treated at 140° C. for 10 minutes to form hole transport layers. As a result, hole transport layers having a thickness (dry film thickness) of about 30 nm were formed on the hole injection layers.

Quantum dot dispersions were prepared by dispersing ZnTeSe/ZnSe/ZnS (core/shell/shell; average diameter approx. 10 nm) blue quantum dots in cyclohexyl benzene at a concentration of 1.0 wt %. The quantum dot dispersions were coated onto the hole transport layers such that a dry film thickness will become 30 nm by using a spin coating method, and dried. As a result, quantum dot emitting layers having a thickness (dry film thickness) of approximately 30 nm were formed on the hole transport layers.

Meanwhile, the light generated by irradiating ultraviolet rays to the quantum dot dispersions had a centered wavelength of about 462 nm and a FWHM (full width at half maximum) of about 30 nm.

The quantum dot emitting layer was completely dried.

Onto the quantum dot emitting layer, lithium 8-hydroxyquinolate (Liq) and 1,3,5-tris(N-phenyl benzimidazol-2-yl)benzene (TPBI) (manufactured by Sigma-Aldrich) were co-deposited as an electron transport material by using a vacuum deposition device. As a result, an electron transport layer having a thickness of approximately 36 nm was formed on the quantum dot emitting layer.

Using a vacuum deposition device, lithium 8-hydroxy quinolate (Liq) was deposited on the electron transport layer. As a result, an electron injection layer having a thickness of about 0.5 nm was formed on the electron transport layer.

Aluminum (Al) was deposited on the electron injection layer by using a vacuum deposition device. As a result, a second electrode (cathode) having a thickness of about 100 nm was formed on the electron injection layer.

Accordingly, a quantum dot electroluminescent device was obtained.

### [Evaluation of Quantum Dot Electroluminescent Device]

With respect to the quantum dot electroluminescent devices prepared by the above processes, luminous efficiency and luminous lifetime were evaluated by using a method described below. The results are shown in Table 2.

### (Luminous Efficiency)

With respect to each quantum dot electroluminescent device, if voltage is applied, current begins to flow at a constant voltage, and the quantum dot electroluminescent device emits light. Using a direct current constant voltage power supply (manufactured by KEYENCE, source meter), voltage is gradually increased across each device, and the current value and luminance are measured by using a measuring device (SR-3, manufactured by Topcom) when the device emits light. Here, the measurement ends when the luminance begins to decline.

Current value per unit area (current density) of each device is calculated from the area of the device, and the luminance (cd/m²) is divided by the current density (A/m²) to calculate the current efficiency (cd/A).

In Table 2 below, the highest current efficiency in the measured voltage range is taken as “Cd/Aₘₐₓ.”

Meanwhile, current efficiency represents the efficiency (conversion efficiency) of converting current to luminous energy, and the higher the current efficiency, the higher the device performance.

In addition, the external quantum efficiency (EQE) (%) at Cd/Aₘₐₓ was calculated and the luminous efficiency was evaluated on the assumption that the luminous spectra radiance spectrum measured by a luminance measurement device performs Lambertian radiation.

In addition, using a direct current constant voltage power supply (manufactured by KEYENCE, source meter), when a voltage is applied to each of the quantum dot electroluminescent devices, current begins to flow at a constant voltage, and the quantum dot electroluminescent device emits light. While measuring the light emission of each device using a luminance measurement device (SR-3, manufactured by Topcom), the current is gradually increased until the luminance reaches 1000 nit (cd/m²). When this happens, keep the current constant and leave it alone. Here, the voltage at 1000 nit is set to “V@1000nit”.

### (Luminous Lifespan)

A predetermined voltage is applied to each quantum dot electroluminescent device by using a direct current constant voltage power supply (made by Keyence Co., Ltd., source meter) such that the quantum dot electroluminescent device emits light. Then, while measuring the luminance of each quantum dot electroluminescent device by using a luminous measurement device (SR-3, manufactured by Topcom), current is gradually increased and kept constant when the luminance reaches 650 nit (cd/m²).

Time until the luminance value measured by the luminance measurement device gradually decreases and reaches 50% of the initial luminance is set to “LT₅₀ (hr)” which may have a unit of hour.

The results are shown in Table 2.

In Table 2 below, each value for Examples 2-1 to 2-30 and Comparative Examples 2-1A to 2-6A is calculated as relative values to those expressed as 100%, which were obtained by the comparative devices (Comparative Examples 2-1B to 2-6B) that have hole transport layers obtained by heat-treating at 190° C. to have solvent resistance while not including liquid crystalline organic compounds.

Specifically, values of Examples 2-1 to 2-5 and Comparative Example 2-1A were calculated as relative values to the value 100% of Comparative Example 2-1B; values of Examples 2-6 to 2-10 and Comparative Example 2-2A were calculated as relative values to the value 100% of Comparative Example 2-2B as 100%; values of Examples 2-11 to 2-15 and Comparative Example 2-3A were calculated as relative values to the value 100% of Comparative Example 2-3B; values of Examples 2-16 to 2-20 and Comparative Example 2-4A were calculated as relative values to the value 100% of Comparative Example 2-4B; values of Examples 2-21 to 2-25 and Comparative Example 2-5A were calculated as relative values to the value 100% of Comparative Example 2-5B; and values of Examples 2-26 to 2-30 and Comparative Example 2-6A were calculated as relative values to the value 100% of Comparative Example 2-6B.

TABLE 2

| | | [1] first | [2] second | EQE (not | LT50 (not |
|---|---|---|---|---|---|
| | | org. com. | org. com. | added: 100) | added: 100) |
| EXE. | 2-1 | P-1 | LAD-1 | 106 | 122 |
| | 2-2 | P-1 | LAD-2 | 102 | 98 |
| | 2-3 | P-1 | LAD-3 | 106 | 101 |
| | 2-4 | P-1 | LAD-4 | 101 | 120 |
| | 2-5 | P-1 | LAD-5 | 100 | 105 |
| Com. Exa. 2-1A | | P-1 | none 140° | 99 | 92 |
| | | | C. treat | | |
| Com. Exa. 2-1B | | P-1 | none 190° | 100 | 100 |
| | | | C. treat | | |
| EXE. | 2-6 | P-2 | LAD-1 | 104 | 111 |
| | 2-7 | P-2 | LAD-2 | 107 | 109 |
| | 2-8 | P-2 | LAD-3 | 101 | 107 |
| | 2-9 | P-2 | LAD-4 | 103 | 108 |
| | 2-10 | P-2 | LAD-5 | 107 | 119 |
| Com. Exa. 2-2A | | P-2 | none 140° | 98 | 95 |
| | | | C. treat | | |
| Com. Exa. 2-2B | | P-2 | none 190° | 100 | 100 |
| | | | C. treat | | |
| EXE. | 2-11 | P-3 | LAD-1 | 101 | 109 |
| | 2-12 | P-3 | LAD-2 | 103 | 117 |
| | 2-13 | P-3 | LAD-3 | 100 | 120 |
| | 2-14 | P-3 | LAD-4 | 101 | 115 |
| | 2-15 | P-3 | LAD-5 | 100 | 123 |
| Com. Exa. 2-3A | | P-3 | none 140° | 94 | 98 |
| | | | C. treat | | |
| Com. Exa. 2-3B | | P-3 | none 190° | 100 | 100 |
| | | | C. treat | | |
| EXE. | 2-16 | P-4 | LAD-1 | 96 | 116 |
| | 2-17 | P-4 | LAD-2 | 109 | 114 |
| | 2-18 | P-4 | LAD-3 | 104 | 116 |
| | 2-19 | P-4 | LAD-4 | 103 | 122 |
| | 2-20 | P-4 | LAD-5 | 98 | 99 |
| Com. Exa. 2-4A | | P-4 | none 140° | 91 | 97 |
| | | | C. treat | | |
| Com. Exa. 2-4B | | P-4 | none 190° | 100 | 100 |
| | | | C. treat | | |
| EXE. | 2-21 | P-5 | LAD-1 | 104 | 123 |
| | 2-22 | P-5 | LAD-2 | 103 | 114 |
| | 2-23 | P-5 | LAD-3 | 101 | 108 |
| | 2-24 | P-5 | LAD-4 | 100 | 110 |
| | 2-25 | P-5 | LAD-5 | 105 | 118 |
| Com. Exa. 2-5A | | P-5 | none 140° | 93 | 98 |
| | | | C. treat | | |
| Com. Exa. 2-5B | | P-5 | none 190° | 100 | 100 |
| | | | C. treat | | |
| EXE. | 2-26 | P-6 | LAD-1 | 109 | 117 |
| | 2-27 | P-6 | LAD-2 | 101 | 115 |
| | 2-28 | P-6 | LAD-3 | 101 | 109 |
| | 2-29 | P-6 | LAD-4 | 100 | 116 |
| | 2-30 | P-6 | LAD-5 | 103 | 114 |

| | | | | |
|---|---|---|---|---|
| Com. Exa. 2-6A | P-6 | none 140° | 98 | 99 |
| | | C. treat | | |
| Com. Exa. 2-6B | P-6 | none 190° | 100 | 100 |
| | | C. treat | | |

In Table 2, “not added: 100” means that the value of EQE or LT50 in the case where the second organic compound is not added is taken as 100; “none 140° C. treat” means that no second organic compound is added, and the hole transport layer is heat-treated at 140° C.; and “none 190° C. treat” may be understood in a similar way.

Although the embodiments have been described in detail above, the scope of rights is not limited thereto, and various modifications and improvements made by those skilled in the art using the basic concepts defined in the following claims also fall within the scope of rights.

What is claimed is:

1. A laminate comprising a hole transport layer and a light-emitting layer,
the hole transport layer comprising a first organic compound and a second organic compound,
wherein the first organic compound and the second organic compound comprise hole transport properties, the first organic compound comprises an amine-based polymer, and the second organic compound comprises a liquid crystalline compound, and
wherein the hole transport layer comprises a domain of the liquid crystalline compound.

2. The laminate according to claim 1, wherein a solvent resistance value of the hole transport layer is greater than or equal to 95%, wherein the solvent resistance value is a ratio of the intensity of the absorption spectrum at a reference wavelength after immersing the hole transport layer in a solvent to the intensity of the absorption spectrum at a reference wavelength before immersing the hole transport layer in a solvent multiplied by 100%.

3. The laminate according to claim 1, wherein the hole transport layer comprises the liquid crystalline compound in an amount of greater than or equal to 5% by weight (wt %) to less than or equal to 50 wt % based on a total weight of all organic compounds contained in the hole transport layer.

4. The laminate according to claim 1, wherein the second organic compound is represented by at least one of Chemical Formulae (L1) to (L4): 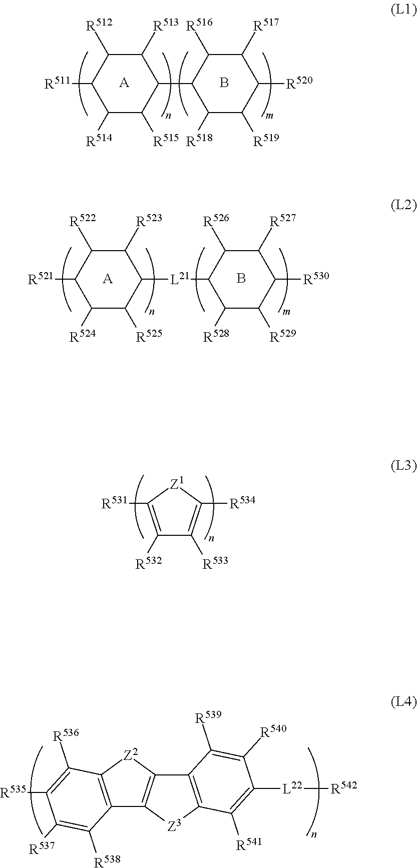
where in Chemical Formulae (L1) to (L4),
ring A and ring B are each independently a benzene ring or a cyclohexane ring,
R⁵¹¹ to R⁵⁴² are each independently hydrogen, deuterium (D), a cyano group, a nitro group, a halogen group, a carboxyl group, an alkyl group having 1 to 20 carbon atoms, an alkoxy group having 1 to 20 carbon atoms, —R⁵⁴³—COOH, wherein R⁵⁴³ is an alkylene group having 1 to 20 carbon atoms or an alkenylene group having 2 to 20 carbon atoms, a deuterated —R⁵⁴³—COOH, wherein R⁵⁴³ is an alkylene group having 1 to 20 carbon atoms or an alkenylene group having 2 to 20 carbon atoms, a silyl group (—Si(R⁵⁴⁴)₃), wherein each occurrence of R⁵⁴⁴ is independently hydrogen or an alkyl group having 1 to 20 carbon atoms, a siloxanyl group (—O—Si(R⁵⁴⁵)₃), wherein each occurrence of R⁵⁴⁵ is independently hydrogen or an alkyl group having 1 to 20 carbon atoms, an amino group (—N(R⁵⁴⁶)₂), wherein each occurrence of R⁵⁴⁶ is independently hydrogen or an alkyl group having 1 to 20 carbon atoms, or —R⁵⁴⁷—C(═O)—R⁵⁴⁸, wherein R⁵⁴⁷ is a single bond, an alkylene group having 1 to 20 carbon atoms or an alkenylene group having 2 to 20 carbon atoms, and R⁵⁴⁸ is an alkyl group having 1 to 20 carbon atoms or an alkenyl group having 2 to 20 carbon atoms,
L²¹ is one of the following structures: 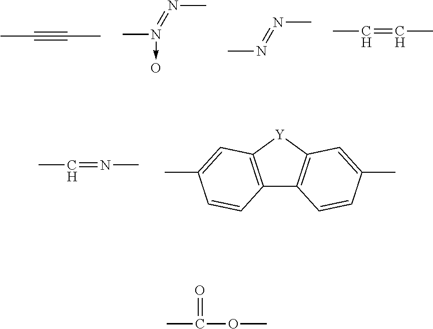
wherein in the above structures,
Y is —Si(R⁵⁴⁹)(R⁵⁵⁰)—, —C(R⁵⁵¹)(R⁵⁵²)—, S, O, Se, or Te, wherein R⁵⁴⁹ to R⁵⁵² are each independently hydrogen, deuterium (D), an alkyl group having 1 to 20 carbon atoms, an alkoxy group having 1 to 20 carbon atoms, —R⁵⁴³—COOH, wherein R⁵⁴³ is an alkylene group having 1 to 20 carbon atoms or an alkenylene group having 2 to 20 carbon atoms, a silyl group (—Si(R⁵⁴⁴)₃), wherein each occurrence of R⁵⁴⁴ is independently hydrogen or an alkyl group having 1 to 20 carbon atoms, or a siloxanyl group (—O—Si(R⁵⁴⁵)₃), wherein each occurrence of R⁵⁴⁵ is independently hydrogen or an alkyl group having 1 to 20 carbon atoms,
Z¹, Z² and Z³ are each independently S, O, Se, or Te,
L²² is a single bond or a phenylene group, and
n and m are each independently an integer of from 1 to 10.

5. The laminate according to claim 4, wherein in Chemical Formulae (L1) and (L2),
when ring A and ring B are each a benzene ring, at least one of R⁵¹¹ to R⁵²⁰ and at least one of R⁵²¹ to R⁵³⁰ each independently comprise a cyano group, a nitro group, a halogen group, a carboxyl group (—COOH), —R⁵⁴³—COOH, wherein R⁵⁴³ is an alkylene group having 1 to 20 carbon atoms or an alkenylene group having 2 to 20 carbon atoms, or —R⁵⁴⁷—C(═O)—R⁵⁴⁸, wherein R⁵⁴⁷ is a single bond, an alkylene group having 1 to 20 carbon atoms or an alkenylene group having 2 to 20 carbon atoms, and R⁵⁴⁸ is an alkyl group having 1 to 20 carbon atoms or an alkenyl group having 2 to 20 carbon atoms, and
when ring A and ring B are each a cyclohexane ring, at least one of R⁵¹¹ to R⁵²⁰, and at least one of R⁵²¹ to R⁵³⁰ each independently comprise hydrogen, deuterium (D), a cyano group, a nitro group, a halogen group, an alkyl group having 1 to 20 carbon atoms, an alkoxy group having 1 to 20 carbon atoms, —R⁵⁴³—COOH, wherein R⁵⁴³ is an alkylene group having 1 to 20 carbon atoms or an alkenylene group having 2 to 20 carbon atoms, a silyl group (—Si(R⁵⁴⁴)₃), wherein R⁵⁴⁴ is each independently hydrogen or an alkyl group having 1 to 20 carbon atoms, a siloxanyl group (—O—Si(R⁵⁴⁵)₃), wherein R⁵⁴⁵ is independently hydrogen or an alkyl group having 1 to 20 carbon atoms, an amino group (—N(R⁵⁴⁶)₂), wherein R⁵⁴⁶ is independently hydrogen, or an alkyl group having 1 to 20 carbon atoms, or a deuterated —R⁵⁴³—COOH, wherein R⁵⁴³ is an alkylene group having 1 to 20 carbon atoms or an alkenylene group having 2 to 20 carbon atoms.

6. The laminate according to claim 1, wherein the amine-based polymer comprises at least one structural unit represented by Chemical Formula (1), (2), or (3): 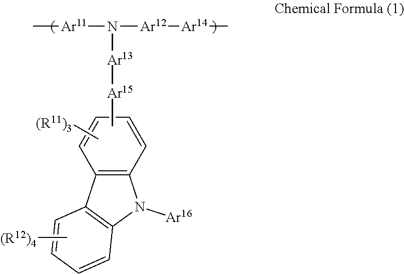
wherein in Chemical Formula (1),
Ar¹¹ and Ar¹² are each independently a substituted or unsubstituted aromatic hydrocarbon group having 6 to 60 carbon atoms,
Ar¹³ is a substituted or unsubstituted aromatic hydrocarbon group having 6 to 120 carbon atoms,
Ar¹⁴ is a substituted or unsubstituted aromatic hydrocarbon group having 6 to 60 carbon atoms, or a substituted or unsubstituted heterocyclic ring having 3 to 60 ring-forming atoms,
Ar¹⁵ is a single bond, or a substituted or unsubstituted heterocyclic ring having 3 to 60 ring-forming atoms,
Ar¹⁶ is a substituted or unsubstituted aromatic hydrocarbon group having 6 to 60 carbon atoms, or a substituted or unsubstituted heterocyclic ring having 3 to 60 ring-forming atoms,
R¹¹ is independently hydrogen atom, an alkyl group, a hydroxyalkyl group, an alkoxy group, an alkoxyalkyl group, an alkenyl group, an alkynyl group, an alkylthio group, an alkoxy carbonyl group, a hydroxyl group (—OH), a carboxyl group (—COOH), a thiol group (—SH), or a cyano group (—CN), and
R¹² is independently hydrogen atom, an alkyl group, a hydroxyalkyl group, an alkoxy group, an alkoxyalkyl group, an alkenyl group, an alkynyl group, an alkylthio group, an alkoxy carbonyl group, a hydroxyl group (—OH), a carboxyl group (—COOH), a thiol group (—SH), or a cyano group (—CN); 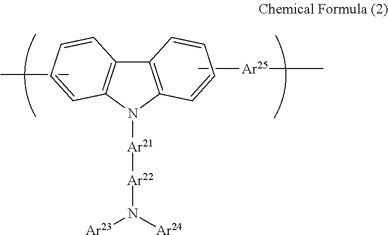
wherein in Chemical Formula (2),
Ar²¹ is a substituted or unsubstituted aromatic hydrocarbon group having 6 to 120 carbon atoms,
Ar²² is a single bond, or a substituted or unsubstituted heterocyclic ring having 3 to 60 ring-forming atoms,
Ar²³ and Ar²⁴ are each independently a substituted or unsubstituted aromatic hydrocarbon group having 6 to 25 carbon atoms, or a substituted or unsubstituted heterocyclic ring having 3 to 60 ring-forming atoms, and
Ar²⁵ is a substituted or unsubstituted aromatic hydrocarbon group having 6 to 60 carbon atoms, or a substituted or unsubstituted heterocyclic ring having 3 to 60 ring-forming atoms, 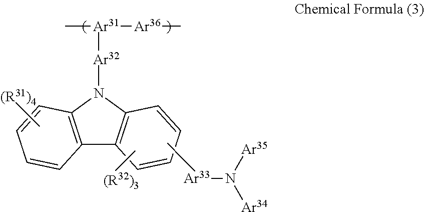
wherein in Chemical Formula (3),
Ar³¹ is a substituted or unsubstituted aromatic hydrocarbon group having 6 to 60 carbon atoms,
Ar³² and Ar³³ are each independently a substituted or unsubstituted aromatic hydrocarbon group having 6 to 120 carbon atoms,
Ar³⁴ and Ar³⁵ are each independently a substituted or unsubstituted aromatic hydrocarbon group having 6 to 60 carbon atoms, or a substituted or unsubstituted heterocyclic ring having 3 to 60 ring-forming atoms,
Ar³⁶ is a substituted or unsubstituted aromatic hydrocarbon group having 6 to 60 carbon atoms, or a substituted or unsubstituted heterocyclic ring having 3 to 60 ring-forming atoms,
R³¹ is independently a hydrogen atom, an alkyl group, a hydroxyalkyl group, an alkoxy group, an alkoxyalkyl group, an alkenyl group, an alkynyl group, an alkylthio group, an alkoxy carbonyl group, a hydroxyl group (—OH), a carboxyl group (—COOH), a thiol group (—SH), or a cyano group (—CN), and
R³² is independently a hydrogen atom, an alkyl group, a hydroxyalkyl group, an alkoxy group, an alkoxyalkyl group, an alkenyl group, an alkynyl group, an alkylthio group, an alkoxy carbonyl group, a hydroxyl group (—OH), a carboxyl group (—COOH), a thiol group (—SH), or a cyano group (—CN).

7. The laminate according to claim 6, wherein in Chemical Formula (1), Ar¹³ is selected from Group I: 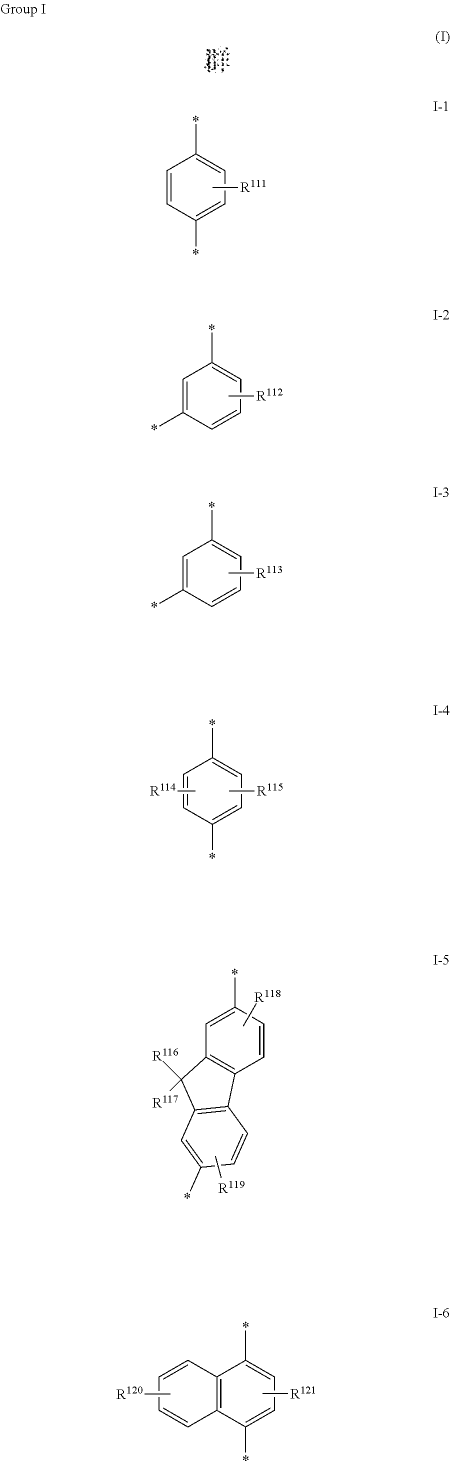 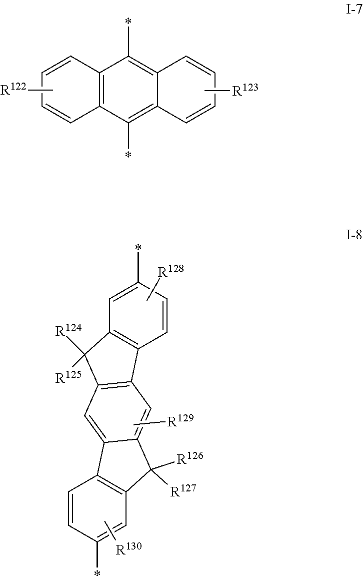
wherein in Group I,
R¹¹¹ to R¹³⁰ are each independently a hydrogen atom, or a linear or branched hydrocarbon group having 1 to 18 carbon atoms, and
* is the bonding position with an adjacent atom.

8. The laminate according to claim 7, wherein Ar¹³ is represented by Chemical Formula I-1 or Chemical Formula 1-4 in Group I, and Ar¹⁵ is a single bond.

9. The laminate according to claim 6, wherein in Chemical Formula (1), Ar¹¹,
Ar¹², and Ar¹⁴ are each independently selected from Group II: 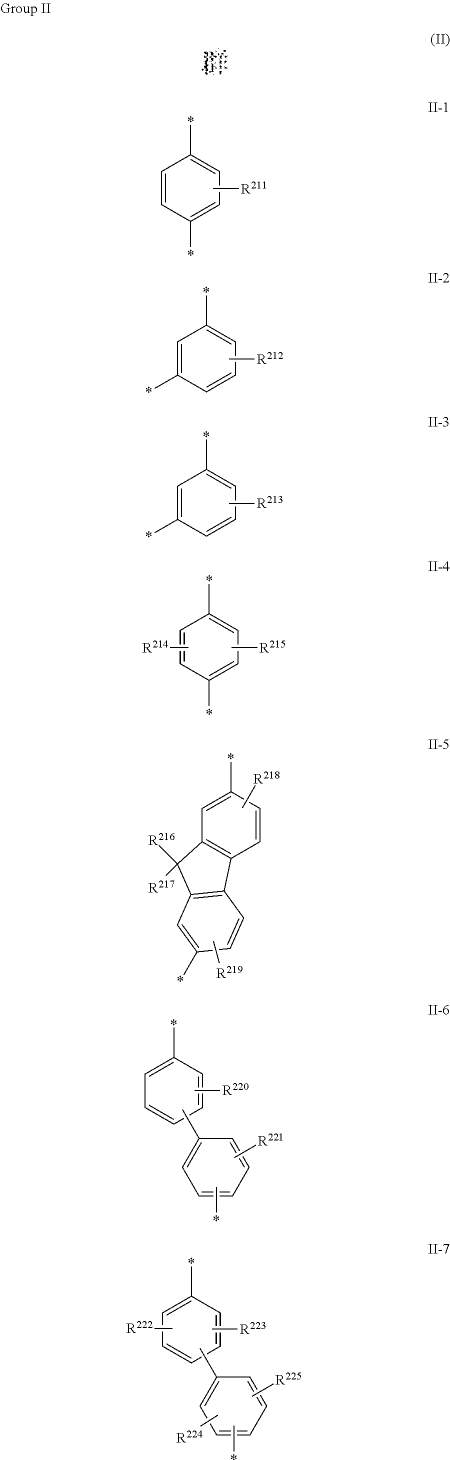 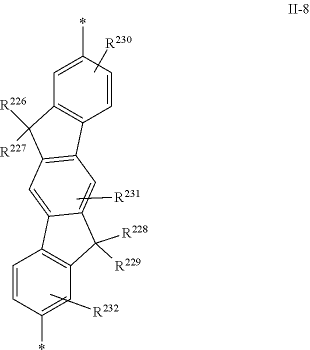
wherein in Group II,
R²¹¹ to R²³² are each independently hydrogen atom, or a linear or branched hydrocarbon group having 1 to 18 carbon atoms, and
* is the bonding position with an adjacent atom.

10. The laminate according to claim 6, wherein in Chemical Formula (1), Ar¹⁶ is selected from Group III: 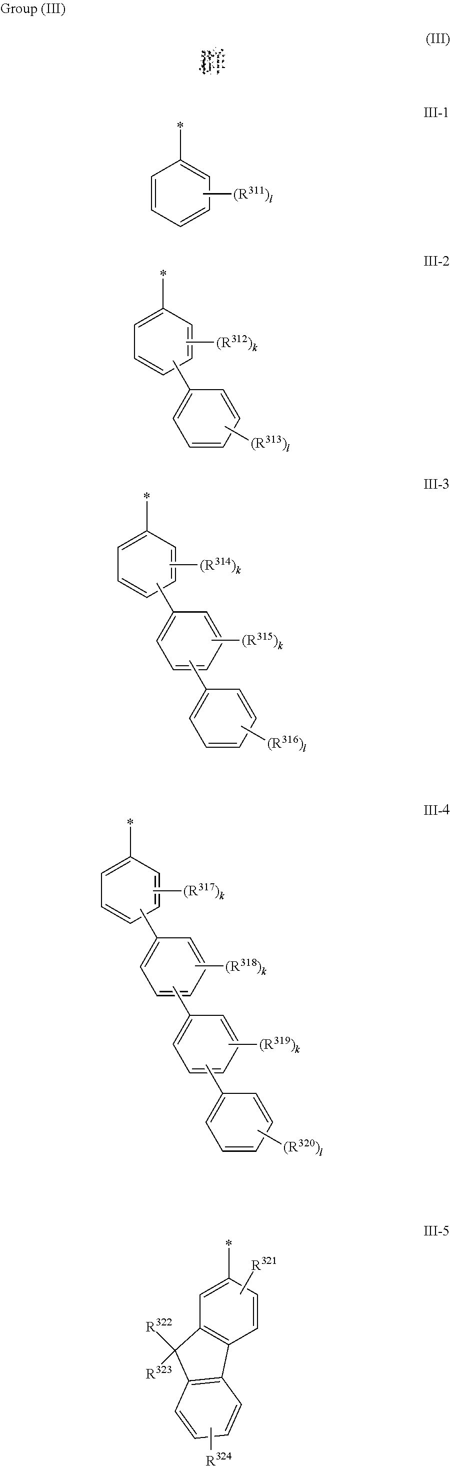 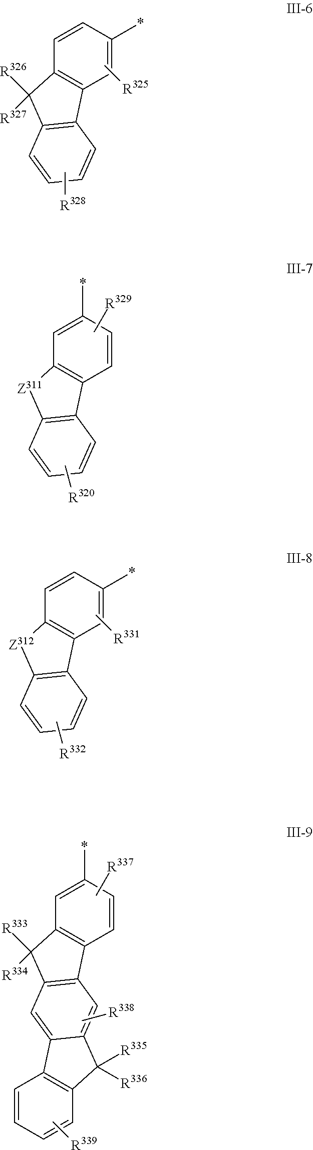
wherein in Group III,
R³¹¹ to R³³⁹ are each independently hydrogen atom, or a linear or branched hydrocarbon group having 1 to 18 carbon atoms,
Z³¹¹ and Z³¹² are each independently oxygen or sulfur,
k is an integer of from 0 to 4,
l is an integer of from 0 to 5, and
* indicates the bonding position with adjacent atoms.

11. The laminate according to claim 6, wherein in Chemical Formula (2), Ar²³ and Ar²⁴ are each independently selected from Group IV:
Group IV 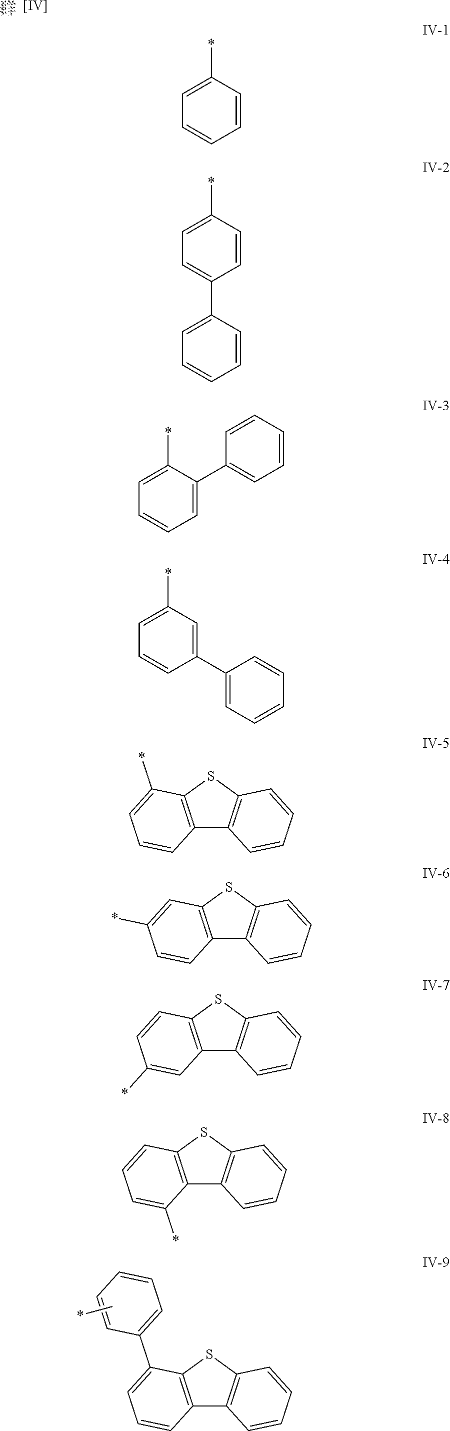 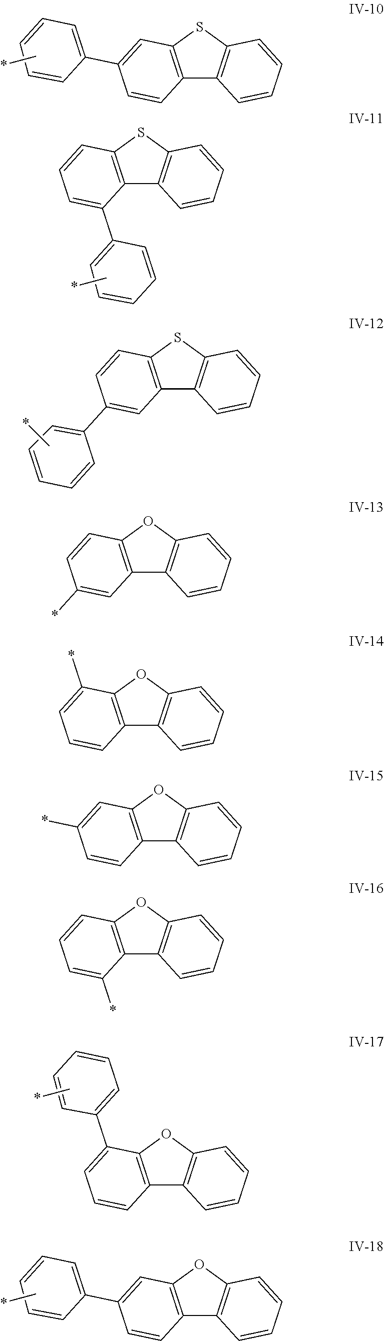 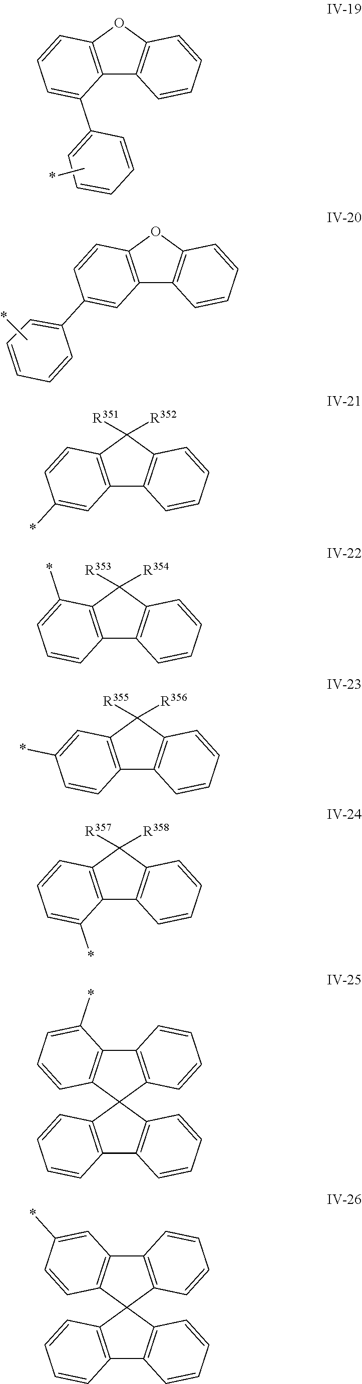 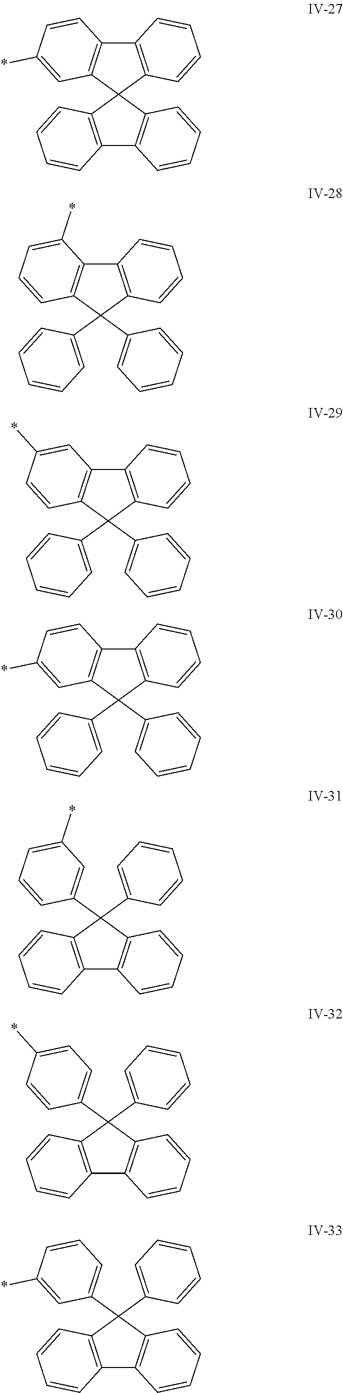
wherein in Group IV,
R³⁵¹ to R³⁵⁸ are each independently an alkyl group having 1 to 20 carbon atoms, and
* indicates the bonding position with an adjacent atom.

12. The laminate according to claim 6, wherein Chemical Formula (2), Ar²⁵ is selected from Group II: 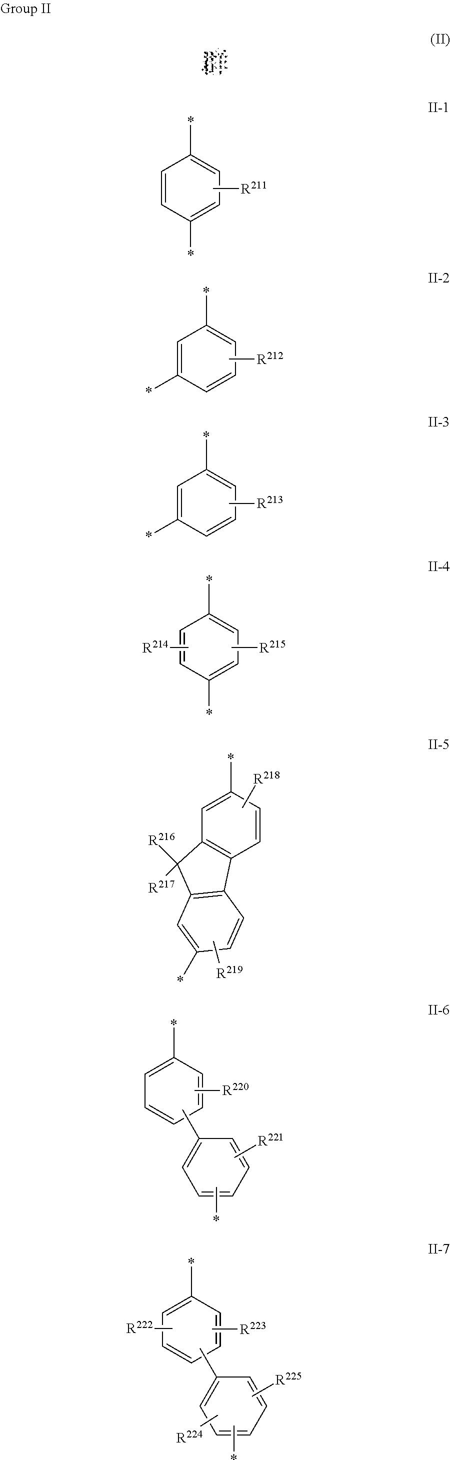 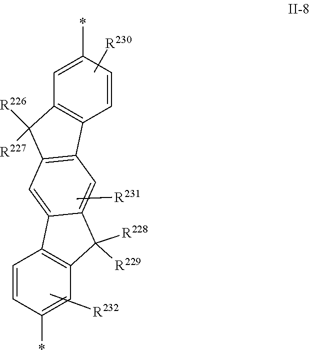
wherein in Group II,
R²¹¹ to R²³² are each independently hydrogen atom, or a linear or branched hydrocarbon group having 1 to 18 carbon atoms, and
* is the bonding position with an adjacent atom.

13. The laminate according to claim 6, wherein the structural unit represented by Chemical Formula (3) comprises at least one of the structural units listed in Group V: 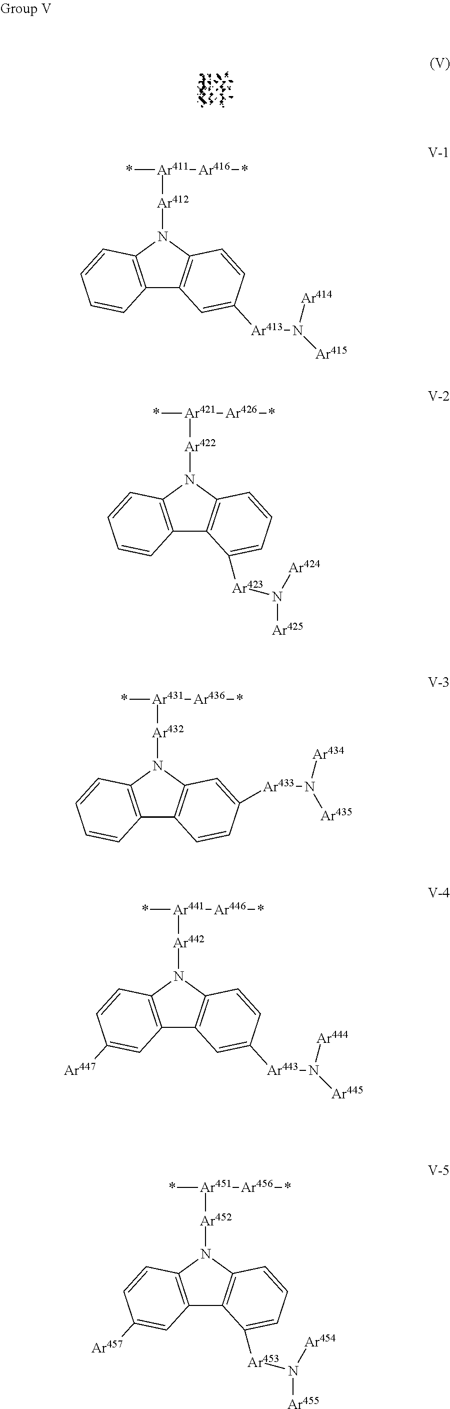 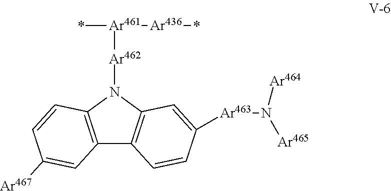
wherein in group V,
Ar⁴¹¹, Ar⁴²¹, Ar⁴³¹, Ar⁴⁴¹, Ar⁴⁵¹, and Ar⁴⁶¹ are each independently a substituted or unsubstituted aromatic hydrocarbon group having 6 to 60 carbon atoms,
Ar⁴¹², Ar⁴²², Ar⁴³², Ar⁴⁴², Ar⁴⁵², Ar⁴⁶², Ar⁴¹³, Ar⁴²³, Ar⁴³³, Ar⁴⁴³, Ar⁴⁵³, and Ar⁴⁶³ are each independently a substituted or unsubstituted aromatic hydrocarbon group having 6 to 120 carbon atoms,
Ar⁴¹⁴, Ar⁴²⁴, Ar⁴³⁴, Ar⁴⁴⁴, Ar⁴⁵⁴, Ar⁴⁶⁴, Ar⁴¹⁵, Ar⁴²⁵, Ar⁴³⁵, Ar⁴⁴⁵, Ar⁴⁵⁵, and Ar⁴⁶⁵ are each independently a group selected from Group IV,
Ar⁴¹⁶, Ar⁴²⁶, Ar⁴³⁶, Ar⁴⁴⁶, Ar⁴⁵⁶, and Ar⁴⁶⁶ are each independently selected from Group II,
Ar⁴⁴⁷, Ar⁴⁵⁷, and Ar⁴⁶⁷ are each independently a hydrogen atom, or a linear or branched hydrocarbon group having 1 to 18 carbon atoms, and
* indicates the bonding position with an adjacent atom: 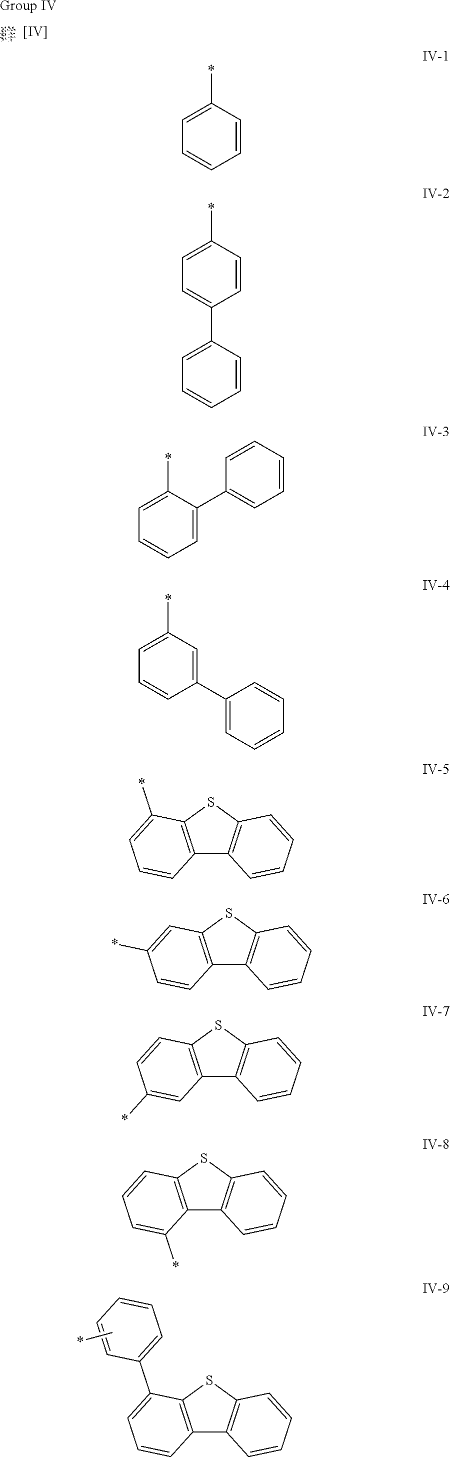 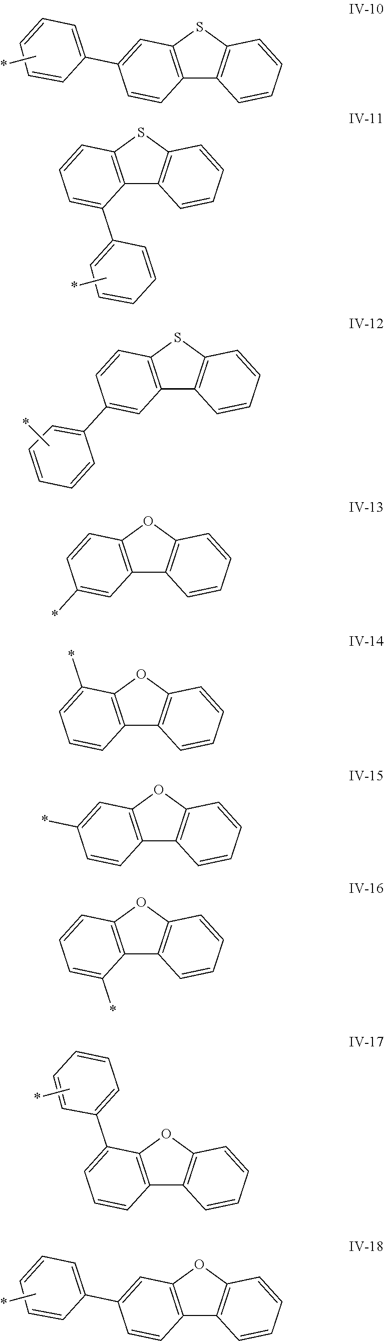 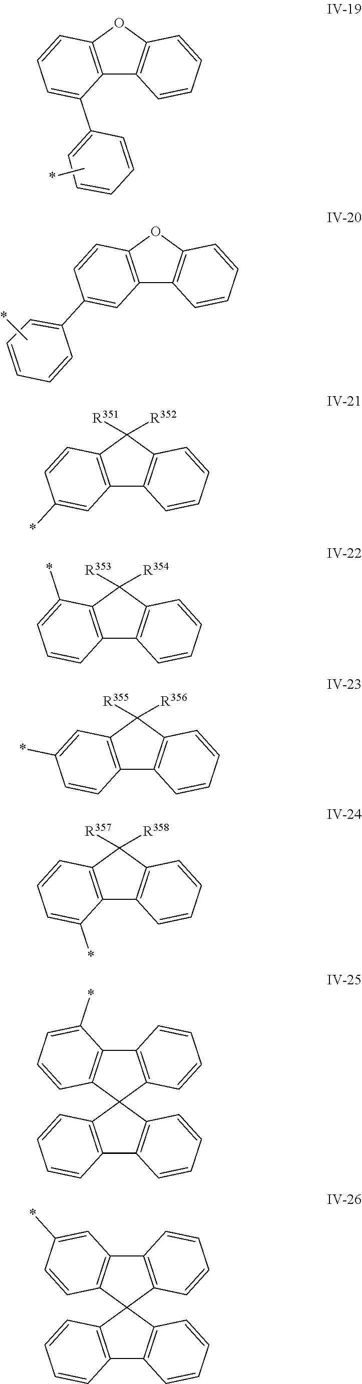 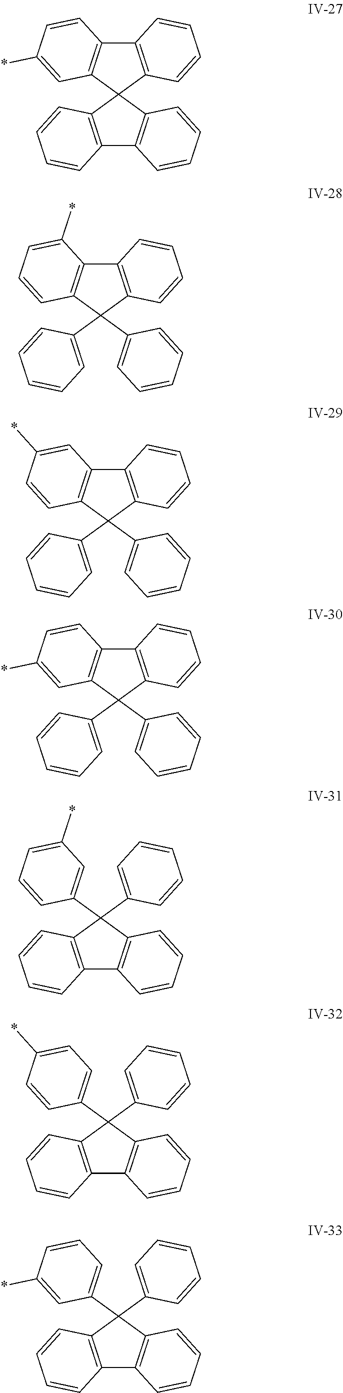
wherein in Group IV,
R³⁵¹ to R³⁵⁸ are each independently an alkyl group having 1 to 20 carbon atoms, and
* indicates the bonding position with an adjacent atom; 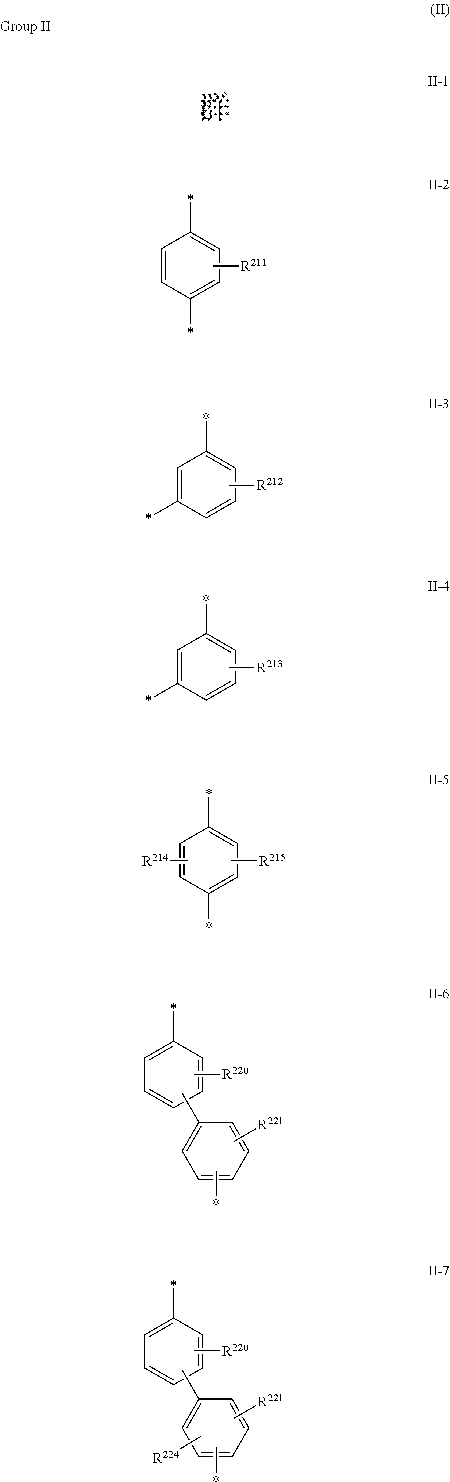 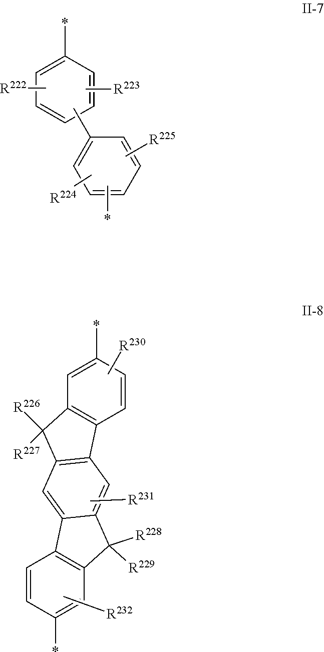
wherein in Group II,
R²¹¹ to R²³² are each independently a hydrogen atom, or a linear or branched hydrocarbon group having 1 to 18 carbon atoms, and
* indicates the bonding position with an adjacent atom.

14. The laminate according to claim 6, wherein in Chemical Formula (1), Ar¹³ is selected from Group I, Ar¹¹ and Ar¹² are each independently selected from Group II, and Ar¹⁴ is represented by Chemical Formula (5): 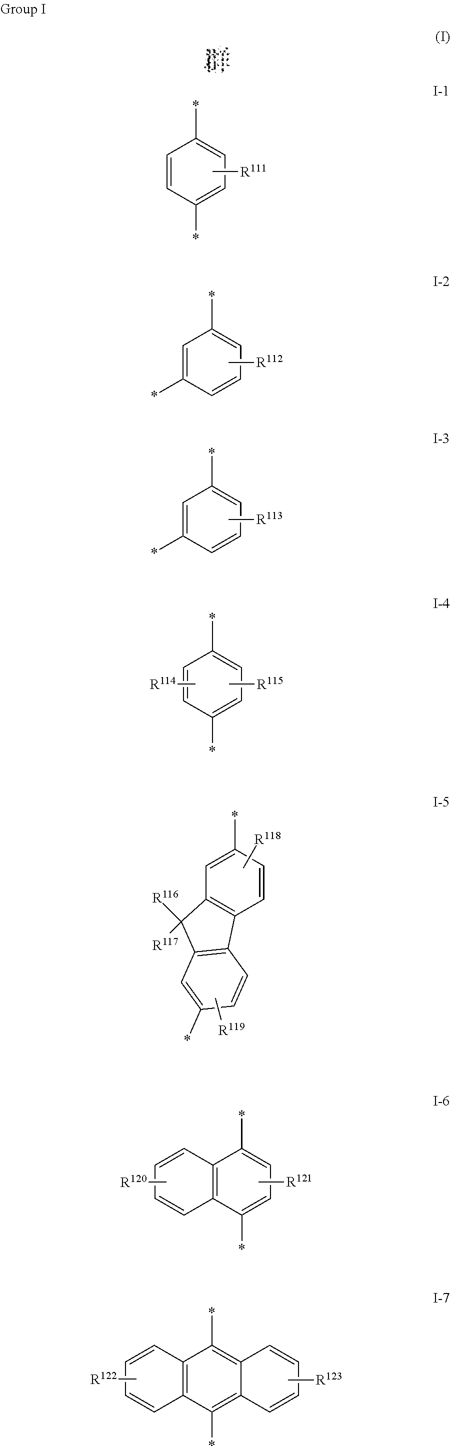 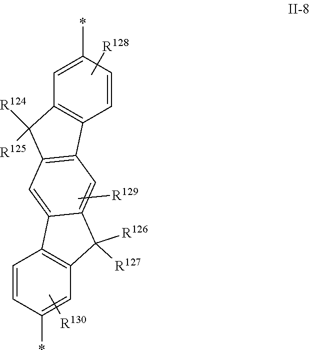
wherein in Group I,
R¹¹¹ to R¹³⁰ are each independently a hydrogen atom, or a linear or branched hydrocarbon group having 1 to 18 carbon atoms, and
* is the bonding position with an adjacent atom; 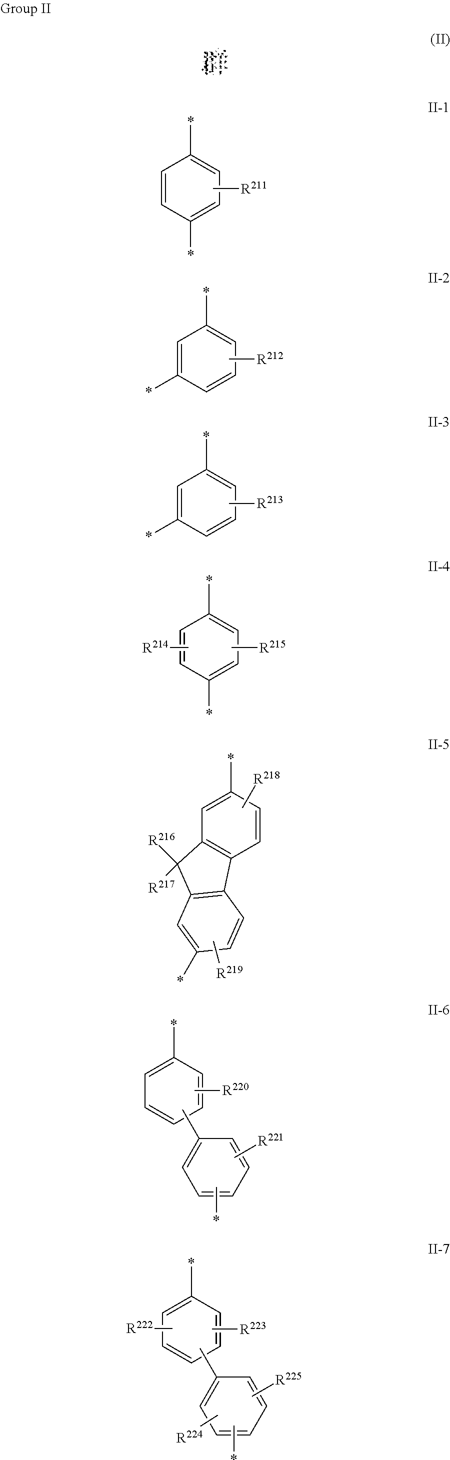 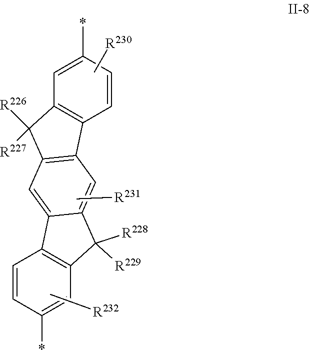
wherein in Group II,
R²¹¹ to R²³² are each independently hydrogen atom, or a linear or branched hydrocarbon group having 1 to 18 carbon atoms, and
* is the bonding position with an adjacent atom; 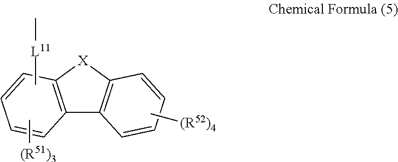
wherein in Chemical Formula (5),
L¹¹ is a single bond, a substituted or unsubstituted aromatic hydrocarbon group having 6 to 30 carbon atoms, or a substituted or unsubstituted heterocyclic ring having 3 to 30 ring-forming atoms,
R⁵¹ and R⁵² are each independently hydrogen atom, a substituted or unsubstituted alkyl group having 1 to 20 carbon atoms, a substituted or unsubstituted alkoxy group having 1 to 20 carbon atoms, a substituted or unsubstituted aromatic hydrocarbon group having 6 to 30 carbon atoms, or a substituted or unsubstituted heterocyclic ring having 3 to 30 ring-forming atoms, wherein R⁵¹ and R⁵² may be the same as or different from each other,
X is —C(R⁵³)(R⁵⁴)—, O, or S, wherein R⁵³ and R⁵⁴ are each independently a substituted or unsubstituted aryl group having 6 to 30 carbon atoms, or a substituted or unsubstituted alkyl group having 1 to 20 carbon atoms, or optionally bonded to each other to form a ring structure including the carbon atom to which they are bonded.

15. The laminate according to claim 1, the first organic compound is a polymer that comprises at least one structural unit represented by Chemical Formulae P-1 to P-6:

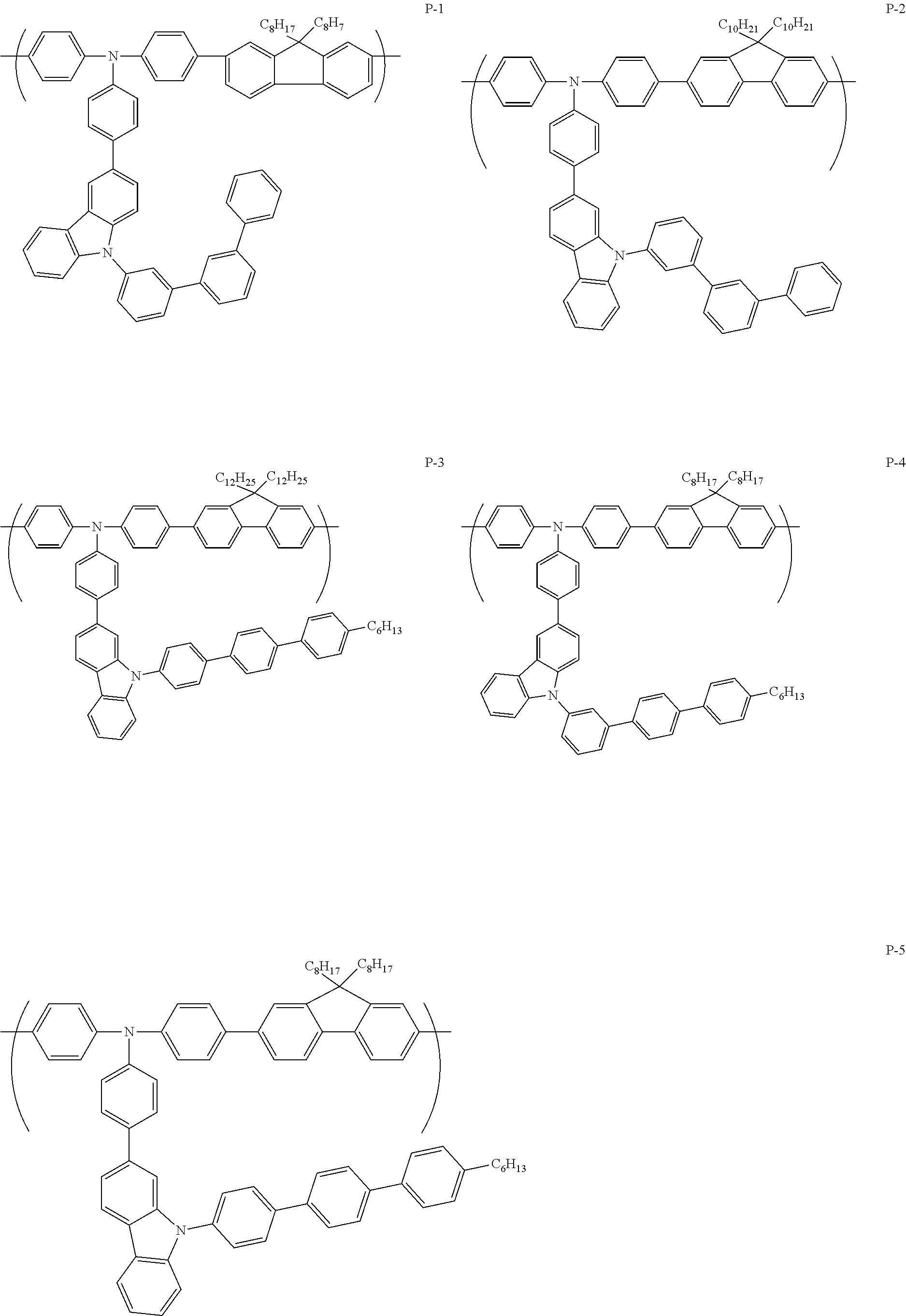

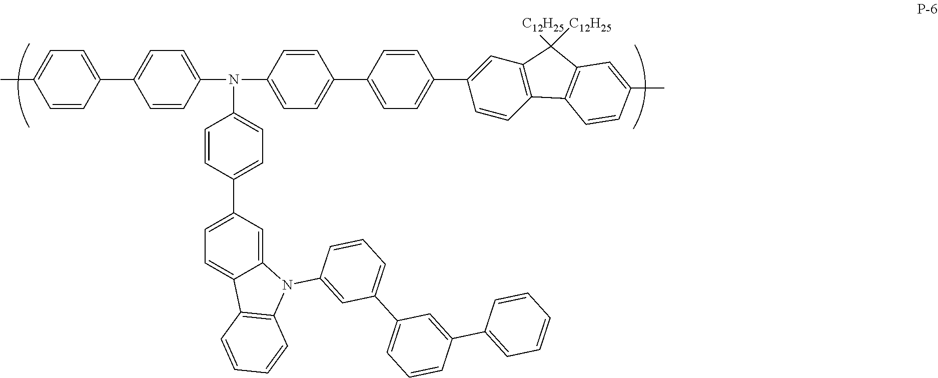

16. The laminate according to claim 1, the second organic compound comprises at least one liquid crystalline compound represented by Chemical Formulae (L-11) to (L-29): 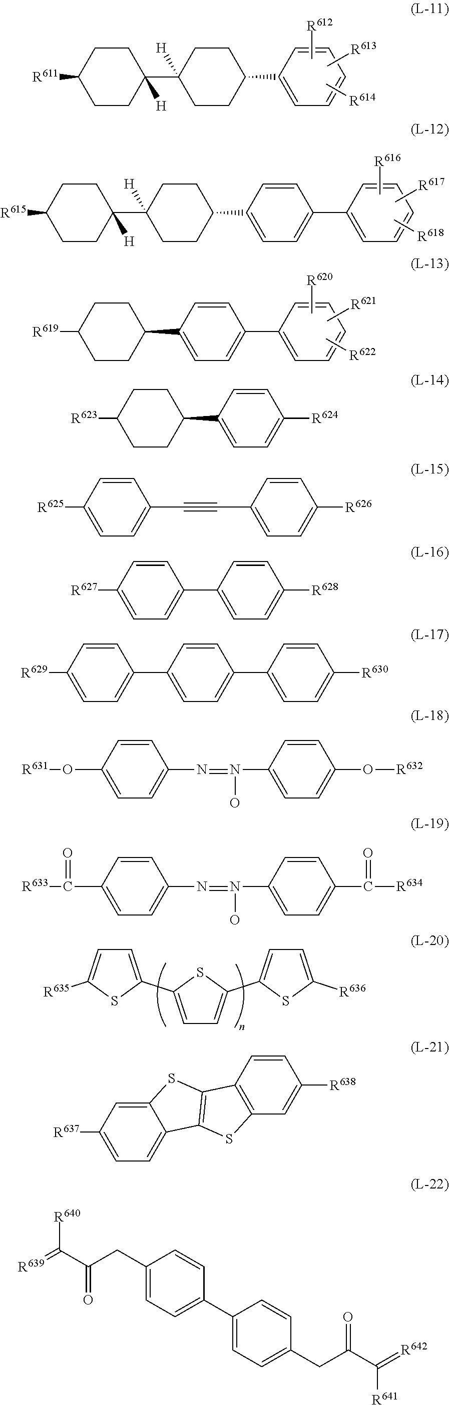 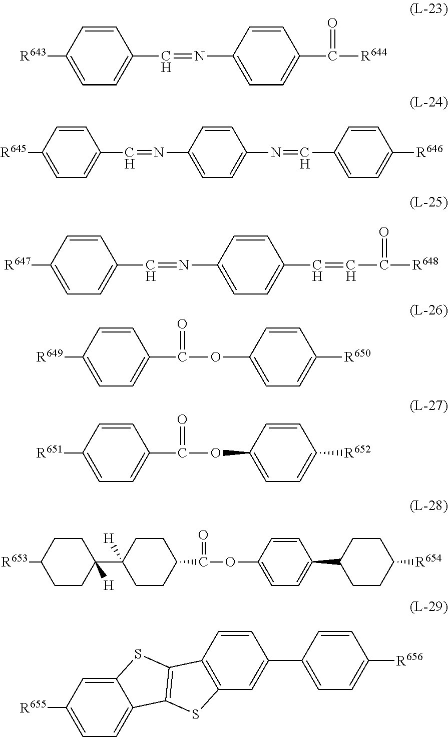
Wherein in Chemical Formulae (L-11) to (L-29),
R⁶¹¹ to R⁶³¹, R⁶³⁵ to R⁶³⁸, R⁶⁴³, R⁶⁴⁵ to R⁶⁴⁷ and R⁶⁴⁹ to R⁶⁵⁶ are each independently hydrogen, deuterium, a cyano group, a nitro group, a halogen group, a carboxyl group, an alkyl group having 1 to 20 carbon atoms, an alkoxy group having 1 to 20 carbon atoms, —R⁶⁵⁷—COOH, wherein R⁶⁵⁷ is an alkylene group having 1 to 20 carbon atoms or an alkenylene group having 2 to 20 carbon atoms, a deuterated-R⁶⁵⁸—COOH, wherein R⁶⁵⁸ is an alkylene group having 1 to 20 carbon atoms or an alkenylene group having 2 to 20 carbon atoms, a silyl group (—Si(R⁶⁵⁹)₃), wherein R⁶⁵⁹ is each independently hydrogen or an alkyl group having 1 to 20 carbon atoms, a siloxanyl group (—O—Si(R⁶⁶⁰)₃), wherein R⁶⁶⁰ is each independently hydrogen or an alkyl group having 1 to 20 carbon atoms, or an amino group (—N(R⁶⁶¹)₂), wherein R⁶⁶¹ is each independently hydrogen or an alkyl group having 1 to 20 carbon atoms, and
R⁶³² to R⁶³⁴, R⁶³⁹ to R⁶⁴², R⁶⁴⁴, and R⁶⁴⁸ are each independently an alkyl group having 1 to 20 carbon atoms.

17. The laminate according to claim 16, wherein the second organic compound is represented by at least one of Chemical Formulae (L-12), (L-13), (L-16), (L-17), or (L-29).

18. The laminate according to claim 1, wherein the second organic compound comprises at least one of the liquid crystalline compounds represented by Chemical Formulae LAD-1 to LAD-5:

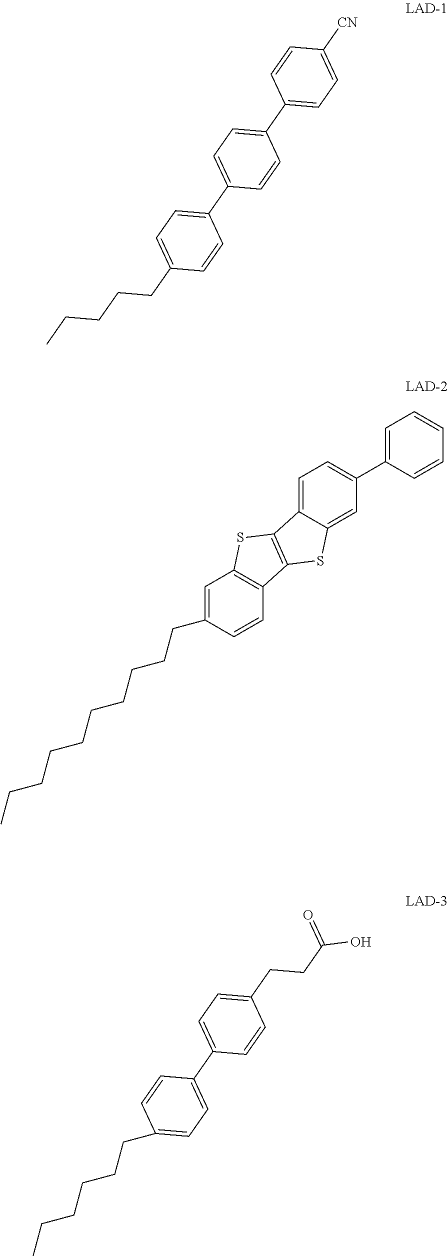 [SMILES: CCCCCc1ccc(-c2ccc(-c3ccc(C#N)cc3)cc2)cc1 ; CCCCCCCCCCc1ccc2c(c1)sc1c3ccc(-c4ccccc4)cc3sc21 ; CCCCCCc1ccc(-c2ccc(CCC(=O)O)cc2)cc1]

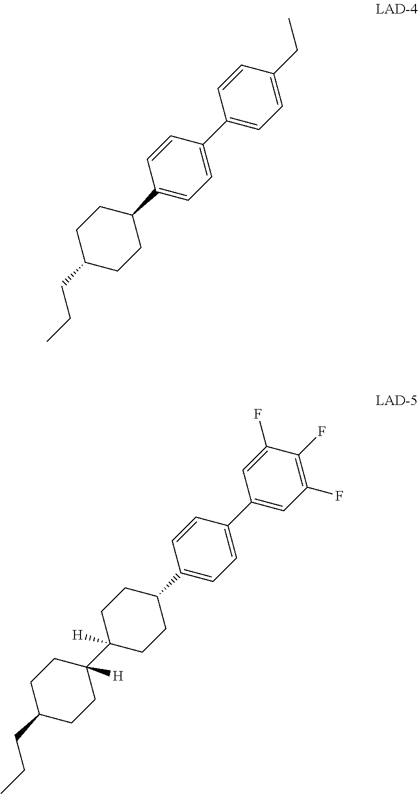

19. The laminate according to claim 1, wherein the emitting layer comprises a core-cell quantum dot.

20. A quantum dot electroluminescent device comprising the laminate according to claim 1.
